(19) United States
(12) Patent Application Publication
(10) Pub. No.: US 2025/0130503 A1
(43) Pub. Date: Apr. 24, 2025

(54) IMAGING EUV OPTICAL UNIT FOR IMAGING AN OBJECT FIELD INTO AN IMAGE FIELD

(71) Applicant: Carl Zeiss SMT GmbH, Oberkochen (DE)

(72) Inventors: Michael BREHM, Sulzbach-Laufen (DE); Susanne BEDER, Aalen (DE); Christoph MENKE, Oberkochen (DE); Marco PRETORIUS, Oberkochen (DE)

(21) Appl. No.: 18/988,581

(22) Filed: Dec. 19, 2024

Related U.S. Application Data
(63) Continuation of application No. PCT/EP2023/065084, filed on Jun. 6, 2023.

(30) Foreign Application Priority Data
Jun. 20, 2022 (DE) 10 2022 206 112.8

(51) Int. Cl. G03F 7/00; G02B 17/06

(52) U.S. Cl. CPC G03F 7/70233; G02B 17/0663; G03F 7/70033

(57) ABSTRACT

An imaging EUV optical unit serves for imaging an object field into an image field. The EUV optical unit has a plurality of mirrors for guiding EUV imaging light at a wavelength of less than 30 nanometers along an imaging beam path from the object field towards the image field. The EUV optical unit has four normal incidence (NI) mirrors. The overall transmission of the NI mirrors is greater than 10%. The mirrors lead to an overall polarization rotation of no more than 10° along the imaging beam path when linearly polarized EUV imaging light is used. This can yield an imaging EUV optical unit with an increased EUV throughput while observing exacting demands on the imaging quality.

### CROSS-REFERENCE TO RELATED APPLICATIONS

The present application is a continuation of, and claims benefit under 35 USC 120 to, international application No. PCT/EP2023/065084, filed Jun. 6, 2023, which claims benefit under 35 USC 119 of German Application No. 10 2022 206 112.8, filed Jun. 20, 2022. The entire disclosure of each of these applications is incorporated by reference herein.

### FIELD

The disclosure relates to an imaging EUV optical unit for imaging an object field into an image field. Furthermore, the disclosure relates to an optical system comprising such an imaging optical unit, a projection exposure apparatus comprising such an optical system, a method for producing a micro- or nanostructured component using such a projection exposure apparatus, and a micro- or nanostructured component produced by the method.

### BACKGROUND

Imaging optical units at the outset are known from DE 10 2018 214 437 A1, U.S. Pat. No. 8,018,650 B2, WO 2018/043 433 A1, U.S. Pat. No. 6,353,470 B1 and U.S. Pat. No. 5,291,340.

### SUMMARY

The present disclosure seeks to provide an imaging EUV optical unit so that the EUV throughput is increased while observing exacting demands on the imaging quality.

In an aspect, the disclosure provides an imaging EUV optical unit for imaging an object field into an image field. The EUV optical unit has a plurality of mirrors for guiding EUV imaging light at a wavelength of shorter than 30 nanometers (nm) along an imaging beam path from the object field towards the image field. The EUV optical unit comprises at least three normal incidence (NI) mirrors. An overall transmission of the NI mirrors is greater than 10%. An overall number of the mirrors leads to an overall polarization rotation of no more than 10° along the imaging beam path when linearly polarized EUV imaging light is used.

According to the disclosure, it was recognized that a small polarization rotation of the imaging EUV optical unit of no more than 10° enables imaging of linearly polarized imaging light as well, without this leading to unwanted contrast losses within the scope of interference of different orders of diffraction guided in the imaging beam path which is used for imaging purposes. The overall polarization rotation can be less than 10°, can be less than 8°, can be less than 7°, can be less than 6°, can be less than 5° and can also be less than 4.5°. An even smaller overall polarization rotation is also possible. The overall polarization rotation is regularly greater than 0.1°. The overall polarization rotation describes the cumulative polarization-rotating effect of all mirrors in the imaging EUV optical unit.

The EUV optical unit may can comprise three NI mirrors or else four NI mirrors. A smaller numbers of NI mirrors is also possible.

Certain known EUV optical unit overall transmissions are regularly significantly less than 10%. An overall transmission of the imaging EUV optical unit of greater than 10% represents a very significant improvement since every percentage obtained in the overall transmission in the case of overall transmissions with a small absolute value means a significant increase in the EUV throughput through the imaging EUV optical unit. This can play a decisive role, especially when using the imaging EUV optical unit within the scope of projection exposure for chip production.

The overall transmission of the NI mirrors, i.e. the overall transmission of the imaging EUV optical unit may be greater than 11%, may be greater than 12%, may be greater than 13%, may be greater than 14%, may be greater than 15%, may be greater than 16%, may be greater than 17%, may be greater than 18%, and may also be greater than 19%. The overall transmission is regularly less than 30%.

An image-side numerical aperture of the imaging EUV optical unit may be less than 0.5, which can promote the imaging aberration correction and for the reflectivity increase usable small angles of incidence or small angle-of-incidence bandwidths on the NI mirrors. At least one of the mirrors of the imaging EUV optical unit can be designed as a free-form surface, which cannot be described with the aid of an axis of rotational symmetry. A plurality or all of the mirrors may also be designed as such free-form surfaces.

The imaging EUV optical unit may have a sequence of mirrors along the imaging beam path, in which use is made firstly of a converging mirror, then a diverging mirror and in turn thereafter a converging mirror again, especially in the plane in a long field direction, provided use is made of an object field with an aspect ratio greater than 1.

In the case of the imaging EUV optical unit, an object plane may extend parallel to an image plane. Alternatively, it is possible to tilt the object plane relative to the image plane, for example for installation space-optimizing reasons.

At least one mirror in the imaging EUV optical unit may have a saddle-shaped basic form. Additionally, 2, 3 or even more of the mirrors in the imaging EUV optical unit may have a saddle-shaped basic form.

A chief ray angle between chief rays of an imaging beam path in the imaging EUV optical unit and a normal to an object plane in which the object field is located may be in the range between 4.5° and 7°, for example in the range between 5° and 6°.

The EUV imaging optical unit may include precisely four NI mirrors. Such a comparatively small number of NI mirrors can yield a relatively high overall transmission, while still being possible to meet exacting demands with respect to the imaging quality to be achieved.

The EUV optical unit can exclusively comprise NI mirrors. It was identified that significant demands in relation to the imaging quality of the EUV optical unit can also be met if exclusive use is made of NI mirrors, that is to say no additional grazing incidence (GI) mirrors, which in principle may have a high EUV reflectivity, are used for further imaging aberration correction.

A first imaging of the object field in the imaging beam path can occur in the image field. A design without an intermediate image between the object field and the image field can allow the provision of particularly small angle-of-incidence bandwidths on the NI mirrors involved. This can make it easier to meet the demand for highly reflective coatings, especially on the NI mirrors of the imaging EUV optical unit.

A small polarization rotation of the imaging EUV optical unit can allow the imaging of linearly polarized imaging light.

At least one of the mirrors can have a saddle-shaped reflection surface. A saddle surface design of at least one of the mirrors 5, that is to say different signs of curvature of the respective mirror reflection surface in mutually perpendicular reflection surface sectional planes, was found to be particularly suitable for the optical design of the imaging EUV optical unit.

At least one of the mirrors can have a reflection surface with an aspect ratio of greater than 1.5 between a greater surface extent along a first reflection surface dimension and a smaller surface extent along a second reflection dimension perpendicular thereto. Such an aspect ratio can allow the imaging beam path to be guided with small angle-of-incidence bandwidths even if the field to be imaged has a large aspect ratio which, for example, may be greater than 3, may be greater than 5, may be greater than 8 and may also be greater than 10. The aspect ratio of the mirror reflection surface may be greater than 1.7, may be greater than 2 and may also be greater than 2.5. This aspect ratio of the mirror reflection surface is regularly less than 5. A corresponding aspect ratio may apply to one of the NI mirrors in the imaging EUV optical unit.

The imaging EUV optical unit can have a ring-field-shaped image field. A ring-field-shaped image field can be corrected well. Alternatively, the image field may be designed in rectangular or else non-ring-field-shaped arcuate fashion.

Depending on the embodiment of the imaging EUV optical unit, a crossing region as disclosed herein may lead to the realization of small angles of incidence on the NI mirrors and/or the realization of small angle-of-incidence bandwidths, each of which is advantageous for the purpose of obtaining high reflectivities.

A crossing region may also be present between an imaging beam path portion between an antepenultimate and a penultimate mirror in the imaging beam path and an imaging beam path portion between the last mirror and the image field.

An entrance pupil can be in the imaging beam path upstream of the object field, that is to say outside of the imaging beam path between the object field and the image field. This can allow the arrangement of a corresponding illumination-optical component in the region of this entrance pupil, with the result that there is no need for an illumination-optical component to be disposed close to a pupil to be imaged into an otherwise inaccessible entrance pupil of the imaging EUV optical unit. This can economize light-guiding component parts and thus likewise increases the EUV throughput.

At least one mirror with a passage opening according to Claim 11 allows the imaging EUV optical unit to be designed as an obscured system. The imaging EUV optical unit can be designed in singly obscured fashion, wherein exactly one of the mirrors has a passage opening for the passage of the imaging beam path. Alternatively, two mirrors may also be provided with such passage openings and, in particular, a doubly obscured system may then be present. Such mirror passage openings allow designs with small angles of incidence and/or small angle-of-incidence bandwidths on the respective NI mirrors. Alternatively, the imaging EUV optical unit may also be designed in non-obscured fashion.

Features of a related optical system, projection exposure apparatus, production method, and microstructured or nanostructured component correspond to those which have already been explained above with reference to the projection optical unit according to the disclosure. The EUV light source of the projection exposure apparatus can be configured so that a used wavelength emerges which is no more than 30 nm, no more than 25 nm, no more than 20 nm or no more than 13.5 nm, which is less than 13.5 nm, which is less than 10 nm, which is less than 8 nm, which is less than 7 nm and which is 6.7 nm or 6.9 nm, for example. A used wavelength of less than 6.7 nm and, in particular, of the order of 6 nm is also possible.

A semiconductor component, for example a memory chip, can be produced using the projection exposure apparatus.

### BRIEF DESCRIPTION OF THE DRAWINGS

Below, at least one exemplary embodiment of the disclosure is described on the basis of the drawings. In the drawings:

FIG. 1 schematically shows a meridional section of a projection exposure apparatus for EUV projection lithography;

FIG. 2 shows, in a meridional section, an embodiment of an imaging EUV optical unit which can be used as a projection lens in the projection exposure apparatus according to FIG. 1, wherein an imaging beam path for chief rays and for an upper coma ray and a lower coma ray of three selected field points is depicted;

FIGS. 3-9 show, in each case in representations similar to FIG. 2, further embodiments of an imaging EUV optical unit, once again usable in each case as a projection lens in the projection exposure apparatus according to FIG. 1; and

FIG. 10 shows a plan view of the imaging EUV optical unit according to FIG. 9, as seen from the viewing direction X in FIG. 9.

### DETAILED DESCRIPTION

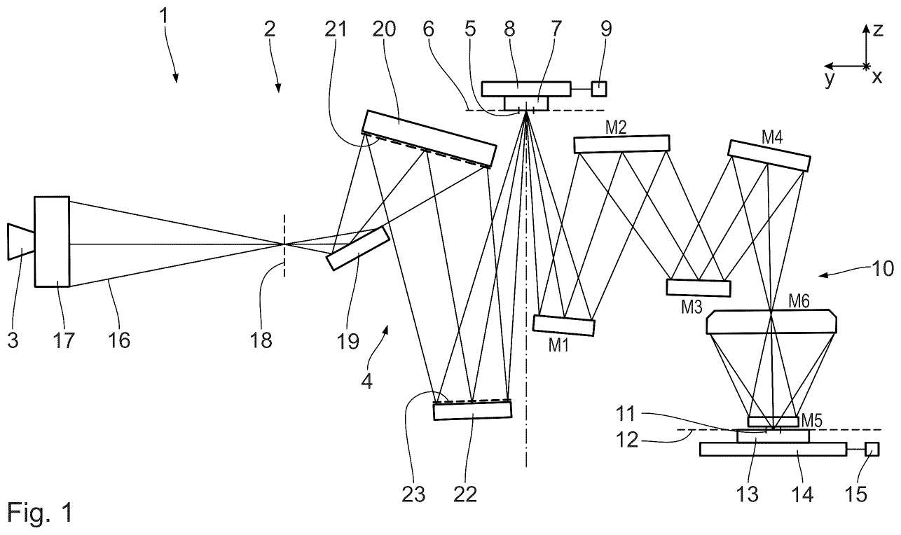

In the following text, certain components of a microlithographic projection exposure apparatus 1 are described first by way of example with reference to FIG. 1. The description of the basic structure of the projection exposure apparatus 1 and its components should not be construed as limiting here.

One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 can also be provided as a module separate from the rest of the illumination system. In this case, the illumination system does not comprise the light source 3.

A reticle 7 arranged in the object field 5 is exposed. The reticle 7 is held by a reticle holder 8. The reticle holder 8 is displaceable by way of a reticle displacement drive 9, in particular in a scanning direction.

A Cartesian xyz-coordinate system is shown in FIG. 1 for explanation purposes. The x-direction runs perpendicular to the plane of the drawing into the latter. The y-direction runs horizontally and the z-direction runs vertically. The scanning direction runs in the y-direction in FIG. 1. The z-direction runs perpendicularly to the object plane 6.

The projection exposure apparatus 1 comprises a projection optical unit 10. The projection optical unit 10 serves as an imaging optical unit for imaging the object field 5 into an image field 11 in an image plane 12. The image plane 12 extends parallel to the object plane 6. Alternatively, an angle that differs from 0° between the object plane 6 and the image plane 12 is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, in particular in the y-direction. The displacement, firstly, of the reticle 7 by way of the reticle displacement drive 9 and, secondly, of the wafer 13 by way of the wafer displacement drive 15 can be implemented so as to be synchronized with one another.

The radiation source 3 is an EUV (extreme ultraviolet) radiation source. The radiation source 3 emits, in particular, EUV radiation 16, which is also referred to below as used radiation, illumination radiation, illumination light or imaging light. In particular, the used radiation has a wavelength in the range of between 5 nm and 30 nm. The radiation source 3 can be a plasma source, for example an LPP (laser produced plasma) source or a GDPP (gas discharge produced plasma) source. It may also be a synchrotron-based radiation source. The radiation source 3 may be a free electron laser (FEL).

The illumination radiation 16 emerging from the radiation source 3 is focused by a collector 17. The collector 17 may be a collector with one or more ellipsoidal and/or hyperboloidal reflection surfaces. The illumination radiation 16 can be incident on the at least one reflection surface of the collector 17 with grazing incidence (GI), that is to say at angles of incidence of greater than 45°, or with normal incidence (NI), that is to say at angles of incidence of less than 45°. The collector 17 may be structured and/or coated on the one hand for optimizing its reflectivity for the used radiation and on the other hand for suppressing stray light.

The illumination radiation 16 propagates through an intermediate focus in an intermediate focal plane 18 downstream of the collector 17. The intermediate focal plane 18 can represent a separation between a radiation source module, having the radiation source 3 and the collector 17, and the illumination optical unit 4.

The illumination optical unit 4 comprises a deflection mirror 19 and, arranged downstream thereof in the beam path, a first facet mirror 20. The deflection mirror 19 may be a plane deflection mirror or, alternatively, a mirror with a beam-influencing effect that goes beyond the purely deflecting effect. Alternatively or in addition, the deflection mirror 19 may be embodied in the form of a spectral filter that separates a used light wavelength of the illumination radiation 16 from extraneous light of a wavelength deviating therefrom. If the first facet mirror 20 is arranged in a plane of the illumination optical unit 4 that is optically conjugate to the object plane 6 as a field plane, it is also referred to as a field facet mirror. The first facet mirror 20 comprises a multiplicity of individual first facets 21, which are also referred to below as field facets. FIG. 1 depicts only some of the facets 21 by way of example.

The first facets 21 may be embodied as macroscopic facets, in particular as rectangular facets or as facets with an arcuate edge contour or an edge contour of part of a circle. The first facets 21 may be embodied as plane facets or alternatively as facets with convex or concave curvature.

As known for example from DE 10 2008 009 600 A1, the first facets 21 themselves may also be composed in each case of a multiplicity of individual mirrors, in particular a multiplicity of micromirrors. The first facet mirror 20 may in particular be formed as a microelectromechanical system (MEMS system). For details, reference is made to DE 10 2008 009 600 A1.

The illumination radiation 16 travels horizontally, that is to say in the y-direction, between the collector 17 and the deflection mirror 19.

In the beam path of the illumination optical unit 4, a second facet mirror 22 is arranged downstream of the first facet mirror 20. If the second facet mirror 22 is arranged in a pupil plane of the illumination optical unit 4, it is also referred to as a pupil facet mirror. The second facet mirror 22 may also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which may for example have a round, rectangular or else hexagonal boundary, or may alternatively be facets composed of micromirrors. In this regard, reference is likewise made to DE 10 2008 009 600 A1.

The second facets 23 may have plane reflection surfaces or alternatively reflection surfaces with convex or concave curvature.

The illumination optical unit 4 consequently forms a doubly faceted system. This fundamental principle is also referred to as a fly's eye condenser (fly's eye integrator).

It may be advantageous to arrange the second facet mirror 22 not exactly in a plane that is optically conjugate to a pupil plane of the projection optical unit 10. In particular, the pupil facet mirror 22 can be arranged so as to be tilted relative to a pupil plane of the projection optical unit 10, as is described, for example, in DE 10 2017 220 586 A1.

With the aid of the second facet mirror 22, the individual first facets 21 are imaged into the object field 5. The second facet mirror 22 is the last beam shaping mirror or else, in fact, the last mirror for the illumination radiation 16 in the beam path upstream of the object field 5.

In a further embodiment, not shown, of the illumination optical unit 4, a transfer optical unit contributing in particular to the imaging of the first facets 21 into the object field 5 may be arranged in the beam path between the second facet mirror 22 and the object field 5. The transfer optical unit may have exactly one mirror, or alternatively have two or more mirrors, which are arranged one behind the other in the beam path of the illumination optical unit 4. The transfer optical unit may in particular comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the field facet mirror 20 and the pupil facet mirror 22.

The deflection mirror 19 can also be dispensed with in a further embodiment of the illumination optical unit 4, and so the illumination optical unit 4 can then have exactly two mirrors downstream of the collector 17, specifically the first facet mirror 20 and the second facet mirror 22.

The imaging of the first facets 21 into the object plane 6 via the second facets 23 or using the second facets 23 and a transfer optical unit is, as a rule, only approximate imaging.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or any other number of mirrors Mi are likewise possible. The projection optical unit 10 is a doubly obscured optical unit. The penultimate mirror M5 and the last mirror M6 each have a passage opening for the illumination radiation 16.

Imaging light 16 guided from the last mirror M6 towards the image field 11 passes through the passage opening of the mirror M5. Imaging light 16 reflected from the antepenultimate mirror M4 towards the penultimate mirror M5 passes through the passage opening of the mirror M6. Around their passage openings, the mirrors M5 and M6 are used reflectively for the guidance of the imaging light 16.

The projection optical unit 10 has an image-side numerical aperture which is greater than 0.25 and which may also be greater than 0.3 and, for example, can be 0.33.

The image-side numerical aperture is regularly less than 0.9, less than 0.75, less than 0.6 and can be less than 0.5. In principle, the image-side numerical aperture may also be larger.

Reflection surfaces of the mirrors Mi may be embodied as free-form surfaces without an axis of rotational symmetry. Alternatively, the reflection surfaces of the mirrors Mi may be designed as aspheric surfaces with exactly one axis of rotational symmetry of the reflection surface shape. Just like the mirrors of the illumination optical unit 4, the mirrors Mi may have highly reflective coatings for the illumination radiation 16. These coatings may be designed as multilayer coatings, in particular with alternating layers of molybdenum and silicon.

The projection optical unit 10 has an object-image offset in the y-direction between a y-coordinate of a centre of the object field 5 and a y-coordinate of the centre of the image field 11. This object-image offset in the y-direction can be of approximately the same magnitude as a z-distance between the object plane 6 and the image plane 12.

In particular, the projection optical unit 10 can have an anamorphic embodiment. In particular, it has different imaging scales βₓ, β_{y} in the x- and y-directions. The two imaging scales βₓ, β_{y} of the projection optical unit 10 can be at (βₓ, β_{y})=(+/−0.25, /+−0.125). A positive imaging scale R means imaging without image inversion. A negative sign for the imaging scale R means imaging with image inversion.

The projection optical unit 10 for example has a reduction in size in the ratio of 4:1 in the x-direction, that is to say in a direction perpendicular to the scanning direction.

In the case of an anamorphic embodiment, the projection optical unit 10 has a reduction in size of 8:1 in the y-direction, that is to say in the scanning direction.

Other imaging scales are likewise possible. Imaging scales with the same sign and the same absolute value in the x-direction and y-direction are also possible, for example with absolute values of 0.125 or of 0.25.

The number of intermediate image planes in the x-direction and in the y-direction in the beam path between the object field 5 and the image field 11 can be the same or, depending on the embodiment of the projection optical unit 10, can differ. Examples of projection optical units with different numbers of such intermediate images in the x- and y-directions are known from US 2018/0074303 A1.

In each case one of the pupil facets 23 is assigned to exactly one of the field facets 21 for forming in each case an illumination channel for illuminating the object field 5. In particular, this can yield illumination according to the Kohler principle. The far field is decomposed into a multiplicity of object fields 5 with the aid of the field facets 21. The field facets 21 generate a plurality of images of the intermediate focus on the pupil facets 23 respectively assigned thereto.

By way of an assigned pupil facet 23, the field facets 21 are imaged in each case onto the reticle 7 in a manner superposed on one another for the purposes of illuminating the object field 5. The illumination of the object field 5 is in particular as homogeneous as possible. It can have a uniformity error of less than 2%. The field uniformity may be achieved by way of the overlay of different illumination channels.

The illumination of the entrance pupil of the projection optical unit 10 can be defined geometrically by way of an arrangement of the pupil facets. The intensity distribution in the entrance pupil of the projection optical unit 10 can be set by selecting the illumination channels, in particular the subset of the pupil facets which guide light. This intensity distribution is also referred to as illumination setting or illumination pupil filling.

A likewise preferred pupil uniformity in the region of sections of an illumination pupil of the illumination optical unit 4 that are illuminated in a defined manner can be achieved by a redistribution of the illumination channels.

Further aspects and details of the illumination of the object field 5 and in particular of the entrance pupil of the projection optical unit 10 are described below.

The projection optical unit 10 may have in particular a homocentric entrance pupil. The latter may be accessible. It may also be inaccessible.

The entrance pupil of the projection optical unit 10 regularly cannot be exactly illuminated using the pupil facet mirror 22. In the case of imaging of the projection optical unit 10 which telecentrically images the centre of the pupil facet mirror 22 onto the wafer 13, the aperture rays often do not intersect at a single point. However, it is possible to find an area in which the distance of the aperture rays determined in pairs becomes minimal. This area represents the entrance pupil or an area in real space that is conjugate thereto. In particular, this area has a finite curvature.

It may be the case that the projection optical unit 10 has different poses of the entrance pupil for the tangential beam path and for the sagittal beam path. In this case, an imaging element, in particular an optical component part of the transfer optical unit, should be provided between the second facet mirror 22 and the reticle 7. With the aid of this optical element, the different position of the tangential entrance pupil and the sagittal entrance pupil can be taken into account.

In the arrangement of the components of the illumination optical unit 4 illustrated in FIG. 1, the pupil facet mirror 22 is arranged in an area conjugate to the entrance pupil of the projection optical unit 10. The field facet mirror 20 is arranged such that it is tilted with respect to the object plane 6. The first facet mirror 20 is arranged in tilted fashion with respect to an arrangement plane defined by the deflection mirror 19.

The first facet mirror 20 is arranged such that it is tilted with respect to an arrangement plane that is defined by the second facet mirror 22.

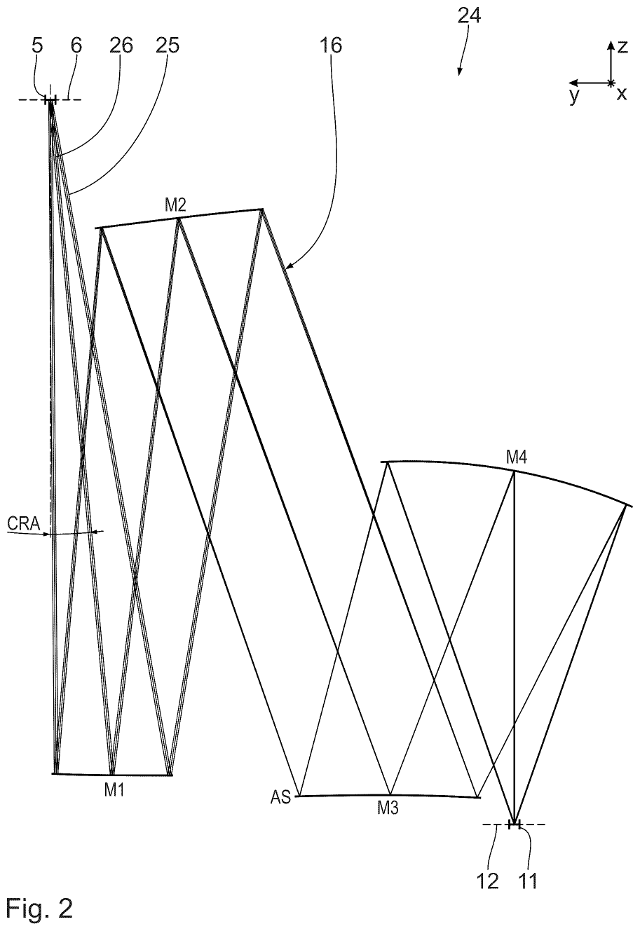

FIG. 2 shows a further embodiment of a projection optical unit or imaging optical unit 24, which can be used in the projection exposure apparatus 1 instead of the projection optical unit 10 of the embodiment according to FIG. 1. Components and functions corresponding to those which have already been explained above with reference to FIG. 1 bear the same reference signs and will not be discussed in detail again.

FIG. 2 depicts the beam path of, in each case, three individual rays 25 emanating from three object field points which are spaced apart from one another in the y-direction in FIG. 2. What is depicted are chief rays 26, that is to say individual rays 25 which pass through the centre of a pupil in a pupil plane of the projection optical unit 24, and, in each case, an upper coma ray and a lower coma ray of these three object field points. Proceeding from the object field 5, the chief rays 26 include an angle CRA of 5.22° with the normal to the object plane 6. A design of the projection optical unit 24 for the reflective reticle 7 is present on account of this chief ray angle CRA. This thus ensures that a beam path of the illumination light 16 incident on the reticle 7 does not interfere with a beam path of the illumination or imaging light 16 reflected by the reticle 7.

The projection optical unit 24 has an image-side numerical aperture of 0.33.

The projection optical unit 24 according to FIG. 2 has a total of four mirrors, which are numbered consecutively by M1 to M4 in the order of the beam path of the individual rays 25, proceeding from the object field 4.

FIG. 2 depicts portions of the calculated reflection surfaces of the mirrors M1 to M4. An actually used region of the reflection surfaces, plus an overhang, is present in the real mirrors M1 to M4. These used reflection surfaces are carried by mirror bodies, not depicted in FIG. 2, in a manner known per se.

In the projection optical unit 24 according to FIG. 2, all mirrors M1 to M4 are embodied as mirrors for perpendicular or normal incidence, that is to say as mirrors onto which the imaging light 16 is incident at an angle of incidence that is smaller than 45°. These mirrors for perpendicular incidence are also referred to as NI (normal incidence) mirrors.

The mirrors M1 to M4 carry a coating that optimizes the reflectivity of the mirrors M1 to M4 for the imaging light 16. This can be a ruthenium coating, a molybdenum coating or a molybdenum coating with an uppermost layer of ruthenium. These highly reflective layers can be embodied as multi-ply layers, where successive layers can be manufactured from different materials. Alternating material layers can also be used. A typical multi-ply layer can have fifty bilayers, respectively made of a layer of molybdenum and a layer of silicon.

For the purposes of calculating an overall reflectivity of the projection optical unit 24, a system transmission is calculated as follows: A mirror reflectivity is determined at each mirror surface on the basis of the angle of incidence of a guide ray, that is to say a chief ray of a central object field point, and combined by multiplication to form the system transmission.

Details with respect to calculating the reflectivity are explained in WO 2015/014 753 A1. Further information with respect to the reflectivity of NI mirrors (normal incidence mirrors) can be found in DE 101 55 711 A.

A system or overall transmission of the projection optical unit 24, that is to say of the overall number of mirrors M1 to M4, is 17.55%. On average, each individual mirror of the four mirrors thus has a reflectivity of the order of 64.7%.

The polarization rotation of linearly polarized imaging light 16 in the imaging beam path of the projection optical unit 24 between the object field 5 and the image field 11 is approximately 3.6°.

None of the mirrors M1 to M4 has a passage opening and the mirrors are used in a reflective manner in a contiguous region without gaps. The mirrors M1 to M4 thus have a reflection surface used without openings.

In the projection optical unit 24, the image field 11 is the first field in the imaging beam path downstream of the object field 5. Thus, the projection optical unit 24 has no intermediate image plane.

A z-distance between the object field and the image field 8 (installation length) is approximately 1750 mm. A y-distance between a central field point of the object field 5 and a central field point of the image field 11 (object-image offset) is approximately 1380 mm. In the xz-plane, an entrance pupil of the projection optical unit 24 lies in the imaging beam path approximately 4100 mm downstream of the object field 5. In the yz-plane, the entrance pupil is in the imaging beam path more than 10 m upstream of the object field 5. Thus, the projection optical unit 24 is telecentric, to a good approximation, on the object side.

The projection optical unit 24 is telecentric on the image side.

A minimal distance between the wafer 13 and the mirror M3 closest to the wafer is 75 mm; this distance is also referred to as the working distance.

A mean wavefront aberration RMS of the projection optical unit 24 is less than 35 mλ in the case where a used wavelength of the imaging light 3 is 13.5 nm.

Tables 1 and 2 below once again summarize certain data of the projection optical unit 24:

Table 1 for FIG. 2

| Used wavelength | 13.5 | nm |
|---|---|---|
| Image-side numerical aperture | 0.33 | |
| Imaging scale | −4.00 | |
| Chief ray angle CRA | 5.22° | |
| Etendue | 7.08 | mm² |
| Mean wavefront aberration RMS | 33.28 | mλ |
| Overall transmission | 17.55% | |
| Position of the entrance pupil (x) | 4101.25 | mm |
| Position of the entrance pupil (y) | −39609.53 | mm |
| Object-image offset | 1379.52 | mm |
| Working distance (M3 to image field) | 75 | mm |
| z-distance between the object field and | 2156.00 | mm |
| image field | | |
| Angle between object plane and image | −0.0° | |
| plane | | |
| Installation space requirement xyz | (980 × 1703 × 1756) | mm |

Table 2 for FIG. 2

| | M1 | M2 | M3 | M4 |
|---|---|---|---|---|
| Max. angle of incidence/° | 10.1 | 14.9 | 23.7 | 17.0 |
| Min. angle of incidence/° | 2.6 | 11.9 | 16.9 | 3.8 |
| Mirror extent (x)/mm | 388.4 | 980.1 | 571.3 | 738.4 |
| Mirror extent (y)/mm | 326.4 | 460.3 | 519.4 | 721.4 |
| Max. mirror diameter/mm | 388.7 | 980.2 | 585.1 | 738.9 |

The extents specified in Table 2 in each case relate to the utilized reflection surface of the mirror M1 to M4.

The largest angle of incidence of the imaging light 16 on the mirrors M1 to M4 is present at the mirror M3 and is also less than 25° there.

The smallest angle of incidence is present at the mirror M1 and is greater than 2.5° there. A greatest angle-of-incidence bandwidth, that is to say the difference between the maximum and the minimum angle of incidence of the imaging light 16, is present at the last mirror M4 and is less than 15° there. The smallest angle-of-incidence bandwidth is present at the mirror M2 and is 3° there.

None of the mirrors M1 to M4 have a diameter greater than 1000 mm. With respect to the x-extent, the M2 mirror is the largest mirror of the projection optical unit 24. In particular, the mirror M2 has a greater x-extent than the mirror M4.

The mirror M2 has a reflection surface with an x/y-aspect ratio between a greater x-surface extent and a smaller y-surface extent which is greater than 1.5 and which is 2.13 in the mirror M2 of the projection optical unit 24, that is to say it is also greater than 2.

The image field 11 is ring-field-shaped with a ring-field radius of 260 mm in the projection optical unit 24. An x-extent of the image field 11 is 26 mm. A y-extent of the image field 11 is 2.5 mm.

The mirrors M1 to M4 are embodied as free-form surfaces which cannot be described by a rotationally symmetric function. Other embodiments of the projection optical unit 24, in which at least one of the mirrors M1 to M4 is embodied as a rotationally symmetric asphere, are also possible. It is also possible for all mirrors M1 to M4 to be embodied as such aspheres.

A free-form surface can be described by the following free-form surface equation (Equation 1):

$$Z = \frac{{c}_{x} {x}^{2} + {c}_{y} {y}^{2}}{1 + \sqrt{1 - ( 1 + {k}_{x} ) {( {c}_{x} x )}^{2} - ( 1 + {k}_{y} ) {( {c}_{y} y )}^{2}}} \qquad ( 1 )$$

$$\begin{matrix}+ {C}_{1} x + {C}_{2} y \\ + {C}_{3} {x}^{2} + {C}_{4} xy + {C}_{6} {y}^{2} \\ + {C}_{6} {x}^{3} + … + {C}_{9} {y}^{3} \\ + {C}_{10} {x}^{4} + … + {C}_{12} {x}^{2} {y}^{2} + … + {C}_{14} {y}^{4} \\ + {C}_{15} {x}^{5} + … + {C}_{20} {y}^{5} \\ + {C}_{21} {x}^{6} + … + {C}_{24} {x}^{3} {y}^{3} + … + {C}_{27} {y}^{6} \\ + …\end{matrix}$$

The following applies to the parameters of this Equation (1):
Z is the sagittal height of the free-form surface at the point x, y, where x²+y²=r². Here, r is the distance from the reference axis of the free-form surface equation (x=0; y=0).

In the free-form surface Equation (1), C₁, C₂, C₃ . . . denote the coefficients of the free-form surface series expansion in powers of x and y.

In the case of a conical base area, cₓ, c_{y} is a constant corresponding to the vertex curvature of a corresponding asphere. Thus, cₓ=1/RDX and c_{y}=1/RDY applies. kₓ and k_{y}, which are also referred to as CCX and CCY, each correspond to a conic constant of a corresponding asphere. Thus, Equation (1) describes a biconical free-form surface.

An alternative possible free-form surface can be produced from a rotationally symmetric reference surface. Such free-form surfaces for reflection surfaces of the mirrors of projection optical units of microlithographic projection exposure apparatuses are known from US 2007-0058269 A1.

Alternatively, free-form surfaces can also be described with the aid of two-dimensional spline surfaces. Examples for this are Bezier curves or non-uniform rational basis splines (NURBS). By way of example, two-dimensional spline surfaces can be described by a grid of points in an xy-plane and associated z-values, or by these points and gradients associated therewith. Depending on the respective type of the spline surface, the complete surface is obtained by interpolation between the grid points using for example polynomials or functions which have specific properties with respect to the continuity and differentiability thereof. Examples for this are analytical functions.

A pupil-defining aperture stop AS is arranged in the region of or on the mirror M3 in the projection optical unit 24; this is indicated in FIG. 2. By way of example, realization options for such an aperture stop are disclosed in WO 2016/188934 A1. Rather than having a single pupil-defining aperture stop AS, the effect thereof can also be adopted by a plurality of pupil-defining partial stops, which are arranged at different points within the projection optical unit 24.

An arrangement plane of the aperture stop AS coincides with a pupil plane of the projection optical unit 24.

The optical design data of the reflection surfaces of the mirrors M1 to M4 of the projection optical unit 24 can be gathered from the further tables below.

Table 3 specifies coordinates of a surface origin of a respective mirror surface and of an area of the object field 5, in relation to a xyz-coordinate system of the image field 11.

The first column specifies the distance of the respective mirror or of the object field 5 from a coordinate origin in the centre of the image field 11 in the z-direction (first column) and in the y-direction (second column).

The third column of Table 3 additionally specifies a tilt value of the respective surface of the mirror M1 to M4 or of the object field 5 in relation to the xy-plane of the image field 11. In the embodiment according to FIG. 2, neither the object field 5 nor the image field 11 are tilted with respect to the x-axis and extend parallel to one another.

Table 4 tabulates, separately for the mirrors M4 to M1, the parameters RDX, RDY, CCX, CCY and, sorted according to the powers in x and y, the values of the coefficients C1, C2, C3 . . . of the free-form surface series expansion according to Equation (1) above.

Mirrors with different signs for the values RDX and RDY have a saddle point-type or minimax basic shape.

Table 3 for FIG. 2

| z-distance [mm] | y-distance [mm] | Tilt about the x-axis [degrees] |
|---|---|---|
| Image field | | |
| 0 | 0 | 0 |
| M4 | | |
| 1052.341063 | 0 | 15.501098 |
| M3 | | |
| 85.619483 | 580.915378 | 10.659276 |
| M2 | | |
| 1817.74382 | 876.483984 | 12.560313 |
| M1 | | |
| 263.752971 | 1956.707604 | 21.254751 |
| Object field | | |
| 2156 | 1379.517221 | 0 |

Table 4 for FIG. 2

| M4 | | |
|---|---|---|
| RDX | −1713.789502 | |
| RDY | −1630.972761 | |
| CCX | 0 | |
| CCY | 0 | |
| x**i | y**j | Coefficient |
| 0 | 1 | −8.808510E−02 |
| 2 | 1 | −9.112639E−08 |
| 0 | 3 | 5.902912E−09 |
| 4 | 0 | −3.180900E−12 |
| 2 | 2 | 5.704739E−12 |
| 0 | 4 | −7.770599E−12 |
| 4 | 1 | −3.760234E−14 |
| 2 | 3 | −3.175126E−14 |
| 0 | 5 | 3.649456E−15 |
| 6 | 0 | −2.863198E−18 |
| 4 | 2 | −9.789031E−19 |
| 2 | 4 | −4.265595E−18 |
| 0 | 6 | 1.071927E−17 |
| 6 | 1 | −1.695599E−20 |
| 4 | 3 | −2.536641E−20 |
| 2 | 5 | −2.486809E−20 |
| 0 | 7 | −1.099456E−19 |
| 8 | 0 | −1.128310E−23 |
| 6 | 2 | −6.555056E−23 |
| 4 | 4 | −6.010323E−23 |
| 2 | 6 | 8.724420E−23 |
| 0 | 8 | −3.350535E−22 |
| 8 | 1 | 1.669458E−25 |
| 6 | 3 | 3.233473E−25 |
| 4 | 5 | −2.112255E−25 |
| 2 | 7 | 4.848322E−25 |
| 0 | 9 | 2.455471E−24 |
| 10 | 0 | 2.190074E−28 |
| 8 | 2 | 1.654072E−27 |
| 6 | 4 | 2.517111E−27 |
| 4 | 6 | 1.214618E−27 |
| 2 | 8 | −3.509487E−27 |
| 0 | 10 | 4.299321E−27 |
| 10 | 1 | −4.097278E−30 |
| 8 | 3 | −1.609570E−29 |
| 6 | 5 | −9.024499E−30 |
| 4 | 7 | 8.044016E−30 |
| 2 | 9 | −7.508526E−30 |
| 0 | 11 | −3.362530E−29 |
| 12 | 0 | −2.817127E−33 |
| 10 | 2 | −2.522775E−32 |
| 8 | 4 | −5.162542E−32 |
| 6 | 6 | −5.104284E−32 |
| 4 | 8 | −2.182309E−33 |
| 2 | 10 | 7.275936E−32 |
| 0 | 12 | −2.728356E−32 |
| 12 | 1 | 5.190002E−35 |
| 10 | 3 | 3.027273E−34 |
| 8 | 5 | 3.943689E−34 |
| 6 | 7 | 5.297904E−35 |
| 4 | 9 | −1.911727E−34 |
| 2 | 11 | 2.320012E−35 |
| 0 | 13 | 2.794200E−34 |
| 14 | 0 | 2.116939E−38 |
| 12 | 2 | 2.173602E−37 |
| 10 | 4 | 5.792844E−37 |
| 6 | 10 | −1.390506E−42 |
| 4 | 12 | 3.955854E−42 |
| 2 | 14 | 4.807288E−42 |
| 0 | 16 | 6.718872E−43 |
| 16 | 1 | 1.392492E−45 |
| 14 | 3 | 1.386113E−44 |
| 12 | 5 | 3.796803E−44 |
| 10 | 7 | 4.229694E−44 |
| 8 | 9 | 1.688964E−44 |
| 6 | 11 | −1.295477E−44 |
| 4 | 13 | −1.904230E−44 |
| 2 | 15 | −6.459948E−45 |
| 0 | 17 | 2.551614E−45 |
| 18 | 0 | 1.460048E−49 |
| 16 | 2 | 1.846243E−48 |
| 14 | 4 | 6.918107E−48 |
| 12 | 6 | 1.478223E−47 |
| 10 | 8 | 1.989426E−47 |
| 8 | 10 | 1.825423E−47 |
| 6 | 12 | −6.581802E−48 |
| 4 | 14 | −1.409239E−47 |
| 2 | 16 | −1.109145E−47 |
| 0 | 18 | −2.289845E−48 |
| 18 | 1 | −2.173200E−51 |
| 16 | 3 | −2.660179E−50 |
| 14 | 5 | −9.153331E−50 |
| 12 | 7 | −1.416227E−49 |
| 10 | 9 | −1.094782E−49 |
| 8 | 11 | −2.473363E−50 |
| 6 | 13 | 6.467927E−50 |
| 4 | 15 | 5.298103E−50 |
| 2 | 17 | 1.907427E−50 |
| 0 | 19 | −4.764273E−52 |
| M3 | | |
| RDX | 1944.036655 | |
| RDY | 5405.334997 | |
| CCX | 0 | |
| CCY | 0 | |
| x**i | y**j | Coefficient |
| 0 | 1 | 2.182169E−01 |
| 2 | 1 | 5.374768E−07 |
| 0 | 3 | 3.368410E−08 |
| 4 | 0 | 1.882522E−10 |
| 2 | 2 | 4.814931E−10 |
| 0 | 4 | 9.895669E−11 |
| 4 | 1 | 7.788498E−13 |
| 2 | 3 | 6.655805E−13 |
| 0 | 5 | 2.429776E−14 |
| 6 | 0 | 2.933456E−16 |
| 4 | 2 | 1.882627E−15 |
| 2 | 4 | 6.696989E−16 |
| 0 | 6 | −7.402579E−16 |
| 6 | 1 | 1.696766E−18 |
| 4 | 3 | 3.040842E−18 |
| 2 | 5 | −1.099018E−18 |
| 0 | 7 | 1.814895E−18 |
| 8 | 0 | −8.465651E−23 |
| 6 | 2 | 4.816016E−22 |
| 4 | 4 | 8.508120E−21 |
| 2 | 6 | 1.060992E−20 |
| 0 | 8 | 7.815341E−20 |
| 8 | 1 | −1.116409E−23 |
| 6 | 3 | −6.898817E−23 |
| 4 | 5 | 2.846265E−22 |
| 2 | 7 | 2.976935E−22 |
| 0 | 9 | 4.324007E−22 |
| 10 | 0 | 8.024701E−27 |
| 8 | 2 | −1.231676E−25 |
| 6 | 4 | −4.735824E−25 |
| 4 | 6 | 4.278970E−24 |
| 2 | 8 | 2.128412E−24 |
| 0 | 10 | −1.134089E−25 |
| 10 | 1 | 3.040809E−28 |
| 8 | 3 | 8.683881E−28 |
| 6 | 5 | −2.322014E−28 |
| 4 | 7 | 3.424304E−26 |
| 2 | 9 | 6.179735E−27 |
| 0 | 11 | −1.054361E−26 |
| 12 | 0 | −1.638002E−32 |
| 10 | 2 | 6.917495E−30 |
| 8 | 4 | 2.450668E−29 |
| 6 | 6 | 5.925965E−30 |
| 4 | 8 | 1.642812E−28 |
| 2 | 10 | −2.386667E−30 |
| 0 | 12 | −4.589280E−29 |
| 12 | 1 | 5.026753E−34 |
| 10 | 3 | 6.136948E−32 |
| 8 | 5 | 1.827506E−31 |
| 6 | 7 | −5.298501E−32 |
| 4 | 9 | 4.686861E−31 |
| 2 | 11 | −6.146641E−32 |
| 0 | 13 | −7.460826E−32 |
| 14 | 0 | −5.233984E−38 |
| 12 | 2 | −4.272331E−35 |
| 10 | 4 | 1.957149E−34 |
| 8 | 6 | 6.365410E−34 |
| 6 | 8 | −8.208325E−34 |
| 4 | 10 | 6.365528E−34 |
| 2 | 12 | −9.232637E−35 |
| 0 | 14 | 1.442545E−35 |
| 14 | 1 | −5.558016E−38 |
| 12 | 3 | −7.260530E−37 |
| 10 | 5 | −1.903403E−37 |
| 8 | 7 | 8.690662E−37 |
| 6 | 9 | −4.244290E−36 |
| 4 | 11 | −4.302095E−37 |
| 2 | 13 | 3.732467E−37 |
| 0 | 15 | 1.478303E−37 |
| 16 | 0 | −1.929915E−41 |
| 14 | 2 | −7.147137E−40 |
| 12 | 4 | −4.323496E−39 |
| 10 | 6 | −2.917091E−39 |
| 8 | 8 | −1.008731E−39 |
| 6 | 10 | −1.177587E−38 |
| 4 | 12 | −3.455714E−39 |
| 2 | 14 | 1.787315E−39 |
| 0 | 16 | −1.865963E−40 |
| 16 | 1 | −2.080615E−43 |
| 14 | 3 | −3.260409E−42 |
| 12 | 5 | −1.215807E−41 |
| 10 | 7 | −7.904989E−42 |
| 8 | 9 | −5.382044E−42 |
| 6 | 11 | −1.880333E−41 |
| 4 | 13 | −6.327925E−42 |
| 2 | 15 | 3.223156E−42 |
| 0 | 17 | −1.083953E−42 |
| 18 | 0 | −3.356665E−48 |
| 16 | 2 | −6.570102E−46 |
| 14 | 4 | −6.355054E−45 |
| 12 | 6 | −1.648753E−44 |
| 10 | 8 | −9.404019E−45 |
| 8 | 10 | −7.297624E−45 |
| 6 | 12 | −1.636786E−44 |
| 4 | 14 | −5.552461E−45 |
| 2 | 16 | 2.837263E−45 |
| 0 | 18 | −1.406749E−45 |
| 18 | 1 | −5.363855E−51 |
| 16 | 3 | −6.119500E−49 |
| 14 | 5 | −4.576056E−48 |
| 12 | 7 | −8.682921E−48 |
| 10 | 9 | −4.344941E−48 |
| 8 | 11 | −3.501716E−48 |
| 6 | 13 | −6.055526E−48 |
| 4 | 15 | −2.007776E−48 |
| 2 | 17 | 1.012732E−48 |
| 0 | 19 | −6.280638E−49 |
| M2 | | |
| RDX | −3324.566351 | |
| RDY | −9483.274483 | |
| CCX | 0 | |
| CCY | 0 | |
| x**i | y**j | Coefficient |
| 0 | 1 | −3.382629E−01 |
| 2 | 1 | −1.071863E−07 |
| 0 | 3 | 2.867961E−08 |
| 4 | 0 | 3.646136E−12 |
| 2 | 2 | 2.026522E−11 |
| 0 | 4 | 2.338237E−11 |
| 4 | 1 | −2.380059E−14 |
| 2 | 3 | −2.851575E−14 |
| 0 | 5 | 2.370796E−14 |
| 6 | 0 | 1.375465E−18 |
| 4 | 2 | 1.816337E−17 |
| 2 | 4 | 3.689470E−17 |
| 0 | 6 | −3.927614E−17 |
| 6 | 1 | −8.861441E−21 |
| 4 | 3 | −3.345473E−20 |
| 2 | 5 | −5.108831E−20 |
| 0 | 7 | 1.254309E−18 |
| 8 | 0 | 3.214031E−24 |
| 6 | 2 | 3.953073E−23 |
| 4 | 4 | −1.934866E−22 |
| 2 | 6 | −3.485323E−21 |
| 0 | 8 | −1.529886E−20 |
| 8 | 1 | −2.518043E−26 |
| 6 | 3 | −2.114232E−25 |
| 4 | 5 | 1.267461E−24 |
| 2 | 7 | 2.626988E−23 |
| 0 | 9 | −4.949649E−23 |
| 10 | 0 | −2.549859E−29 |
| 8 | 2 | −5.812428E−29 |
| 6 | 4 | 1.698673E−27 |
| 4 | 6 | 2.527500E−26 |
| 2 | 8 | 1.669312E−25 |
| 0 | 10 | 1.375769E−24 |
| 10 | 1 | 3.780417E−31 |
| 8 | 3 | 1.499086E−30 |
| 6 | 5 | −2.212016E−30 |
| 4 | 7 | −3.564862E−28 |
| 2 | 9 | −2.508847E−27 |
| 0 | 11 | −4.841319E−27 |
| 12 | 0 | 1.526141E−34 |
| 10 | 2 | −1.668335E−33 |
| 8 | 4 | −6.543909E−33 |
| 6 | 6 | −1.789348E−31 |
| 4 | 8 | 1.133507E−30 |
| 2 | 10 | 4.120133E−30 |
| 0 | 12 | −2.166689E−29 |
| 12 | 1 | −2.725810E−36 |
| 10 | 3 | −5.983401E−36 |
| 8 | 5 | −4.725667E−35 |
| 6 | 7 | 2.372085E−33 |
| 4 | 9 | 9.674447E−33 |
| 2 | 11 | 6.880258E−32 |
| 0 | 13 | 2.104488E−31 |
| 14 | 0 | −5.145899E−40 |
| 12 | 2 | 2.019986E−38 |
| 10 | 4 | 6.151038E−38 |
| 8 | 6 | 2.982274E−37 |
| 6 | 8 | −1.709548E−35 |
| 4 | 10 | −1.023535E−34 |
| 2 | 12 | −4.192489E−34 |
| 0 | 14 | −5.171864E−34 |
| 14 | 1 | 8.441310E−42 |
| 12 | 3 | −1.255458E−41 |
| 10 | 5 | 5.441572E−40 |
| 8 | 7 | 5.400383E−39 |
| 6 | 9 | 7.253605E−38 |
| 4 | 11 | 3.560909E−37 |
| 2 | 13 | 6.153482E−37 |
| 0 | 15 | −4.737862E−37 |
| 16 | 0 | 1.009312E−45 |
| 14 | 2 | −8.690749E−44 |
| 12 | 4 | −7.389234E−43 |
| 10 | 6 | −1.046126E−41 |
| 8 | 8 | −5.665240E−41 |
| 6 | 10 | −1.456557E−40 |
| 4 | 12 | −2.825150E−40 |
| 2 | 14 | 2.217120E−39 |
| 0 | 16 | 5.617953E−39 |
| 16 | 1 | −5.943041E−48 |
| 14 | 3 | 4.510326E−46 |
| 12 | 5 | 5.758296E−45 |
| 10 | 7 | 5.731059E−44 |
| 8 | 9 | 2.046469E−43 |
| 6 | 11 | −1.864067E−44 |
| 4 | 13 | −1.444615E−42 |
| 2 | 15 | −1.058514E−41 |
| 0 | 17 | −1.377045E−41 |
| 18 | 0 | −1.479107E−51 |
| 16 | 2 | 3.466199E−50 |
| 14 | 4 | −1.381294E−48 |
| 12 | 6 | −1.826969E−47 |
| 10 | 8 | −1.325469E−46 |
| 8 | 10 | −3.175971E−46 |
| 6 | 12 | 5.512598E−46 |
| 4 | 14 | 4.037566E−45 |
| 2 | 16 | 1.675399E−44 |
| 0 | 18 | 1.574392E−44 |
| 18 | 1 | 5.882889E−54 |
| 16 | 3 | −1.000900E−52 |
| 14 | 5 | 2.138644E−51 |
| 12 | 7 | 1.999396E−50 |
| 10 | 9 | 1.122599E−49 |
| 8 | 11 | 1.704435E−49 |
| 6 | 13 | −6.225197E−49 |
| 4 | 15 | −3.181412E−48 |
| 2 | 17 | −9.754343E−48 |
| 0 | 19 | −7.315424E−48 |
| M1 | | |
| RDX | −1202.543664 | |
| RDY | −1250.239722 | |
| CCX | 0 | |
| CCY | 0 | |
| x**i | y**j | Coefficient |
| 0 | 1 | −1.608492E−01 |
| 2 | 1 | −4.553729E−06 |
| 0 | 3 | 3.531343E−06 |
| 4 | 0 | −5.383125E−08 |
| 2 | 2 | −1.036445E−08 |
| 0 | 4 | 1.175888E−08 |
| 4 | 1 | −3.605367E−10 |
| 2 | 3 | −7.632990E−12 |
| 0 | 5 | 1.276139E−11 |
| 6 | 0 | 5.814080E−13 |
| 4 | 2 | −7.904053E−13 |
| 2 | 4 | −2.462679E−15 |
| 0 | 6 | −7.187144E−16 |
| 6 | 1 | 5.227958E−15 |
| 4 | 3 | −3.444078E−16 |
| 2 | 5 | −4.638409E−18 |
| 0 | 7 | −9.529463E−18 |
| 8 | 0 | 4.879792E−17 |
| 6 | 2 | 1.595287E−17 |
| 4 | 4 | 6.873424E−19 |
| 2 | 6 | 2.433790E−20 |
| 0 | 8 | −1.420795E−21 |
| 8 | 1 | 3.140876E−19 |
| 6 | 3 | 1.635033E−20 |
| 4 | 5 | −2.822595E−22 |
| 2 | 7 | 3.354631E−23 |
| 0 | 9 | 2.177824E−24 |
| 10 | 0 | −1.129971E−22 |
| 8 | 2 | 6.858662E−22 |
| 6 | 4 | −4.976489E−24 |
| 4 | 6 | −1.902997E−24 |
| 2 | 8 | −9.626517E−26 |
| 0 | 10 | −1.972173E−27 |
| 10 | 1 | −5.070592E−25 |
| 8 | 3 | 3.244055E−25 |
| 6 | 5 | −2.529376E−27 |
| 4 | 7 | 8.607357E−29 |
| 2 | 9 | −1.435733E−28 |
| 0 | 11 | 1.735592E−30 |
| 12 | 0 | −2.123660E−26 |
| 10 | 2 | −2.078327E−28 |
| 8 | 4 | −7.541069E−28 |
| 6 | 6 | 3.280078E−29 |
| 4 | 8 | 1.534835E−30 |
| 2 | 10 | 5.992828E−32 |
| 0 | 12 | 1.406172E−33 |
| 12 | 1 | −1.759678E−28 |
| 10 | 3 | 3.964315E−30 |
| 8 | 5 | −4.740502E−31 |
| 6 | 7 | 2.032458E−33 |
| 4 | 9 | −1.583307E−33 |
| 2 | 11 | 5.971554E−35 |
| 0 | 13 | −3.170590E−36 |
| 14 | 0 | −2.925593E−31 |
| 12 | 2 | −5.349341E−31 |
| 10 | 4 | 1.124492E−32 |
| 8 | 6 | 1.238620E−33 |
| 6 | 8 | −6.048986E−35 |
| 4 | 10 | −1.482595E−36 |
| 2 | 12 | −1.615024E−37 |
| 0 | 14 | 3.224503E−39 |
| 14 | 1 | −1.840085E−33 |
| 12 | 3 | −6.484121E−34 |
| 10 | 5 | 4.202589E−36 |
| 8 | 7 | 8.323025E−37 |
| 6 | 9 | 1.140934E−38 |
| 4 | 11 | 2.886884E−39 |
| 2 | 13 | −8.325232E−42 |
| 0 | 15 | 3.719157E−42 |
| 16 | 0 | −3.096944E−38 |
| 14 | 2 | −4.575138E−36 |
| 12 | 4 | 5.179296E−38 |
| 10 | 6 | −3.239485E−38 |
| 8 | 8 | −1.873420E−39 |
| 6 | 10 | 1.283441E−40 |
| 4 | 12 | 2.020349E−42 |
| 2 | 14 | 2.576550E−43 |
| 0 | 16 | −6.193179E−45 |
| 16 | 1 | −6.350078E−41 |
| 14 | 3 | −5.622070E−39 |
| 12 | 5 | 9.077445E−40 |
| 10 | 7 | −6.493625E−41 |
| 8 | 9 | −2.768084E−42 |
| 6 | 11 | 1.025629E−43 |
| 4 | 13 | −2.297136E−45 |
| 2 | 15 | 1.238093E−46 |
| 0 | 17 | −5.677907E−48 |
| 18 | 0 | −1.005481E−44 |
| 16 | 2 | −1.322724E−45 |
| 14 | 4 | −3.415610E−42 |
| 12 | 6 | 8.359513E−43 |
| 10 | 8 | −5.006957E−44 |
| 8 | 10 | −1.314784E−45 |
| 6 | 12 | 1.840471E−47 |
| 4 | 14 | −2.599925E−48 |
| 2 | 16 | −6.227256E−50 |
| 0 | 18 | 5.924167E−52 |
| 18 | 1 | −9.759547E−48 |
| 16 | 3 | 3.668009E−47 |
| 14 | 5 | −8.212843E−46 |
| 12 | 7 | 2.482996E−46 |
| 10 | 9 | −1.427232E−47 |
| 8 | 11 | −1.974772E−49 |
| 6 | 13 | −4.441671E−51 |
| 4 | 15 | −6.928630E−52 |
| 2 | 17 | −4.009669E−53 |
| 0 | 19 | 1.054394E−54 |

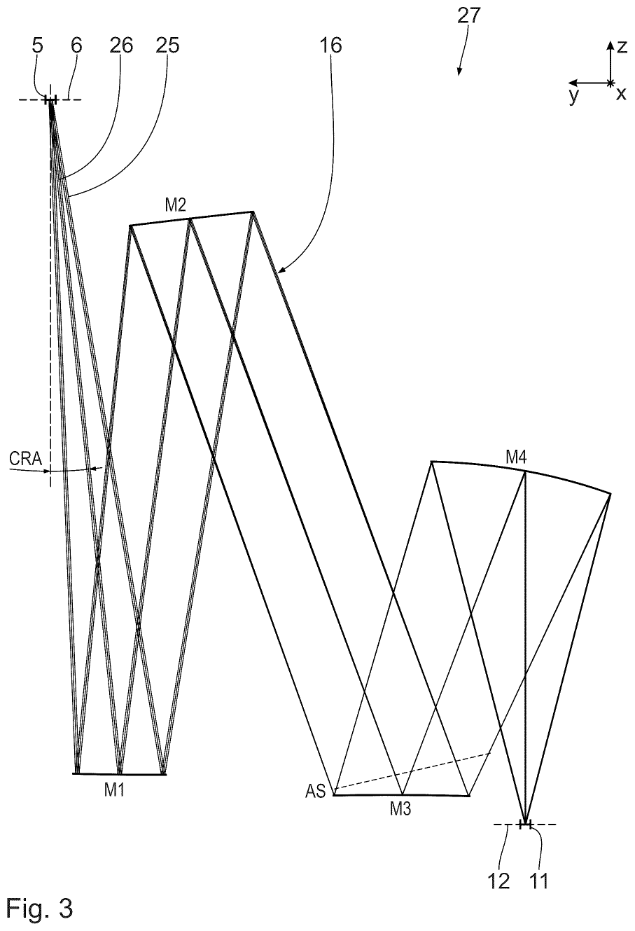

FIG. 3 shows a further embodiment of a projection optical unit or imaging optical unit 27, which can be used in the projection exposure apparatus 1 instead of the projection optical unit 10 of the embodiment according to FIG. 1. Components and functions corresponding to those which have already been explained above in conjunction with FIGS. 1 and 2, and in particular in conjunction with FIG. 2, are denoted by the same reference signs and are not discussed in detail again.

A ring-field radius of the image field 11 is 80 mm in the projection optical unit 27. In the projection optical unit 27, the image field dimensions in the x- and y-directions are the same as for the projection optical unit 24.

Core parameters of the optical design are tabulated again below in relation to the projection optical unit 27:

Table 1 for FIG. 3

| Used wavelength | 13.5 | nm |
|---|---|---|
| Image-side numerical aperture | 0.25 | |
| Imaging scale | −4.00 | |
| Chief ray angle CRA | 5.86° | |
| Etendue | 4.06 | mm² |
| Mean wavefront aberration RMS | 17.57 | mλ |
| Overall transmission | 17.59% | |
| Position of the entrance pupil (x) | 4095.77 | mm |
| Position of the entrance pupil (y) | −40778.74 | mm |
| Object-image offset | 1413.37 | mm |
| Working distance (M3 to image field) | 81 | mm |
| z-distance between the object field and | 2156.00 | mm |
| image field | | |
| Angle between object plane and image | 0.0° | |
| plane | | |
| Installation space requirement xyz | (758 × 1600 × 1742) | mm |

Table 2 for FIG. 3

| | M1 | M2 | M3 | M4 |
|---|---|---|---|---|
| Max. angle of incidence/° | 9.4 | 14.8 | 22.9 | 15.5 |
| Min. angle of incidence/° | 3.9 | 12.5 | 17.9 | 5.3 |
| Mirror extent (x)/mm | 306.2 | 758.3 | 431.7 | 560.4 |
| Mirror extent (y)/mm | 252.8 | 353.9 | 393.7 | 543.4 |
| Max. mirror diameter/mm | 306.8 | 758.4 | 437.0 | 561.0 |

The largest angle of incidence of the imaging light 16 on the mirrors M1 to M4 is on the mirror M3 and is 22.9°. Thus, an angle of incidence of less than 25° for all individual rays is present on all mirrors M1 to M4 of the projection optical unit 27.

The minimum angle of incidence is present on the mirror M1 and is 3.9°. An angle-of-incidence bandwidth between the minimum angle of incidence and the maximum angle of incidence is less than 10° for all mirrors M1 to M4 and is no more than 6° for each of mirrors M1 to M3. The smallest angle-of-incidence bandwidth, that is to say the difference between the maximum and the minimum angle of incidence, is present on the mirror M2 and is less than 2.5° there.

None of the mirrors M1 to M4 have a diameter greater than 760 mm. With respect to the x-extent, the mirror M2 is the largest mirror. In particular, the mirror M2 has a greater x-extent than the last mirror M4 of the projection optical unit 27.

The mean wavefront aberration RMS is less than 20 mλ in the projection optical unit 27.

The image-side numerical aperture of the projection optical unit 27 is 0.25.

A maximum x/y-aspect ratio of the surface extents is at the mirror M2 in the projection optical unit 27 and is 2.14 there.

The overall transmission is 17.59% in the projection optical unit 27.

The polarization rotation of linearly polarized imaging light 16 in the imaging beam path of the projection optical unit 27 between the object field 5 and the image field 11 is approximately 2.8°.

The optical design data for the projection optical unit 27 according to FIG. 3 are tabulated in turn below, in the same format that was already explained above in relation to the embodiment according to FIG. 2.

Table 3 for FIG. 3

| z-distance [mm] | y-distance [mm] | Tilt about the x-axis [degrees] |
|---|---|---|
| Image field | | |
| 0 | 0 | 0 |
| M4 | | |
| 1052.151834 | 0 | 15.511974 |
| M3 | | |
| 85.639487 | 581.289186 | 10.665766 |
| M2 | | |
| 1816.248985 | 876.871977 | 12.551063 |
| M1 | | |
| 262.173154 | 1956.763329 | 21.244435 |
| Object field | | |
| 2156 | 1413.368133 | 0 |

Table 4 for FIG. 3

| M4 | | |
|---|---|---|
| RDX | −1718.361974 | |
| RDY | −1630.972683 | |
| CCX | 0 | |
| CCY | 0 | |
| x**i | y**j | Coefficient |
| 0 | 1 | −8.958776E−02 |
| 2 | 1 | −9.203320E−08 |
| 0 | 3 | 5.439527E−09 |
| 4 | 0 | −3.058412E−12 |
| 2 | 2 | 6.174640E−12 |
| 0 | 4 | −7.522104E−12 |
| 4 | 1 | −3.783620E−14 |
| 2 | 3 | −3.220679E−14 |
| 0 | 5 | 2.647345E−15 |
| 6 | 0 | −2.301182E−18 |
| 4 | 2 | −1.017562E−18 |
| 2 | 4 | −3.208626E−18 |
| 0 | 6 | 1.298458E−17 |
| 6 | 1 | −3.692393E−20 |
| 4 | 3 | −5.869952E−20 |
| 2 | 5 | −5.103198E−20 |
| 0 | 7 | −8.809417E−20 |
| 8 | 0 | −5.073881E−23 |
| 6 | 2 | −1.098772E−22 |
| 4 | 4 | 1.183205E−23 |
| 2 | 6 | 4.135545E−23 |
| 0 | 8 | −4.805095E−22 |
| 8 | 1 | 1.404190E−24 |
| 6 | 3 | 3.088309E−24 |
| 4 | 5 | 1.822223E−24 |
| 2 | 7 | 1.581019E−24 |
| 0 | 9 | 2.506186E−24 |
| 10 | 0 | 2.036646E−27 |
| 8 | 2 | 7.583794E−27 |
| 6 | 4 | 3.749259E−27 |
| 4 | 6 | −1.063745E−27 |
| 2 | 8 | −1.846348E−27 |
| 0 | 10 | 7.439352E−27 |
| 10 | 1 | −5.308849E−29 |
| 8 | 3 | −1.791125E−28 |
| 6 | 5 | −1.699788E−28 |
| 4 | 7 | −6.460812E−29 |
| 2 | 9 | −3.708372E−29 |
| 0 | 11 | −4.750018E−29 |
| 12 | 0 | −4.826737E−32 |
| 10 | 2 | −2.550668E−31 |
| 8 | 4 | −2.809812E−31 |
| 6 | 6 | −1.296886E−31 |
| 4 | 8 | 2.312623E−32 |
| 2 | 10 | 3.322372E−32 |
| 0 | 12 | −6.684701E−32 |
| 12 | 1 | 1.188398E−33 |
| 10 | 3 | 5.588491E−33 |
| 8 | 5 | 7.828409E−33 |
| 6 | 7 | 5.177536E−33 |
| 4 | 9 | 1.146493E−33 |
| 2 | 11 | 5.680166E−34 |
| 0 | 13 | 6.281564E−34 |
| 14 | 0 | 6.629312E−37 |
| 12 | 2 | 4.558611E−36 |
| 10 | 4 | 7.529084E−36 |
| 8 | 6 | 7.867152E−36 |
| 6 | 8 | 3.746548E−36 |
| 4 | 10 | −5.719726E−37 |
| 2 | 12 | −1.080816E−37 |
| 0 | 14 | 3.392424E−37 |
| 14 | 1 | −1.563712E−38 |
| 12 | 3 | −9.550645E−38 |
| 10 | 5 | −1.836836E−37 |
| 8 | 7 | −1.763546E−37 |
| 6 | 9 | −9.076810E−38 |
| 4 | 11 | −5.780125E−39 |
| 2 | 13 | −6.975318E−39 |
| 0 | 15 | −5.708644E−39 |
| 16 | 0 | −4.898875E−42 |
| 14 | 2 | −4.175324E−41 |
| 12 | 4 | −8.952951E−41 |
| 10 | 6 | −1.316286E−40 |
| 8 | 8 | −1.457488E−40 |
| 6 | 10 | −3.561932E−41 |
| 4 | 12 | 7.311069E−42 |
| 2 | 14 | −3.710146E−42 |
| 0 | 16 | −1.471567E−42 |
| 16 | 1 | 1.118489E−43 |
| 14 | 3 | 8.433103E−43 |
| 12 | 5 | 2.085672E−42 |
| 10 | 7 | 2.699934E−42 |
| 8 | 9 | 2.123616E−42 |
| 6 | 11 | 7.511531E−43 |
| 4 | 13 | −6.338613E−44 |
| 2 | 15 | 6.709825E−44 |
| 0 | 17 | 3.389982E−44 |
| 18 | 0 | 1.505551E−47 |
| 16 | 2 | 1.541238E−46 |
| 14 | 4 | 4.023052E−46 |
| 12 | 6 | 7.133920E−46 |
| 10 | 8 | 1.119568E−45 |
| 8 | 10 | 9.361065E−46 |
| 6 | 12 | 2.247014E−47 |
| 4 | 14 | −2.050393E−47 |
| 2 | 16 | 2.884056E−47 |
| 0 | 18 | 5.387059E−48 |
| 18 | 1 | −3.355919E−49 |
| 16 | 3 | −3.009031E−48 |
| 14 | 5 | −9.134997E−48 |
| 12 | 7 | −1.488706E−47 |
| 10 | 9 | −1.589345E−47 |
| 8 | 11 | −1.004847E−47 |
| 6 | 13 | −1.880511E−48 |
| 4 | 15 | 5.475794E−49 |
| 2 | 17 | −3.047415E−49 |
| 0 | 19 | −9.727850E−50 |
| M3 | | |
| RDX | 1950.769311 | |
| RDY | 5405.33455 | |
| CCX | 0 | |
| CCY | 0 | |
| x**i | y**j | Coefficient |
| 0 | 1 | 2.211959E−01 |
| 2 | 1 | 5.363149E−07 |
| 0 | 3 | 3.395479E−08 |
| 4 | 0 | 1.864443E−10 |
| 2 | 2 | 4.823368E−10 |
| 0 | 4 | 9.157018E−11 |
| 4 | 1 | 7.645753E−13 |
| 2 | 3 | 6.891428E−13 |
| 0 | 5 | −2.570660E−14 |
| 6 | 0 | 2.467281E−16 |
| 4 | 2 | 1.618139E−15 |
| 2 | 4 | 8.325315E−16 |
| 0 | 6 | −8.820476E−16 |
| 6 | 1 | 6.337835E−19 |
| 4 | 3 | 2.254354E−19 |
| 2 | 5 | −4.831058E−19 |
| 0 | 7 | 1.843931E−18 |
| 8 | 0 | 1.040700E−21 |
| 6 | 2 | −6.931574E−21 |
| 4 | 4 | −5.203138E−21 |
| 2 | 6 | 1.117601E−20 |
| 0 | 8 | 7.896627E−20 |
| 8 | 1 | 2.520620E−23 |
| 6 | 3 | −7.530962E−23 |
| 4 | 5 | 2.702727E−22 |
| 2 | 7 | 2.957338E−22 |
| 0 | 9 | 4.321044E−22 |
| 10 | 0 | 2.324394E−27 |
| 8 | 2 | 1.716953E−25 |
| 6 | 4 | −3.636255E−25 |
| 4 | 6 | 4.395988E−24 |
| 2 | 8 | 2.130226E−24 |
| 0 | 10 | −1.174848E−25 |
| 10 | 1 | −2.162324E−28 |
| 8 | 3 | 1.562169E−27 |
| 6 | 5 | 2.219468E−29 |
| 4 | 7 | 3.452406E−26 |
| 2 | 9 | 6.192937E−27 |
| 0 | 11 | −1.053470E−26 |
| 12 | 0 | −1.345201E−30 |
| 10 | 2 | 3.487516E−30 |
| 8 | 4 | 2.301171E−29 |
| 6 | 6 | 6.508609E−30 |
| 4 | 8 | 1.638736E−28 |
| 2 | 10 | −2.420174E−30 |
| 0 | 12 | −4.587658E−29 |
| 12 | 1 | −2.759759E−32 |
| 10 | 3 | 5.445478E−32 |
| 8 | 5 | 1.784350E−31 |
| 6 | 7 | −4.197042E−32 |
| 4 | 9 | 4.689537E−31 |
| 2 | 11 | −6.143645E−32 |
| 0 | 13 | −7.467778E−32 |
| 14 | 0 | 9.162545E−36 |
| 12 | 2 | −4.524112E−34 |
| 10 | 4 | 2.012209E−34 |
| 8 | 6 | 6.747699E−34 |
| 6 | 8 | −7.939156E−34 |
| 4 | 10 | 6.439473E−34 |
| 2 | 12 | −9.179677E−35 |
| 0 | 14 | 1.444574E−35 |
| 14 | 1 | 2.497393E−38 |
| 12 | 3 | −3.240023E−36 |
| 10 | 5 | 1.046025E−37 |
| 8 | 7 | 9.506375E−37 |
| 6 | 9 | −4.333504E−36 |
| 4 | 11 | −4.314460E−37 |
| 2 | 13 | 3.739944E−37 |
| 0 | 15 | 1.480508E−37 |
| 16 | 0 | −4.495069E−41 |
| 14 | 2 | 2.446468E−39 |
| 12 | 4 | −8.023350E−39 |
| 10 | 6 | −2.675986E−39 |
| 8 | 8 | −9.165381E−40 |
| 6 | 10 | −1.193130E−38 |
| 4 | 12 | −3.489656E−39 |
| 2 | 14 | 1.791866E−39 |
| 0 | 16 | −1.871617E−40 |
| 16 | 1 | 2.125963E−42 |
| 14 | 3 | 3.071722E−41 |
| 12 | 5 | −1.554874E−42 |
| 10 | 7 | −1.564685E−41 |
| 8 | 9 | −2.155536E−42 |
| 6 | 11 | −1.761698E−41 |
| 4 | 13 | −6.269715E−42 |
| 2 | 15 | 3.245717E−42 |
| 0 | 17 | −1.082520E−42 |
| 18 | 0 | 1.924996E−46 |
| 16 | 2 | 2.443271E−44 |
| 14 | 4 | 1.066775E−43 |
| 12 | 6 | 1.074146E−44 |
| 10 | 8 | −3.435471E−44 |
| 8 | 10 | 5.302669E−45 |
| 6 | 12 | −1.291405E−44 |
| 4 | 14 | −5.259902E−45 |
| 2 | 16 | 2.876640E−45 |
| 0 | 18 | −1.397427E−45 |
| 18 | 1 | 3.244719E−48 |
| 16 | 3 | 5.195045E−47 |
| 14 | 5 | 1.079975E−46 |
| 12 | 7 | 9.818738E−49 |
| 10 | 9 | −2.530050E−47 |
| 8 | 11 | 9.709033E−48 |
| 6 | 13 | −3.512977E−48 |
| 4 | 15 | −1.753958E−48 |
| 2 | 17 | 1.035584E−48 |
| 0 | 19 | −6.191131E−49 |
| M2 | | |
| RDX | −3324.161871 | |
| RDY | −9483.273952 | |
| CCX | 0 | |
| CCY | 0 | |
| x**i | y**j | Coefficient |
| 0 | 1 | −3.352548E−01 |
| 2 | 1 | −1.066975E−07 |
| 0 | 3 | 2.828071E−08 |
| 4 | 0 | 3.674763E−12 |
| 2 | 2 | 2.111023E−11 |
| 0 | 4 | 1.836277E−11 |
| 4 | 1 | −2.399790E−14 |
| 2 | 3 | −2.765283E−14 |
| 0 | 5 | 7.073497E−14 |
| 6 | 0 | 1.435970E−18 |
| 4 | 2 | 1.591669E−17 |
| 2 | 4 | −5.270059E−19 |
| 0 | 6 | −5.617890E−16 |
| 6 | 1 | −9.649586E−21 |
| 4 | 3 | −2.256619E−20 |
| 2 | 5 | 4.525704E−19 |
| 0 | 7 | 5.503615E−18 |
| 8 | 0 | 1.066142E−23 |
| 6 | 2 | 1.909708E−22 |
| 4 | 4 | 4.811811E−22 |
| 2 | 6 | −8.495791E−21 |
| 0 | 8 | −3.175982E−20 |
| 8 | 1 | −1.732938E−25 |
| 6 | 3 | −1.299077E−24 |
| 4 | 5 | −2.361479E−24 |
| 2 | 7 | 6.539053E−23 |
| 0 | 9 | −4.459133E−23 |
| 10 | 0 | −2.078057E−28 |
| 8 | 2 | −3.119694E−27 |
| 6 | 4 | −2.336766E−26 |
| 4 | 6 | −3.032869E−26 |
| 2 | 8 | −3.098679E−26 |
| 0 | 10 | 1.492980E−24 |
| 10 | 1 | 5.797700E−30 |
| 8 | 3 | 6.751324E−29 |
| 6 | 5 | 3.639691E−28 |
| 4 | 7 | 3.180267E−28 |
| 2 | 9 | −2.168906E−27 |
| 0 | 11 | −4.723878E−27 |
| 12 | 0 | 2.019976E−33 |
| 10 | 2 | −5.852430E−33 |
| 8 | 4 | −2.695835E−31 |
| 6 | 6 | −1.615166E−30 |
| 4 | 8 | −1.625220E−30 |
| 2 | 10 | 6.437924E−30 |
| 0 | 12 | −2.309351E−29 |
| 12 | 1 | −7.225996E−35 |
| 10 | 3 | −7.881430E−34 |
| 8 | 5 | −1.560118E−33 |
| 6 | 7 | 6.447943E−35 |
| 4 | 9 | 1.555573E−32 |
| 2 | 11 | 5.635467E−32 |
| 0 | 13 | 2.076124E−31 |
| 14 | 0 | −8.318004E−39 |
| 12 | 2 | 5.361877E−37 |
| 10 | 4 | 8.027278E−36 |
| 8 | 6 | 1.445372E−35 |
| 6 | 8 | 8.520528E−36 |
| 4 | 10 | −1.298243E−34 |
| 2 | 12 | −4.262780E−34 |
| 0 | 14 | −5.039513E−34 |
| 14 | 1 | 3.970989E−40 |
| 12 | 3 | 1.164289E−39 |
| 10 | 5 | −3.866255E−38 |
| 8 | 7 | −1.459056E−38 |
| 6 | 9 | 1.196716E−37 |
| 4 | 11 | 4.874640E−37 |
| 2 | 13 | 7.427533E−37 |
| 0 | 15 | −4.298059E−37 |
| 16 | 0 | −1.748162E−45 |
| 14 | 2 | −4.270297E−42 |
| 12 | 4 | −3.026188E−41 |
| 10 | 6 | 1.248911E−40 |
| 8 | 8 | −1.998889E−40 |
| 6 | 10 | −1.050110E−39 |
| 4 | 12 | −1.788739E−40 |
| 2 | 14 | 2.544837E−39 |
| 0 | 16 | 5.525771E−39 |
| 16 | 1 | −5.109127E−46 |
| 14 | 3 | 1.840306E−44 |
| 12 | 5 | 1.588798E−43 |
| 10 | 7 | −3.775213E−43 |
| 8 | 9 | 8.934178E−43 |
| 6 | 11 | 3.463040E−42 |
| 4 | 13 | −4.296729E−42 |
| 2 | 15 | −1.423987E−41 |
| 0 | 17 | −1.439764E−41 |
| 18 | 0 | 3.907694E−50 |
| 16 | 2 | 5.376711E−48 |
| 14 | 4 | −4.447702E−47 |
| 12 | 6 | −3.808184E−46 |
| 10 | 8 | 9.638937E−46 |
| 8 | 10 | −1.626263E−45 |
| 6 | 12 | −5.468425E−45 |
| 4 | 14 | 1.260476E−44 |
| 2 | 16 | 2.570582E−44 |
| 0 | 18 | 1.785736E−44 |
| 18 | 1 | −2.187170E−52 |
| 16 | 3 | −1.302474E−50 |
| 14 | 5 | 6.509474E−50 |
| 12 | 7 | 3.255861E−49 |
| 10 | 9 | −1.115572E−48 |
| 8 | 11 | 1.261492E−48 |
| 6 | 13 | 3.423631E−48 |
| 4 | 15 | −1.147906E−47 |
| 2 | 17 | −1.714431E−47 |
| 0 | 19 | −9.157444E−48 |
| M1 | | |
| RDX | −1202.543882 | |
| RDY | −1250.019936 | |
| CCX | 0 | |
| CCY | 0 | |
| x**i | y**j | Coefficient |
| 0 | 1 | −1.563425E−01 |
| 2 | 1 | −4.531102E−06 |
| 0 | 3 | 3.532752E−06 |
| 4 | 0 | −5.415418E−08 |
| 2 | 2 | −1.030738E−08 |
| 0 | 4 | 1.175951E−08 |
| 4 | 1 | −3.615123E−10 |
| 2 | 3 | −7.628358E−12 |
| 0 | 5 | 1.275970E−11 |
| 6 | 0 | 5.882071E−13 |
| 4 | 2 | −7.905420E−13 |
| 2 | 4 | −2.531874E−15 |
| 0 | 6 | −7.172501E−16 |
| 6 | 1 | 5.248282E−15 |
| 4 | 3 | −3.433417E−16 |
| 2 | 5 | −4.593723E−18 |
| 0 | 7 | −9.529411E−18 |
| 8 | 0 | 4.858136E−17 |
| 6 | 2 | 1.596273E−17 |
| 4 | 4 | 6.863731E−19 |
| 2 | 6 | 2.438932E−20 |
| 0 | 8 | −1.421542E−21 |
| 8 | 1 | 3.137142E−19 |
| 6 | 3 | 1.636644E−20 |
| 4 | 5 | −2.829057E−22 |
| 2 | 7 | 3.344288E−23 |
| 0 | 9 | 2.180154E−24 |
| 10 | 0 | −1.507050E−22 |
| 8 | 2 | 6.871118E−22 |
| 6 | 4 | −4.947241E−24 |
| 4 | 6 | −1.900225E−24 |
| 2 | 8 | −9.619657E−26 |
| 0 | 10 | −1.974095E−27 |
| 10 | 1 | −5.922204E−25 |
| 8 | 3 | 3.235591E−25 |
| 6 | 5 | −2.634030E−27 |
| 4 | 7 | 8.633161E−29 |
| 2 | 9 | −1.435327E−28 |
| 0 | 11 | 1.737266E−30 |
| 12 | 0 | −2.089061E−26 |
| 10 | 2 | −2.240346E−28 |
| 8 | 4 | −7.627932E−28 |
| 6 | 6 | 3.269388E−29 |
| 4 | 8 | 1.531835E−30 |
| 2 | 10 | 5.986287E−32 |
| 0 | 12 | 1.407014E−33 |
| 12 | 1 | −1.774134E−28 |
| 10 | 3 | 3.891570E−30 |
| 8 | 5 | −4.738407E−31 |
| 6 | 7 | 2.078089E−33 |
| 4 | 9 | −1.588538E−33 |
| 2 | 11 | 6.002127E−35 |
| 0 | 13 | −3.174629E−36 |
| 14 | 0 | −2.659417E−31 |
| 12 | 2 | −5.413750E−31 |
| 10 | 4 | 1.100674E−32 |
| 8 | 6 | 1.246581E−33 |
| 6 | 8 | −6.055077E−35 |
| 4 | 10 | −1.488641E−36 |
| 2 | 12 | −1.616775E−37 |
| 0 | 14 | 3.230342E−39 |
| 14 | 1 | −1.707796E−33 |
| 12 | 3 | −6.490427E−34 |
| 10 | 5 | 4.220081E−36 |
| 8 | 7 | 8.171585E−37 |
| 6 | 9 | 1.153092E−38 |
| 4 | 11 | 2.891004E−39 |
| 2 | 13 | −8.898599E−42 |
| 0 | 15 | 3.717090E−42 |
| 16 | 0 | −6.969664E−37 |
| 14 | 2 | −4.371025E−36 |
| 12 | 4 | 6.033881E−38 |
| 10 | 6 | −3.223343E−38 |
| 8 | 8 | −1.884409E−39 |
| 6 | 10 | 1.286094E−40 |
| 4 | 12 | 2.026228E−42 |
| 2 | 14 | 2.579207E−43 |
| 0 | 16 | −6.194114E−45 |
| 16 | 1 | −1.805419E−39 |
| 14 | 3 | −5.737127E−39 |
| 12 | 5 | 9.048566E−40 |
| 10 | 7 | −6.520915E−41 |
| 8 | 9 | −2.755574E−42 |
| 6 | 11 | 1.022544E−43 |
| 4 | 13 | −2.309566E−45 |
| 2 | 15 | 1.237944E−46 |
| 0 | 17 | −5.667040E−48 |
| 18 | 0 | 1.714397E−42 |
| 16 | 2 | −1.467642E−42 |
| 14 | 4 | −3.943840E−42 |
| 12 | 6 | 8.266524E−43 |
| 10 | 8 | −5.059477E−44 |
| 8 | 10 | −1.316345E−45 |
| 6 | 12 | 1.795255E−47 |
| 4 | 14 | −2.619794E−48 |
| 2 | 16 | −6.312609E−50 |
| 0 | 18 | 5.841591E−52 |
| 18 | 1 | 2.298365E−45 |
| 16 | 3 | −3.955873E−46 |
| 14 | 5 | −1.143973E−45 |
| 12 | 7 | 2.469066E−46 |
| 10 | 9 | −1.452947E−47 |
| 8 | 11 | −2.061163E−49 |
| 6 | 13 | −4.538537E−51 |
| 4 | 15 | −7.007726E−52 |
| 2 | 17 | −4.054179E−53 |
| 0 | 19 | 1.042343E−54 |

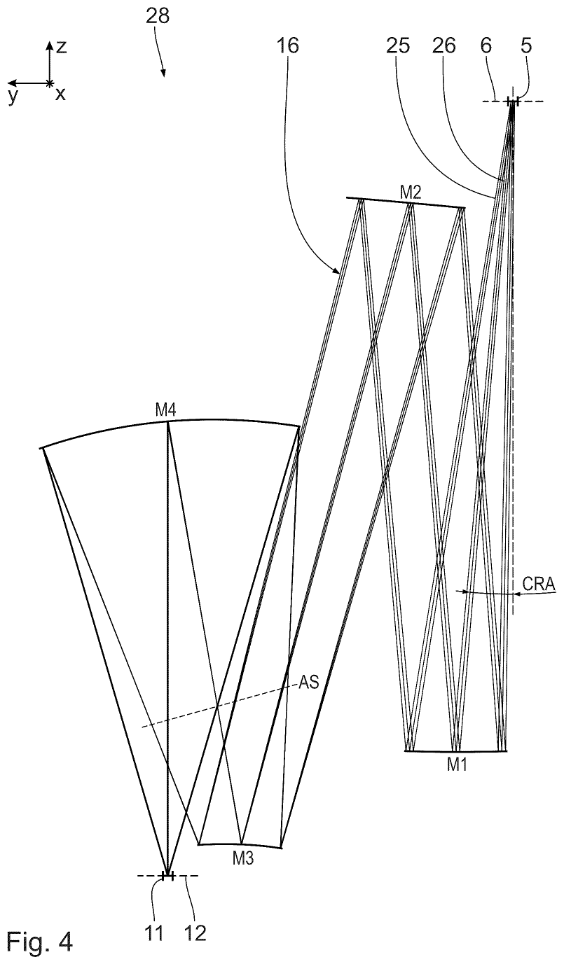

FIG. 4 shows a further embodiment of a projection optical unit or imaging optical unit 28, which can be used in the projection exposure apparatus 1 instead of the projection optical unit 10 of the embodiment according to FIG. 1. Components and functions corresponding to those which have already been explained above in conjunction with FIGS. 1 to 3, and in particular in conjunction with FIGS. 2 and 3, are denoted by the same reference signs and are not discussed in detail again.

The image field 11 of the projection optical unit 28 is rectangular and the x-extent of the image field 11 is 26 mm. The y-extent of the image field 11 is 2.5 mm.

An aperture stop AS can be arranged in the region of an entrance pupil which is located in the beam path of the imaging light 16 between the mirrors M3 and M4.

Tables 1 and 2 below once again summarize certain data of the projection optical unit 28:

Table 1 for FIG. 4

| Used wavelength | 13.5 | nm |
|---|---|---|
| Image-side numerical aperture | 0.28 | |
| Imaging scale | −4.00 | |
| Chief ray angle CRA | 4.99° | |
| Etendue | 5.10 | mm² |
| Mean wavefront aberration RMS | 105.11 | mλ |
| Overall transmission | 19.21% | |
| Position of the entrance pupil (x) | −1787.10 | mm |
| Position of the entrance pupil (y) | −1744.09 | mm |
| Object-image offset | 959.98 | mm |
| Working distance (M3 to image field) | 77 | mm |
| z-distance between the object field | 2155.72 | mm |
| and image field | | |
| Angle between object plane and image | 0.0° | |
| plane | | |
| Installation space requirement xyz | (740 × 1289 × 1808) | mm |

Table 2 for FIG. 4

| | M1 | M2 | M3 | M4 |
|---|---|---|---|---|
| Max. angle of incidence/° | 7.0 | 10.3 | 18.0 | 7.0 |
| Min. angle of incidence/° | 2.6 | 9.4 | 6.5 | 2.6 |
| Mirror extent (x)/mm | 464.9 | 418.3 | 236.1 | 739.6 |
| Mirror extent (y)/mm | 277.2 | 293.6 | 228.5 | 717.7 |
| Max. mirror diameter/mm | 465.7 | 419.3 | 236.8 | 740.4 |

The mirrors M1 to M4 each have very small angle-of-incidence bandwidths, which are less than 12° for all individual rays of the imaging light 16. A very small angle-of-incidence bandwidth, which is less than 2° and even less than 1°, is present on the mirror M2 of the projection optical unit 28. The absolute angles of incidence on the mirrors M1 to M4 are also quite small in each case, specifically less than 20° for all individual rays. In the mirrors M1 and M4, these absolute angles of incidence are even less than 10° and even less than 8° for all individual rays.

None of the mirrors M1 to M4 of the projection optical unit 28 has a diameter which is greater than 750 mm.

A maximum x/y-aspect ratio of the surface extents is at the mirror M1 in the projection optical unit 28 and is 1.68 there.

The image-side numerical aperture of the projection optical unit 28 is 0.28.

The projection optical unit 28 has an overall transmission of 19.21%.

The polarization rotation of linearly polarized imaging light 16 in the imaging beam path of the projection optical unit 28 between the object field 5 and the image field 11 is approximately 0°.

The entrance pupil of the projection optical unit 28 is in the imaging beam path upstream of the object field 5 both in the xz-plane and in the yz-plane, specifically approximately 1750 mm upstream of the object field 5 in the imaging beam path. In particular, a pupil facet mirror of the illumination optical unit 4 may be arranged there.

The optical design data for the projection optical unit 28 according to FIG. 4 are tabulated in turn below, in the same format that was already explained above in relation to the embodiment according to FIG. 2.

Table 3 for FIG. 4

| z-distance [mm] | y-distance [mm] | Tilt about the x-axis [degrees] |
|---|---|---|
| Image field | | |
| 0 | 0 | 0 |
| M4 | | |
| 1265.259208 | 0 | −4.891753 |
| M3 | | |
| 87.643865 | −203.060378 | 2.252342 |
| M2 | | |
| 1874.587205 | −658.154257 | 4.467444 |
| M1 | | |
| 344.596382 | −801.522927 | −0.176651 |
| Object field | | |
| 2155.723202 | −959.975992 | 0 |

Table 4 for FIG. 4

| M4 | | |
|---|---|---|
| RDX | −1459.985984 | |
| RDY | −1471.16496 | |
| CCX | 0 | |
| CCY | 0 | |
| x**i | y**j | Coefficient |
| 0 | 1 | −7.411356E−04 |
| 2 | 1 | −1.817703E−09 |
| 0 | 3 | −1.142046E−10 |
| 4 | 0 | −4.505287E−12 |
| 2 | 2 | −9.337127E−12 |
| 0 | 4 | −5.218128E−12 |
| 4 | 1 | −8.902935E−16 |
| 2 | 3 | −3.582759E−16 |
| 0 | 5 | 3.062720E−15 |
| 6 | 0 | −2.276580E−18 |
| 4 | 2 | −6.683108E−18 |
| 2 | 4 | −7.875132E−18 |
| 0 | 6 | −1.488301E−18 |
| 6 | 1 | −3.286883E−21 |
| 4 | 3 | −1.470188E−20 |
| 2 | 5 | −4.386099E−20 |
| 0 | 7 | −8.991473E−20 |
| 8 | 0 | −3.452340E−24 |
| 6 | 2 | −2.155999E−23 |
| 4 | 4 | −4.893344E−23 |
| 2 | 6 | 2.633672E−23 |
| 0 | 8 | 8.990355E−23 |
| 8 | 1 | 3.023767E−26 |
| 6 | 3 | 2.218767E−25 |
| 4 | 5 | 4.968627E−25 |
| 2 | 7 | 9.922682E−25 |
| 0 | 9 | 1.014563E−24 |
| 10 | 0 | 3.887180E−29 |
| 8 | 2 | 2.997838E−28 |
| 6 | 4 | 9.380474E−28 |
| 4 | 6 | 1.137132E−27 |
| 2 | 8 | −7.444560E−28 |
| 0 | 10 | −1.439654E−27 |
| 10 | 1 | −1.408401E−31 |
| 8 | 3 | −2.327731E−30 |
| 6 | 5 | −4.951165E−30 |
| 4 | 7 | −8.803809E−30 |
| 2 | 9 | −1.213767E−29 |
| 0 | 11 | −6.185665E−30 |
| 12 | 0 | −4.045153E−34 |
| 10 | 2 | −3.641017E−33 |
| 8 | 4 | −9.553028E−33 |
| 6 | 6 | −2.308243E−32 |
| 4 | 8 | −1.346996E−32 |
| 2 | 10 | 8.564910E−33 |
| 0 | 12 | 9.433408E−33 |
| 12 | 1 | 5.750699E−38 |
| 10 | 3 | 1.233052E−35 |
| 8 | 5 | 3.313836E−35 |
| 6 | 7 | 4.657227E−35 |
| 4 | 9 | 7.419267E−35 |
| 2 | 11 | 7.392669E−35 |
| 0 | 13 | 2.015834E−35 |
| 14 | 0 | 2.183652E−39 |
| 12 | 2 | 2.402104E−38 |
| 10 | 4 | 5.321841E−38 |
| 8 | 6 | 1.569644E−37 |
| 6 | 8 | 2.211418E−37 |
| 4 | 10 | 6.886862E−38 |
| 2 | 12 | −4.654317E−38 |
| 0 | 14 | −2.643409E−38 |
| 14 | 1 | 9.268157E−43 |
| 12 | 3 | −2.473635E−41 |
| 10 | 5 | −9.401326E−41 |
| 8 | 7 | −1.324523E−40 |
| 6 | 9 | −1.694528E−40 |
| 4 | 11 | −2.350844E−40 |
| 2 | 13 | −1.759871E−40 |
| 0 | 15 | −2.796266E−41 |
| 16 | 0 | −4.747404E−45 |
| 14 | 2 | −6.265481E−44 |
| 12 | 4 | −1.401714E−43 |
| 10 | 6 | −3.678372E−43 |
| 8 | 8 | −8.212117E−43 |
| 6 | 10 | −6.930776E−43 |
| 4 | 12 | −1.249946E−43 |
| 2 | 14 | 9.437368E−44 |
| 0 | 16 | 2.016067E−44 |
| M3 | | |
| RDX | 993.417469 | |
| RDY | 1047.579204 | |
| CCX | 0 | |
| CCY | 0 | |
| x**i | y**j | Coefficient |
| 0 | 1 | −1.740816E−03 |
| 2 | 1 | −1.564476E−07 |
| 0 | 3 | −2.242914E−07 |
| 4 | 0 | 5.071709E−10 |
| 2 | 2 | 1.035067E−09 |
| 0 | 4 | 6.298150E−10 |
| 4 | 1 | −5.531917E−13 |
| 2 | 3 | −1.604328E−12 |
| 0 | 5 | −2.083537E−12 |
| 6 | 0 | 1.291818E−15 |
| 4 | 2 | 4.819062E−15 |
| 2 | 4 | 8.579477E−15 |
| 0 | 6 | 8.389321E−15 |
| 6 | 1 | 1.331430E−17 |
| 4 | 3 | 3.811486E−17 |
| 2 | 5 | 1.325720E−16 |
| 0 | 7 | 2.818392E−16 |
| 8 | 0 | 7.660155E−20 |
| 6 | 2 | −5.114559E−20 |
| 4 | 4 | −8.478639E−20 |
| 2 | 6 | −1.440522E−18 |
| 0 | 8 | −2.876140E−18 |
| 8 | 1 | −2.248822E−21 |
| 6 | 3 | −6.556521E−21 |
| 4 | 5 | −1.744590E−20 |
| 2 | 7 | −3.022254E−20 |
| 0 | 9 | −2.113127E−20 |
| 10 | 0 | −1.236249E−23 |
| 8 | 2 | 2.701220E−23 |
| 6 | 4 | 1.738656E−24 |
| 4 | 6 | 9.451001E−23 |
| 2 | 8 | 3.054578E−22 |
| 0 | 10 | 3.596652E−22 |
| 10 | 1 | 1.689984E−25 |
| 8 | 3 | 5.727559E−25 |
| 6 | 5 | 1.428133E−24 |
| 4 | 7 | 3.256573E−24 |
| 2 | 9 | 3.468505E−24 |
| 0 | 11 | 2.388918E−25 |
| 12 | 0 | 1.215538E−27 |
| 10 | 2 | −3.416089E−27 |
| 8 | 4 | −3.094976E−27 |
| 6 | 6 | 3.846174E−28 |
| 4 | 8 | −2.371755E−26 |
| 2 | 10 | −3.317170E−26 |
| 0 | 12 | −2.051409E−26 |
| 12 | 1 | −5.749715E−30 |
| 10 | 3 | −2.619638E−29 |
| 8 | 5 | −6.240658E−29 |
| 6 | 7 | −1.669648E−28 |
| 4 | 9 | −2.781630E−28 |
| 2 | 11 | −2.001536E−28 |
| 0 | 13 | 4.202469E−29 |
| 14 | 0 | −6.120780E−32 |
| 12 | 2 | 1.794892E−31 |
| 10 | 4 | 4.684304E−31 |
| 8 | 6 | −2.924202E−31 |
| 6 | 8 | 5.736029E−31 |
| 4 | 10 | 2.234436E−30 |
| 2 | 12 | 1.801868E−30 |
| 0 | 14 | 4.752822E−31 |
| 14 | 1 | 5.404010E−35 |
| 12 | 3 | 4.390788E−34 |
| 10 | 5 | 1.069309E−33 |
| 8 | 7 | 3.263713E−33 |
| 6 | 9 | 7.175869E−33 |
| 4 | 11 | 8.656268E−33 |
| 2 | 13 | 4.525034E−33 |
| 0 | 15 | −1.508141E−33 |
| 16 | 0 | 1.221936E−36 |
| 14 | 2 | −3.237546E−36 |
| 12 | 4 | −1.768236E−35 |
| 10 | 6 | 2.943503E−36 |
| 8 | 8 | 9.790991E−36 |
| 6 | 10 | −4.485353E−35 |
| 4 | 12 | −7.093981E−35 |
| 2 | 14 | −3.856464E−35 |
| 0 | 16 | −1.425716E−36 |
| M2 | | |
| RDX | −12328.55323 | |
| RDY | −14249.78736 | |
| CCX | 0 | |
| CCY | 0 | |
| x**i | y**j | Coefficient |
| 0 | 1 | 8.441191E−03 |
| 2 | 1 | 1.702516E−08 |
| 0 | 3 | 3.597981E−08 |
| 4 | 0 | −3.195563E−12 |
| 2 | 2 | −3.584015E−12 |
| 0 | 4 | −7.192425E−12 |
| 4 | 1 | −1.273679E−15 |
| 2 | 3 | 9.673514E−15 |
| 0 | 5 | 7.429591E−15 |
| 6 | 0 | −2.337422E−17 |
| 4 | 2 | −4.113079E−17 |
| 2 | 4 | −3.482538E−16 |
| 0 | 6 | −1.250780E−15 |
| 6 | 1 | 3.393081E−19 |
| 4 | 3 | −4.824056E−19 |
| 2 | 5 | −1.266943E−18 |
| 0 | 7 | 1.087581E−17 |
| 8 | 0 | 1.841089E−21 |
| 6 | 2 | 4.421445E−21 |
| 4 | 4 | 9.901407E−21 |
| 2 | 6 | 6.548610E−20 |
| 0 | 8 | 1.270313E−19 |
| 8 | 1 | −3.530077E−23 |
| 6 | 3 | 1.269091E−23 |
| 4 | 5 | 1.448321E−22 |
| 2 | 7 | 8.086313E−23 |
| 0 | 9 | −2.340839E−21 |
| 10 | 0 | −9.053332E−26 |
| 8 | 2 | −2.749048E−25 |
| 6 | 4 | −6.741347E−25 |
| 4 | 6 | −1.346474E−24 |
| 2 | 8 | −6.445753E−24 |
| 0 | 10 | −5.433212E−24 |
| 10 | 1 | 1.704017E−27 |
| 8 | 3 | 1.130479E−27 |
| 6 | 5 | −8.654484E−27 |
| 4 | 7 | −1.541699E−26 |
| 2 | 9 | −2.554007E−27 |
| 0 | 11 | 2.001114E−25 |
| 12 | 0 | 2.615771E−30 |
| 10 | 2 | 1.047683E−29 |
| 8 | 4 | 2.303065E−29 |
| 6 | 6 | 4.357951E−29 |
| 4 | 8 | 8.176319E−29 |
| 2 | 10 | 3.392389E−28 |
| 0 | 12 | 2.950021E−28 |
| 12 | 1 | −3.884804E−32 |
| 10 | 3 | −7.029084E−32 |
| 8 | 5 | 2.130590E−31 |
| 6 | 7 | 6.452493E−31 |
| 4 | 9 | 8.960452E−31 |
| 2 | 11 | 1.072324E−31 |
| 0 | 13 | −8.072254E−30 |
| 14 | 0 | −4.143649E−35 |
| 12 | 2 | −2.319745E−34 |
| 10 | 4 | −4.466640E−34 |
| 8 | 6 | −3.691570E−34 |
| 6 | 8 | −5.126553E−34 |
| 4 | 10 | −1.115748E−33 |
| 2 | 12 | −8.633275E−33 |
| 0 | 14 | −1.693128E−32 |
| 14 | 1 | 3.398984E−37 |
| 12 | 3 | 1.036930E−36 |
| 10 | 5 | −1.454444E−36 |
| 8 | 7 | −9.455322E−36 |
| 6 | 9 | −1.608054E−35 |
| 4 | 11 | −2.270646E−35 |
| 2 | 13 | −3.120909E−36 |
| 0 | 15 | 1.281055E−34 |
| 16 | 0 | 2.797219E−40 |
| 14 | 2 | 2.191745E−39 |
| 12 | 4 | 4.806919E−39 |
| 10 | 6 | −3.144938E−39 |
| 8 | 8 | −1.834862E−38 |
| 6 | 10 | −3.041114E−38 |
| 4 | 12 | −4.437899E−38 |
| 2 | 14 | 7.810250E−38 |
| 0 | 16 | 3.822764E−37 |
| M1 | | |
| RDX | −4049.940492 | |
| RDY | −4011.364431 | |
| CCX | 0 | |
| CCY | 0 | |
| x**i | y**j | Coefficient |
| 0 | 1 | −5.481922E−03 |
| 2 | 1 | −6.747788E−09 |
| 0 | 3 | −1.583252E−08 |
| 4 | 0 | 2.277802E−13 |
| 2 | 2 | 2.117441E−12 |
| 0 | 4 | 9.949218E−12 |
| 4 | 1 | 4.564205E−17 |
| 2 | 3 | −1.739245E−14 |
| 0 | 5 | −1.227968E−13 |
| 6 | 0 | 7.151025E−18 |
| 4 | 2 | −2.590453E−17 |
| 2 | 4 | 1.793620E−17 |
| 0 | 6 | 1.120764E−15 |
| 6 | 1 | −1.604675E−19 |
| 4 | 3 | 1.004635E−19 |
| 2 | 5 | 3.727676E−18 |
| 0 | 7 | 2.164669E−17 |
| 8 | 0 | −5.441412E−22 |
| 6 | 2 | 1.816302E−21 |
| 4 | 4 | 8.206931E−21 |
| 2 | 6 | −1.697825E−20 |
| 0 | 8 | −3.319486E−19 |
| 8 | 1 | 1.302569E−23 |
| 6 | 3 | −4.434767E−24 |
| 4 | 5 | −3.219492E−23 |
| 2 | 7 | −5.340782E−22 |
| 0 | 9 | −1.457772E−21 |
| 10 | 0 | 2.421402E−26 |
| 8 | 2 | −4.261739E−26 |
| 6 | 4 | −5.147908E−25 |
| 4 | 6 | −7.349540E−25 |
| 2 | 8 | 3.211751E−24 |
| 0 | 10 | 3.694368E−23 |
| 10 | 1 | −5.067503E−28 |
| 8 | 3 | −1.989270E−28 |
| 6 | 5 | 2.259795E−27 |
| 4 | 7 | 2.745965E−27 |
| 2 | 9 | 4.114472E−26 |
| 0 | 11 | 3.673559E−26 |
| 12 | 0 | −5.865349E−31 |
| 10 | 2 | −3.692018E−32 |
| 8 | 4 | 1.402344E−29 |
| 6 | 6 | 3.771171E−29 |
| 4 | 8 | 2.747047E−29 |
| 2 | 10 | −2.713491E−28 |
| 0 | 12 | −2.126680E−27 |
| 12 | 1 | 9.300679E−33 |
| 10 | 3 | 1.282166E−32 |
| 8 | 5 | −5.168761E−32 |
| 6 | 7 | −1.174732E−31 |
| 4 | 9 | −1.259425E−31 |
| 2 | 11 | −1.596138E−30 |
| 0 | 13 | 1.951698E−31 |
| 14 | 0 | 7.321206E−36 |
| 12 | 2 | 1.458921E−35 |
| 10 | 4 | −1.658061E−34 |
| 8 | 6 | −7.491998E−34 |
| 6 | 8 | −1.098496E−33 |
| 4 | 10 | −4.891952E−34 |
| 2 | 12 | 1.091569E−32 |
| 0 | 14 | 6.247808E−32 |
| 14 | 1 | −6.524460E−38 |
| 12 | 3 | −1.594904E−37 |
| 10 | 5 | 3.026949E−37 |
| 8 | 7 | 1.614172E−36 |
| 6 | 9 | 1.830610E−36 |
| 4 | 11 | 2.652557E−36 |
| 2 | 13 | 2.417602E−35 |
| 0 | 15 | −1.697322E−35 |
| 16 | 0 | −3.709766E−41 |
| 14 | 2 | −1.443243E−40 |
| 12 | 4 | 6.063705E−40 |
| 10 | 6 | 5.172541E−39 |
| 8 | 8 | 1.082790E−38 |
| 6 | 10 | 1.302819E−38 |
| 4 | 12 | 4.199247E−39 |
| 2 | 14 | −1.692833E−37 |
| 0 | 16 | −7.411635E−37 |

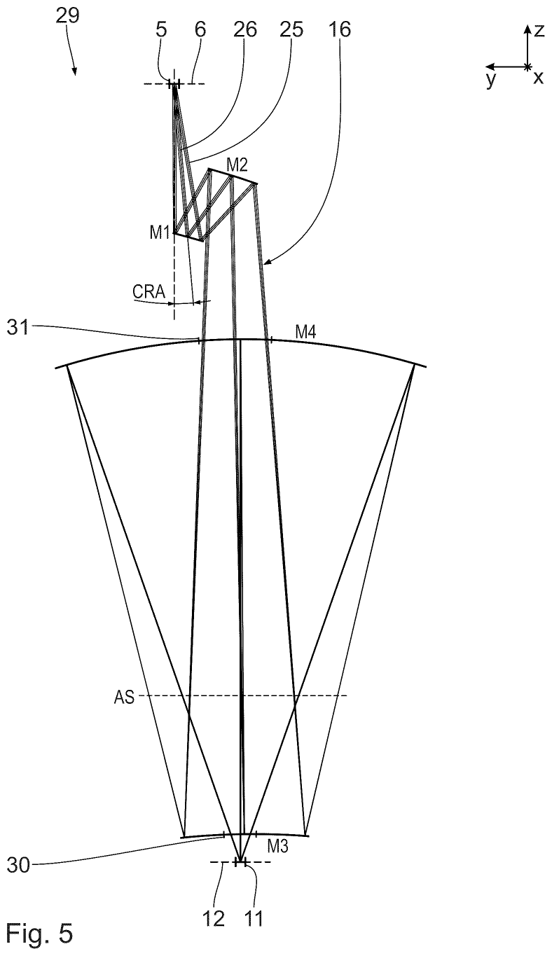

FIG. 5 shows a further embodiment of a projection optical unit or imaging optical unit 29, which can be used in the projection exposure apparatus 1 instead of the projection optical unit 10 of the embodiment according to FIG. 1. Components and functions corresponding to those which have already been explained above in conjunction with FIGS. 1 to 4, and in particular in conjunction with FIGS. 2 to 4, are denoted by the same reference signs and are not discussed in detail again.

The basic design of the projection optical unit 29 is similar to that of the embodiment in FIG. 2 of DE 10 2018 214 437 A1, for example.

The first two mirrors M1 and M2 are used reflectively throughout and the two subsequent mirrors M3 and M4 each have a passage opening 30, 31 for the passage of the imaging light 16 in the imaging beam path of the projection optical unit 29.

On account of the passage opening 30, 25.3% of an overall reflection surface of the mirror M3 are obscured. On account of the passage opening 31, 25.6% of an overall reflection surface of the mirror M4 are obscured.

The projection optical unit 29 has an image-side numerical aperture of 0.33.

The image field 11 of the projection optical unit 29 is rectangular. The image field 11 has an x-extent of 26 mm and a y-extent of 2.5 mm.

A pupil plane is present in the imaging beam path between the mirrors M3 and M4. As indicated in FIG. 5, an aperture stop AS may be arranged there.

An overall transmission is 17.28% in the projection optical unit 29.

The polarization rotation of linearly polarized imaging light 16 in the imaging beam path of the projection optical unit 29 between the object field 5 and the image field 11 is approximately 0°.

An object-image offset is significantly smaller in the projection optical unit 29 than in the projection optical units 27 and 28 and is approximately 200 mm in the projection optical unit 29.

The core parameters of the optical design are tabulated again below, in this case in relation to the projection optical unit 29:

| | | |
|---|---|---|
| Used wavelength | 13.5 | nm |
| Image-side numerical aperture | 0.33 | |
| Imaging scale | −4.00 | |
| Chief ray angle CRA | 5.00° | |
| Etendue | 7.08 | mm² |
| Mean wavefront aberration RMS | 50.64 | mλ |
| Overall transmission | 17.28% | |
| Position of the entrance pupil (x) | 2812.91 | mm |
| Position of the entrance pupil (y) | 2964.98 | mm |
| Object-image offset | 203.26 | mm |
| Working distance (M3 to image field) | 75 | mm |
| z-distance between the object field and | 2385.61 | mm |
| image field | | |
| Angle between object plane and image | −0.0° | |
| plane | | |
| Installation space requirement xyz | (1096 × 1070 × 2051) | mm |

Table 1 for FIG. 5

| | M1 | M2 | M3 | M4 |
|---|---|---|---|---|
| Max. angle of incidence/° | 26.2 | 23.5 | 9.5 | 3.3 |
| Min. angle of incidence/° | 14.4 | 13.2 | 0.2 | 0.2 |
| Mirror extent (x)/mm | 164.8 | 235.0 | 381.0 | 1096.1 |
| Mirror extent (y)/mm | 92.7 | 152.7 | 370.7 | 1069.6 |
| Max. mirror diameter/mm | 165.4 | 235.8 | 381.7 | 1096.1 |

Table 2 for FIG. 5

Very small angles of incidence are present on each of mirrors M3 and M4 of the projection optical unit 29, and, for each individual ray, these are less than 10°. The largest angle of incidence is even less than 5° and even less than 4° in the mirror M4.

A maximum x/y-aspect ratio of the reflection surface extents is at the mirror M1 in the projection optical unit 29 and is 1.77 there.

None of the mirrors M1 to M4 has a diameter which is greater than 1100 mm.

The optical design data for the projection optical unit 29 according to FIG. 5 are tabulated in turn below, in the same format that was already explained above in relation to the embodiment according to FIG. 2.

| z-distance [mm] | y-distance [mm] | Tilt about the x-axis [degrees] |
|---|---|---|
| Image field | | |
| 0 | 0 | 0 |
| M4 | | |
| 1602.762713 | 0 | −0.221361 |
| M3 | | |
| 85.563209 | −10.89504 | −0.7957 |
| M2 | | |
| 2105.234774 | 28.179636 | 17.232651 |
| M1 | | |
| 1916.355899 | 161.567845 | 15.328909 |
| Object field | | |
| 2385.606084 | 203.256135 | 0 |

Table 3 for FIG. 5

| M4 | | |
|---|---|---|
| RDX | −1896.612449 | |
| RDY | −1898.000451 | |
| CCX | 0 | |
| CCY | 0 | |
| x**i | y**j | Coefficient |
| 2 | 1 | −2.774952E−10 |
| 0 | 3 | −2.592514E−10 |
| 4 | 0 | −2.034136E−12 |
| 2 | 2 | −4.046657E−12 |
| 0 | 4 | −2.193125E−12 |
| 4 | 1 | −4.941871E−17 |
| 2 | 3 | −8.317272E−17 |
| 0 | 5 | −5.068573E−16 |
| 6 | 0 | −6.915420E−19 |
| 4 | 2 | −2.075615E−18 |
| 2 | 4 | −2.142960E−18 |
| 0 | 6 | 1.472719E−19 |
| 6 | 1 | 2.263475E−23 |
| 4 | 3 | −6.450748E−23 |
| 2 | 5 | −4.341871E−22 |
| 0 | 7 | 1.229492E−21 |
| 8 | 0 | −1.981639E−25 |
| 6 | 2 | −6.187089E−25 |
| 4 | 4 | −1.265732E−24 |
| 2 | 6 | 6.304428E−26 |
| 0 | 8 | −3.359561E−24 |
| 8 | 1 | −3.685176E−28 |
| 6 | 3 | −5.177311E−28 |
| 4 | 5 | 1.189740E−27 |
| 2 | 7 | 3.423550E−27 |
| 0 | 9 | −2.160284E−27 |
| 10 | 0 | −1.601533E−31 |
| 8 | 2 | −2.591068E−30 |
| 6 | 4 | −1.846959E−30 |
| 4 | 6 | 3.998578E−30 |
| 2 | 8 | −6.319116E−30 |
| 0 | 10 | 7.185171E−30 |
| 10 | 1 | 1.889933E−33 |
| 8 | 3 | 6.119518E−33 |
| 6 | 5 | −1.288347E−33 |
| 4 | 7 | −1.151201E−32 |
| 2 | 9 | −1.915542E−32 |
| 0 | 11 | −3.586685E−34 |
| 12 | 0 | 6.058319E−37 |
| 10 | 2 | 1.343291E−35 |
| 8 | 4 | 1.890085E−35 |
| 6 | 6 | −1.512723E−35 |
| 4 | 8 | −4.940575E−35 |
| 2 | 10 | 2.593279E−35 |
| 0 | 12 | −6.752728E−36 |
| 12 | 1 | −4.796194E−39 |
| 10 | 3 | −2.305475E−38 |
| 8 | 5 | −1.913224E−38 |
| 6 | 7 | 2.577847E−38 |
| 4 | 9 | 4.190837E−38 |
| 2 | 11 | 5.627113E−38 |
| 0 | 13 | 1.060108E−38 |
| 14 | 0 | −1.657266E−42 |
| 12 | 2 | −3.773344E−41 |
| 10 | 4 | −8.364551E−41 |
| 8 | 6 | −2.694547E−41 |
| 6 | 8 | 1.502360E−40 |
| 4 | 10 | 1.967819E−40 |
| 2 | 12 | −6.174345E−41 |
| 0 | 14 | −4.860142E−42 |
| 14 | 1 | 4.836337E−45 |
| 12 | 3 | 2.918613E−44 |
| 10 | 5 | 5.068683E−44 |
| 8 | 7 | 2.594062E−47 |
| 6 | 9 | −5.659188E−44 |
| 4 | 11 | −5.363765E−44 |
| 2 | 13 | −6.584444E−44 |
| 0 | 15 | −1.482130E−44 |
| 16 | 0 | 1.655768E−48 |
| 14 | 2 | 4.016054E−47 |
| 12 | 4 | 1.199545E−46 |
| 10 | 6 | 1.177798E−46 |
| 8 | 8 | −7.418456E−47 |
| 6 | 10 | −3.348069E−46 |
| 4 | 12 | −2.699080E−46 |
| 2 | 14 | 6.040288E−47 |
| 0 | 16 | 1.017435E−47 |
| M3 | | |
| RDX | 2152.094958 | |
| RDY | 2170.791343 | |
| CCX | 0 | |
| CCY | 0 | |
| x**i | y**j | Coefficient |
| 2 | 1 | 4.621465E−09 |
| 0 | 3 | 4.171487E−09 |
| 4 | 0 | 1.490248E−10 |
| 2 | 2 | 2.950115E−10 |
| 0 | 4 | 1.607555E−10 |
| 4 | 1 | 9.401010E−15 |
| 2 | 3 | 1.629859E−14 |
| 0 | 5 | 1.123310E−13 |
| 6 | 0 | 1.525762E−16 |
| 4 | 2 | 4.530267E−16 |
| 2 | 4 | 4.915723E−16 |
| 0 | 6 | −4.203565E−16 |
| 6 | 1 | −4.795272E−21 |
| 4 | 3 | −2.488879E−20 |
| 2 | 5 | 5.671921E−19 |
| 0 | 7 | −2.369938E−18 |
| 8 | 0 | 6.258650E−22 |
| 6 | 2 | 2.102143E−21 |
| 4 | 4 | 4.441941E−21 |
| 2 | 6 | −2.712567E−21 |
| 0 | 8 | 1.865416E−20 |
| 8 | 1 | 5.860996E−25 |
| 6 | 3 | 1.447554E−23 |
| 4 | 5 | 3.167383E−24 |
| 2 | 7 | −3.814351E−23 |
| 0 | 9 | 3.809653E−23 |
| 10 | 0 | −2.394789E−26 |
| 8 | 2 | −7.996981E−26 |
| 6 | 4 | −3.002289E−25 |
| 4 | 6 | −4.293578E−25 |
| 2 | 8 | 2.253172E−25 |
| 0 | 10 | −3.830409E−25 |
| 10 | 1 | 2.027308E−29 |
| 8 | 3 | −7.461065E−28 |
| 6 | 5 | −1.039090E−27 |
| 4 | 7 | 2.731521E−28 |
| 2 | 9 | 1.890663E−27 |
| 0 | 11 | −1.427744E−28 |
| 12 | 0 | 8.323626E−31 |
| 10 | 2 | 2.959543E−30 |
| 8 | 4 | 1.387158E−29 |
| 6 | 6 | 2.704898E−29 |
| 4 | 8 | 2.693460E−29 |
| 2 | 10 | −8.501992E−30 |
| 0 | 12 | 4.197506E−30 |
| 12 | 1 | −1.084649E−33 |
| 10 | 3 | 1.565999E−32 |
| 8 | 5 | 4.332552E−32 |
| 6 | 7 | 2.326563E−32 |
| 4 | 9 | −1.735573E−32 |
| 2 | 11 | −4.887520E−32 |
| 0 | 13 | −7.735360E−33 |
| 14 | 0 | −1.502837E−35 |
| 12 | 2 | −5.727984E−35 |
| 10 | 4 | −3.132230E−34 |
| 8 | 6 | −7.367812E−34 |
| 6 | 8 | −1.015308E−33 |
| 4 | 10 | −7.698205E−34 |
| 2 | 12 | 1.705278E−34 |
| 0 | 14 | −1.365811E−35 |
| 14 | 1 | 1.231658E−38 |
| 12 | 3 | −1.099287E−37 |
| 10 | 5 | −5.353450E−37 |
| 8 | 7 | −6.055353E−37 |
| 6 | 9 | −1.346645E−37 |
| 4 | 11 | 2.629146E−37 |
| 2 | 13 | 4.961818E−37 |
| 0 | 15 | 1.062565E−37 |
| 16 | 0 | 1.107682E−40 |
| 14 | 2 | 4.675367E−40 |
| 12 | 4 | 2.782630E−39 |
| 10 | 6 | 7.946130E−39 |
| 8 | 8 | 1.216237E−38 |
| 6 | 10 | 1.382898E−38 |
| 4 | 12 | 8.159712E−39 |
| 2 | 14 | −1.356714E−39 |
| 0 | 16 | −4.702174E−41 |
| M2 | | |
| RDX | −1923.1304 | |
| RDY | −2219.473474 | |
| CCX | 0 | |
| CCY | 0 | |
| x**i | y**j | Coefficient |
| 2 | 1 | −5.748117E−08 |
| 0 | 3 | −5.004139E−08 |
| 4 | 0 | 4.009398E−11 |
| 2 | 2 | 6.746734E−11 |
| 0 | 4 | −1.594106E−10 |
| 4 | 1 | −1.230988E−14 |
| 2 | 3 | −5.006134E−14 |
| 0 | 5 | −3.174698E−12 |
| 6 | 0 | 5.542537E−17 |
| 4 | 2 | 4.325988E−16 |
| 2 | 4 | −1.568903E−15 |
| 0 | 6 | 5.226648E−14 |
| 6 | 1 | −2.656489E−18 |
| 4 | 3 | −1.430353E−17 |
| 2 | 5 | −3.423005E−18 |
| 0 | 7 | 5.628867E−16 |
| 8 | 0 | −5.365074E−21 |
| 6 | 2 | −1.468642E−19 |
| 4 | 4 | −9.741380E−20 |
| 2 | 6 | 1.308915E−18 |
| 0 | 8 | −1.410339E−17 |
| 8 | 1 | 4.972131E−22 |
| 6 | 3 | 2.366641E−21 |
| 4 | 5 | 1.210811E−20 |
| 2 | 7 | 4.231993E−21 |
| 0 | 9 | −7.738693E−20 |
| 10 | 0 | 2.736194E−25 |
| 8 | 2 | 3.243836E−23 |
| 6 | 4 | 6.849828E−23 |
| 4 | 6 | −4.760068E−25 |
| 2 | 8 | −5.749294E−22 |
| 0 | 10 | 2.976643E−21 |
| 10 | 1 | −5.763081E−26 |
| 8 | 3 | −2.920835E−25 |
| 6 | 5 | −1.414582E−24 |
| 4 | 7 | −4.641822E−24 |
| 2 | 9 | −1.429389E−24 |
| 0 | 11 | 6.416399E−24 |
| 12 | 0 | 8.738299E−30 |
| 10 | 2 | −3.688634E−27 |
| 8 | 4 | −1.252427E−26 |
| 6 | 6 | −1.708211E−26 |
| 4 | 8 | 3.385225E−27 |
| 2 | 10 | 1.397095E−25 |
| 0 | 12 | −4.367528E−25 |
| 12 | 1 | 3.426769E−30 |
| 10 | 3 | 2.091941E−29 |
| 8 | 5 | 7.711087E−29 |
| 6 | 7 | 3.839325E−28 |
| 4 | 9 | 7.460093E−28 |
| 2 | 11 | 2.815766E−28 |
| 0 | 13 | −5.627423E−29 |
| 14 | 0 | −1.572900E−33 |
| 12 | 2 | 2.085214E−31 |
| 10 | 4 | 9.511523E−31 |
| 8 | 6 | 2.105344E−30 |
| 6 | 8 | 2.965991E−30 |
| 4 | 10 | −2.065715E−31 |
| 2 | 12 | −1.641397E−29 |
| 0 | 14 | 3.933252E−29 |
| 14 | 1 | −7.846332E−35 |
| 12 | 3 | −6.205612E−34 |
| 10 | 5 | −1.047769E−33 |
| 8 | 7 | −1.182934E−32 |
| 6 | 9 | −2.637610E−32 |
| 4 | 11 | −4.848910E−32 |
| 2 | 13 | −2.268051E−32 |
| 0 | 15 | −2.243898E−32 |
| 16 | 0 | 4.842555E−38 |
| 14 | 2 | −4.655643E−36 |
| 12 | 4 | −2.666823E−35 |
| 10 | 6 | −6.958593E−35 |
| 8 | 8 | −1.815569E−34 |
| 6 | 10 | −1.816555E−34 |
| 4 | 12 | −7.206911E−35 |
| 2 | 14 | 7.115489E−34 |
| 0 | 16 | −1.638864E−33 |
| M1 | | |
| RDX | 1755.063305 | |
| RDY | 2147.601582 | |
| CCX | 0 | |
| CCY | 0 | |
| x**i | y**j | Coefficient |
| 2 | 1 | 1.184699E−07 |
| 0 | 3 | 9.573008E−08 |
| 4 | 0 | −1.428257E−10 |
| 2 | 2 | −2.292500E−10 |
| 0 | 4 | 4.643347E−10 |
| 4 | 1 | −2.924438E−14 |
| 2 | 3 | 1.123224E−13 |
| 0 | 5 | 2.386181E−11 |
| 6 | 0 | −1.557101E−16 |
| 4 | 2 | −1.199582E−15 |
| 2 | 4 | 2.034369E−14 |
| 0 | 6 | −4.478883E−13 |
| 6 | 1 | 5.281243E−17 |
| 4 | 3 | 1.609890E−16 |
| 2 | 5 | 6.441107E−17 |
| 0 | 7 | −1.432148E−14 |
| 8 | 0 | −2.071742E−21 |
| 6 | 2 | 9.858022E−19 |
| 4 | 4 | −1.727492E−18 |
| 2 | 6 | −3.838913E−17 |
| 0 | 8 | 3.742033E−16 |
| 8 | 1 | −2.372994E−20 |
| 6 | 3 | −5.674282E−20 |
| 4 | 5 | −3.447810E−19 |
| 2 | 7 | −1.578190E−19 |
| 0 | 9 | 7.142425E−18 |
| 10 | 0 | 1.144218E−23 |
| 8 | 2 | −6.459108E−22 |
| 6 | 4 | −3.927221E−22 |
| 4 | 6 | 3.937244E−21 |
| 2 | 8 | 4.270203E−20 |
| 0 | 10 | −2.443914E−19 |
| 10 | 1 | 5.927660E−24 |
| 8 | 3 | 1.757922E−23 |
| 6 | 5 | 7.237423E−23 |
| 4 | 7 | 3.537100E−22 |
| 2 | 9 | 1.449351E−22 |
| 0 | 11 | −2.532107E−21 |
| 12 | 0 | −3.266350E−27 |
| 10 | 2 | 1.813940E−25 |
| 8 | 4 | 4.934095E−25 |
| 6 | 6 | −2.791265E−25 |
| 4 | 8 | −3.336562E−24 |
| 2 | 10 | −2.685800E−23 |
| 0 | 12 | 1.091363E−22 |
| 12 | 1 | −7.321071E−28 |
| 10 | 3 | −2.950208E−27 |
| 8 | 5 | −7.408885E−27 |
| 6 | 7 | −5.487276E−26 |
| 4 | 9 | −1.424537E−25 |
| 2 | 11 | −8.244894E−26 |
| 0 | 13 | 5.001853E−25 |
| 14 | 0 | 4.113048E−31 |
| 12 | 2 | −2.295726E−29 |
| 10 | 4 | −1.048887E−28 |
| 8 | 6 | −1.347135E−28 |
| 6 | 8 | 1.452659E−28 |
| 4 | 10 | 1.243200E−27 |
| 2 | 12 | 8.407264E−27 |
| 0 | 14 | −2.887808E−26 |
| 14 | 1 | 3.482369E−32 |
| 12 | 3 | 1.831772E−31 |
| 10 | 5 | 1.965410E−31 |
| 8 | 7 | 3.080072E−30 |
| 6 | 9 | 9.355299E−30 |
| 4 | 11 | 2.367852E−29 |
| 2 | 13 | 1.770252E−29 |
| 0 | 15 | −3.765155E−29 |
| 16 | 0 | −1.986410E−35 |
| 14 | 2 | 1.093730E−33 |
| 12 | 4 | 6.966547E−33 |
| 10 | 6 | 1.404361E−32 |
| 8 | 8 | 3.229483E−32 |
| 6 | 10 | −4.917594E−32 |
| 4 | 12 | −1.139920E−31 |
| 2 | 14 | −1.017838E−30 |
| 0 | 16 | 3.372124E−30 |

Table 4 for FIG. 5

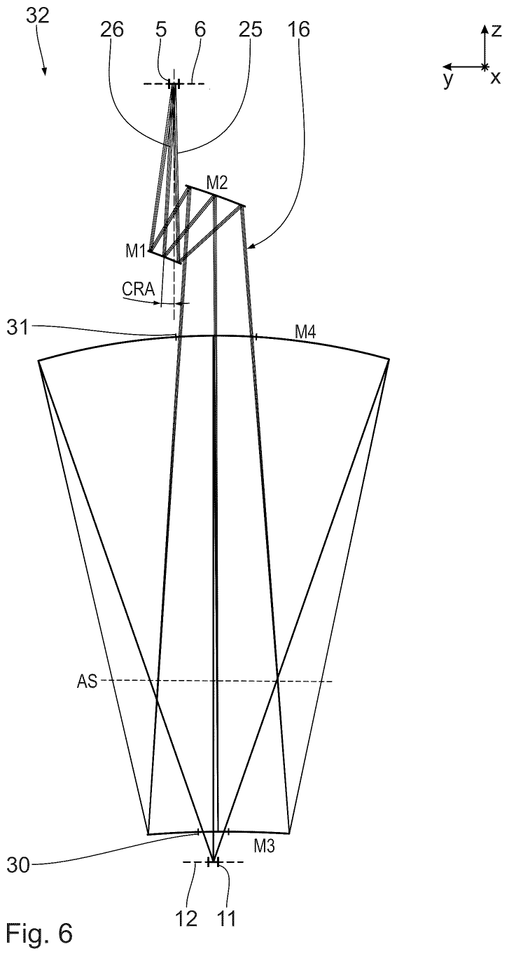

FIG. 6 shows a further embodiment of a projection optical unit or imaging optical unit 32, which can be used in the projection exposure apparatus 1 instead of the projection optical unit 10 of the embodiment according to FIG. 1. Components and functions corresponding to those which have already been explained above in conjunction with FIGS. 1 to 5, and in particular in conjunction with FIGS. 2 to 5, are denoted by the same reference signs and are not discussed in detail again.

In contrast to the projection optical unit 29 according to FIG. 5, the object plane 6 is not parallel to the image plane 12, but tilted with respect to the latter, in the projection optical unit 32 according to FIG. 6. In the projection optical unit 32, an angle between the object plane 6 and the image plane 12 is 8.3°. This angle is therefore less than 10°.

The core parameters of the optical design are tabulated again below, in this case in relation to the projection optical unit 32:

| | | |
|---|---|---|
| Used wavelength | 13.5 | nm |
| Image-side numerical aperture | 0.33 | |
| Imaging scale | −4.00 | |
| Chief ray angle CRA | 5.00° | |
| Etendue | 7.08 | mm² |
| Mean wavefront aberration RMS | 61.41 | mλ |
| Overall transmission | 17.37% | |
| Position of the entrance pupil (x) | 1883.14 | mm |
| Position of the entrance pupil (y) | 1601.18 | mm |
| Object-image offset | 109.39 | mm |
| Working distance (M3 to image field) | 75 | mm |
| z-distance between the object field and | 2156.00 | mm |
| image field | | |
| Angle between object plane and image | −8.3° | |
| plane | | |
| Installation space requirement xyz | (997 × 975 × 1797) | mm |

Table 1 for FIG. 6

| | M1 | M2 | M3 | M4 |
|---|---|---|---|---|
| Max. angle of incidence/° | 24.6 | 26.0 | 9.3 | 3.9 |
| Min. angle of incidence/° | 11.5 | 13.7 | 0.0 | 0.2 |
| Mirror extent (x)/mm | 157.3 | 217.9 | 399.7 | 997.0 |
| Mirror extent (y)/mm | 91.7 | 161.9 | 392.3 | 975.0 |
| Max. mirror diameter/mm | 157.7 | 218.9 | 400.0 | 997.8 |

Table 2 for FIG. 6

The maximum x/y-aspect ratio of the reflection surface extent is at the mirror M1 in the projection optical unit 32 and is 1.71 there.

The overall transmission of the projection optical unit 32 is 17.37%.

The polarization rotation of linearly polarized imaging light 16 in the imaging beam path of the projection optical unit 32 between the object field 5 and the image field 11 is approximately 1.4°.

On account of the passage opening 30, 24.4% of an overall reflection surface of the mirror M3 are obscured. On account of the passage opening 31, 26.0% of an overall reflection surface of the mirror M4 are obscured. The optical design data for the projection optical unit 32 according to FIG. 6 are tabulated in turn below, in the same format that was already explained above in relation to the embodiment according to FIG. 2.

| z-distance [mm] | y-distance [mm] | Tilt about the x-axis [degrees] |
|---|---|---|
| Image field | | |
| 0 | 0 | 0 |
| M4 | | |
| 1458.185065 | 0 | −0.266921 |
| M3 | | |
| 83.461902 | −13.009742 | −0.41328 |
| M2 | | |
| 1848.166908 | −2.599705 | 19.513997 |
| M1 | | |
| 1676.945301 | 137.885982 | 21.303345 |
| Object field | | |
| 2155.999495 | 109.392218 | 8.298895 |

Table 3 for FIG. 6

| M4 | | |
|---|---|---|
| RDX | −1781.351688 | |
| RDY | −1786.933058 | |
| CCX | 0 | |
| CCY | 0 | |
| x**i | y**j | Coefficient |
| 2 | 1 | −1.577032E−09 |
| 0 | 3 | −8.754015E−10 |
| 4 | 0 | −2.763784E−12 |
| 2 | 2 | −5.361566E−12 |
| 0 | 4 | −3.499969E−12 |
| 4 | 1 | −4.349902E−16 |
| 2 | 3 | −6.866580E−16 |
| 0 | 5 | −1.333906E−15 |
| 6 | 0 | −1.125273E−18 |
| 4 | 2 | −3.285566E−18 |
| 2 | 4 | −3.499881E−18 |
| 0 | 6 | 2.469208E−18 |
| 6 | 1 | −1.123221E−22 |
| 4 | 3 | −3.026120E−22 |
| 2 | 5 | −5.826308E−22 |
| 0 | 7 | 1.299257E−21 |
| 8 | 0 | −3.212716E−25 |
| 6 | 2 | −1.473202E−24 |
| 4 | 4 | −2.399569E−24 |
| 2 | 6 | −2.873776E−25 |
| 0 | 8 | −1.250687E−23 |
| 8 | 1 | −7.893464E−29 |
| 6 | 3 | −2.928983E−28 |
| 4 | 5 | −6.749919E−28 |
| 2 | 7 | −5.553059E−28 |
| 0 | 9 | 3.807155E−27 |
| 10 | 0 | −3.727491E−31 |
| 8 | 2 | −8.324067E−31 |
| 6 | 4 | −1.256065E−30 |
| 4 | 6 | 9.537689E−32 |
| 2 | 8 | −4.272432E−30 |
| 0 | 10 | 2.378393E−29 |
| 10 | 1 | 9.290659E−36 |
| 8 | 3 | −9.638184E−34 |
| 6 | 5 | 1.581225E−33 |
| 4 | 7 | 6.223740E−34 |
| 2 | 9 | 6.475910E−33 |
| 0 | 11 | −1.673891E−32 |
| 12 | 0 | 3.309670E−37 |
| 10 | 2 | 1.698787E−37 |
| 8 | 4 | −4.077089E−37 |
| 6 | 6 | −1.640044E−36 |
| 4 | 8 | −4.464894E−36 |
| 2 | 10 | 4.555441E−36 |
| 0 | 12 | −1.966704E−35 |
| 12 | 1 | 3.665695E−41 |
| 10 | 3 | 3.355117E−39 |
| 8 | 5 | 1.871653E−39 |
| 6 | 7 | −2.898512E−39 |
| 4 | 9 | 2.752840E−39 |
| 2 | 11 | −1.316362E−38 |
| 0 | 13 | 1.823380E−38 |
| M3 | | |
| RDX | 2756.438197 | |
| RDY | 2799.881003 | |
| CCX | 0 | |
| CCY | 0 | |
| x**i | y**j | Coefficient |
| 2 | 1 | 2.336844E−08 |
| 0 | 3 | 9.616894E−09 |
| 4 | 0 | 1.269254E−10 |
| 2 | 2 | 2.433646E−10 |
| 0 | 4 | 1.560478E−10 |
| 4 | 1 | 3.072222E−14 |
| 2 | 3 | 4.943873E−14 |
| 0 | 5 | 1.421980E−13 |
| 6 | 0 | 1.106007E−16 |
| 4 | 2 | 3.153900E−16 |
| 2 | 4 | 3.619385E−16 |
| 0 | 6 | −8.704664E−16 |
| 6 | 1 | 4.815942E−20 |
| 4 | 3 | 9.375829E−20 |
| 2 | 5 | 1.372310E−19 |
| 0 | 7 | −1.144889E−18 |
| 8 | 0 | 1.649856E−22 |
| 6 | 2 | 6.191820E−22 |
| 4 | 4 | 1.055121E−21 |
| 2 | 6 | −1.063376E−21 |
| 0 | 8 | 2.048025E−20 |
| 8 | 1 | −2.720588E−25 |
| 6 | 3 | 2.436473E−24 |
| 4 | 5 | 3.138023E−24 |
| 2 | 7 | 4.993968E−24 |
| 0 | 9 | −1.149177E−23 |
| 10 | 0 | −6.073156E−28 |
| 8 | 2 | −2.606917E−27 |
| 6 | 4 | −1.922072E−27 |
| 4 | 6 | −1.107514E−26 |
| 2 | 8 | 2.608892E−26 |
| 0 | 10 | −2.485678E−25 |
| 10 | 1 | 1.344650E−29 |
| 8 | 3 | −2.550393E−29 |
| 6 | 5 | −1.370734E−28 |
| 4 | 7 | −2.756973E−29 |
| 2 | 9 | −1.957515E−28 |
| 0 | 11 | 3.747474E−28 |
| 12 | 0 | 8.548938E−33 |
| 10 | 2 | 5.122573E−32 |
| 8 | 4 | 6.687237E−32 |
| 6 | 6 | 9.839367E−32 |
| 4 | 8 | 2.203827E−31 |
| 2 | 10 | −1.748925E−31 |
| 0 | 12 | 1.270232E−30 |
| 12 | 1 | −1.425391E−34 |
| 10 | 3 | −4.555582E−35 |
| 8 | 5 | 1.494223E−33 |
| 6 | 7 | 1.459523E−33 |
| 4 | 9 | −5.314405E−34 |
| 2 | 11 | 2.176709E−33 |
| 0 | 13 | −2.586810E−33 |
| M2 | | |
| RDX | −2362.925822 | |
| RDY | −2065.32297 | |
| CCX | 0 | |
| CCY | 0 | |
| x**i | y**i | Coefficient |
| 2 | 1 | −1.601565E−07 |
| 0 | 3 | −8.212809E−08 |
| 4 | 0 | 1.256633E−10 |
| 2 | 2 | 2.273679E−10 |
| 0 | 4 | −3.792821E−10 |
| 4 | 1 | −5.883858E−14 |
| 2 | 3 | −1.282392E−13 |
| 0 | 5 | −4.030038E−12 |
| 6 | 0 | 3.481209E−16 |
| 4 | 2 | 8.356580E−16 |
| 2 | 4 | −2.299657E−16 |
| 0 | 6 | 7.799752E−14 |
| 6 | 1 | −1.826514E−18 |
| 4 | 3 | −2.126057E−18 |
| 2 | 5 | 2.370234E−17 |
| 0 | 7 | 3.766295E−16 |
| 8 | 0 | −3.663222E−20 |
| 6 | 2 | −8.479403E−20 |
| 4 | 4 | −1.636193E−20 |
| 2 | 6 | 3.559382E−20 |
| 0 | 8 | −1.031778E−17 |
| 8 | 1 | 2.040449E−22 |
| 6 | 3 | −1.116659E−21 |
| 4 | 5 | 1.574054E−21 |
| 2 | 7 | −7.064762E−21 |
| 0 | 9 | −1.718828E−20 |
| 10 | 0 | 2.834490E−24 |
| 8 | 2 | 8.990412E−24 |
| 6 | 4 | 6.428969E−24 |
| 4 | 6 | −8.874749E−24 |
| 2 | 8 | 2.605661E−23 |
| 0 | 10 | 8.388679E−22 |
| 10 | 1 | −1.561690E−26 |
| 8 | 3 | 1.232149E−25 |
| 6 | 5 | −5.193271E−27 |
| 4 | 7 | −5.693922E−25 |
| 2 | 9 | 1.290030E−24 |
| 0 | 11 | 6.105191E−25 |
| 12 | 0 | −8.680887E−29 |
| 10 | 2 | −3.818533E−28 |
| 8 | 4 | −4.550999E−28 |
| 6 | 6 | 3.301563E−28 |
| 4 | 8 | 6.066363E−28 |
| 2 | 10 | −3.096519E−27 |
| 0 | 12 | −2.959578E−26 |
| 12 | 1 | 4.264558E−31 |
| 10 | 3 | −4.018665E−30 |
| 8 | 5 | −6.089999E−30 |
| 6 | 7 | 4.389431E−29 |
| 4 | 9 | 3.597680E−29 |
| 2 | 11 | −9.006648E−29 |
| 0 | 13 | −3.287759E−29 |
| M1 | | |
| RDX | 1802.158337 | |
| RDY | 1383.333286 | |
| CCX | 0 | |
| CCY | 0 | |
| x**i | y**j | Coefficient |
| 2 | 1 | 3.055289E−07 |
| 0 | 3 | 1.588269E−07 |
| 4 | 0 | −3.233031E−10 |
| 2 | 2 | −6.599977E−10 |
| 0 | 4 | 1.769134E−09 |
| 4 | 1 | −7.323518E−14 |
| 2 | 3 | 7.857463E−13 |
| 0 | 5 | 2.871263E−11 |
| 6 | 0 | −2.170601E−15 |
| 4 | 2 | −5.922462E−15 |
| 2 | 4 | 1.141578E−14 |
| 0 | 6 | −1.133979E−12 |
| 6 | 1 | 1.102227E−17 |
| 4 | 3 | 1.534716E−17 |
| 2 | 5 | −8.062953E−16 |
| 0 | 7 | −7.331779E−15 |
| 8 | 0 | 5.452183E−19 |
| 6 | 2 | 1.822246E−18 |
| 4 | 4 | 5.345617E−19 |
| 2 | 6 | −3.704703E−18 |
| 0 | 8 | 4.846948E−16 |
| 8 | 1 | 6.366046E−22 |
| 6 | 3 | 4.847363E−20 |
| 4 | 5 | −5.123540E−20 |
| 2 | 7 | 5.804308E−19 |
| 0 | 9 | 2.023231E−19 |
| 10 | 0 | −7.833507E−23 |
| 8 | 2 | −3.460998E−22 |
| 6 | 4 | −3.977246E−22 |
| 4 | 6 | 8.773183E−22 |
| 2 | 8 | −2.790707E−21 |
| 0 | 10 | −1.266135E−19 |
| 10 | 1 | −3.898393E−25 |
| 8 | 3 | −1.076683E−23 |
| 6 | 5 | −8.909172E−24 |
| 4 | 7 | 6.160100E−23 |
| 2 | 9 | −2.833607E−22 |
| 0 | 11 | 1.946035E−22 |
| 12 | 0 | 4.510808E−27 |
| 10 | 2 | 2.752066E−26 |
| 8 | 4 | 3.836562E−26 |
| 6 | 6 | −4.564857E−26 |
| 4 | 8 | −1.917629E−25 |
| 2 | 10 | 1.179558E−24 |
| 0 | 12 | 1.431623E−23 |
| 12 | 1 | 3.899648E−29 |
| 10 | 3 | 7.419905E−28 |
| 8 | 5 | 1.765702E−27 |
| 6 | 7 | −9.379213E−27 |
| 4 | 9 | −8.205350E−27 |
| 2 | 11 | 5.723353E−26 |
| 0 | 13 | −1.509316E−26 |

Table 4 for FIG. 6

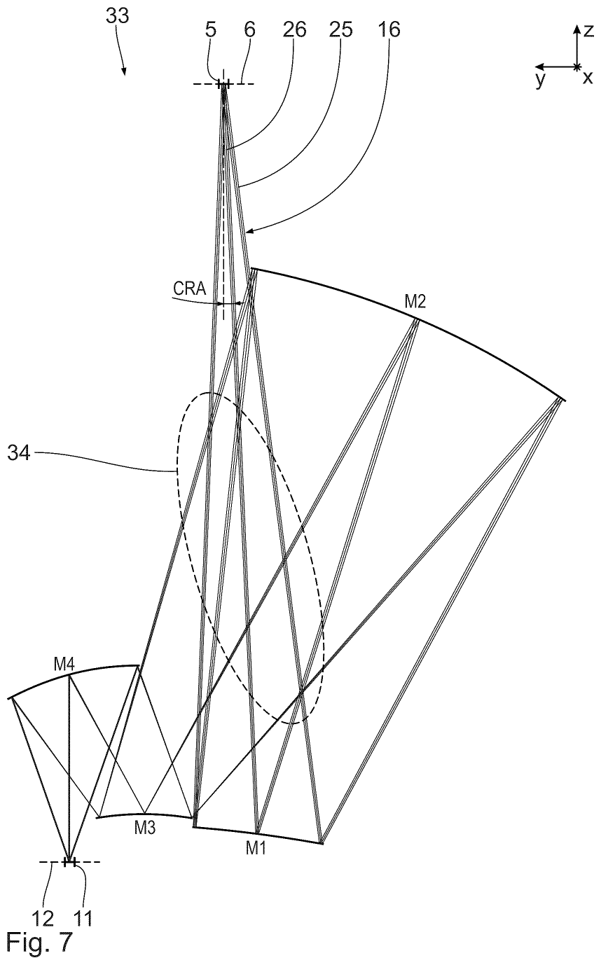

FIG. 7 shows a further embodiment of a projection optical unit or imaging optical unit 33, which can be used in the projection exposure apparatus 1 instead of the projection optical unit 10 of the embodiment according to FIG. 1. Components and functions corresponding to those which have already been explained above in conjunction with FIGS. 1 to 6, and in particular in conjunction with FIGS. 2 to 6, are denoted by the same reference signs and are not discussed in detail again.

The image-side numerical aperture of the projection optical unit 33 is 0.33.

A mean wavefront aberration RMS is 47.2 mλ in the projection optical unit 33.

An x-position of the entrance pupil is in the imaging beam path more than 5 m downstream of the object field 5. A y-position of the entrance pupil of the projection optical unit 33 is in the imaging beam path more than 8 m upstream of the object field 5. Thus, there is object-side telecentricity to a good approximation in the projection optical unit 33 as well.

The overall transmission is 15.6% in the projection optical unit 33.

The polarization rotation of linearly polarized imaging light 16 in the imaging beam path of the projection optical unit 33 between the object field 5 and the image field 11 is approximately 0.5°.

All projection optical units described above are designed so that they have a very small polarization-rotating effect for imaging light 16 propagating linearly along the imaging beam path. Linearly polarized imaging light 16 which propagates along the imaging beam path between the object field 5 and the image field 11 experiences a polarization rotation which is less than 10°, which is less than 7° and which may also be less than 5°. This polarization rotation is very small in the projection optical units 28 and 29 and may in particular be less than 1°. As a rule, the polarization rotation is greater than 0°.

The projection optical unit 33 has a chief ray angle CRA of 6.0°.

There is a tilt angle of 8.6° between the object plane 6 and the image plane 12 in the projection optical unit 33.

An object-image offset is 415 mm in the projection optical unit 33.

An installation space requirement in the x/y-direction is 1450 mm in the projection optical unit 33.

A working distance between the mirror closest to the wafer and the image field 11 is 50 mm in the projection optical unit 33.

In the projection optical unit 33, an imaging beam path portion between the object field 5 and the mirror M1 crosses an imaging beam path portion between the mirror M2 and the mirror M3 in a crossing region 34.

The mirrors M1 to M4 of the projection optical unit 33 also have free-form reflection surfaces. These free-form surfaces of the mirrors M1 to M4 of the projection optical unit 33 can be described by a surface equation which is explained in the specialist article “Characterizing the shape of freeform optics” by G. W. Forbes, Optics Express, 2012, vol. 20, no. 3, pages 2483 to 2499. Free-form surfaces with such a surface description are also referred to as Forbes free-form surfaces.

The Forbes free-form surface equation is:

$$z ( h , θ ) = \frac{ρ {h}^{2}}{1 + \sqrt{1 - ( 1 + κ ) {ρ}^{2} {h}^{2}}} + \frac{\sqrt{1 - {κρ}^{2} {h}^{2}}}{\sqrt{1 - ( 1 + κ ) {ρ}^{2} {h}^{2}}} {u}^{2} ( 1 - {u}^{2} ) {\sum }_{n = 0}^{N} {a}_{n}^{0} {Q}_{n}^{0} ( {u}^{2} ) + \frac{\sqrt{1 - {κρ}^{2} {h}^{2}}}{\sqrt{1 - ( 1 + κ ) {ρ}^{2} {h}^{2}}} {\sum }_{m = 1}^{M} {u}^{m} {\sum }_{n = 0}^{N} [ {a}_{0}^{m} cos ( m θ ) + {b}_{n}^{m} sin ( m θ ) ] {Q}_{n}^{m} ( {u}^{2} ) \qquad ( 2 )$$

The following applies to the parameters of this Equation (2):
z is the sag of the free-form surface at the point h, θ, where h is the radial coordinate and θ is the azimuthal coordinate of this point;
u=h/NH is a normalized radial coordinate;
ρ is the curvature, that is to say the inverse of the radius of curvature RD;
κ is the conic constant, that is to say corresponds to the values CC in the tables above;
Q^{m}ₙ are the orthogonal polynomials on the unit circle which are described in the aforementioned specialist article by Forbes.

The optical design data of the projection optical unit 33 can be gathered from the following Tables 1 and 2. The coefficients in Table 2 below are the coefficients aₙ^{m} of Equation (2) above. The coefficients bₙ^{m} are zero.

The optical design data for the projection optical unit 33 according to FIG. 7 are tabulated in turn below, in the same format that was already explained above in relation to the embodiment according to FIG. 2.

Table 1 for FIG. 7

| z-distance | y-distance | Tilt about the |
|---|---|---|
| [mm] | [mm] | x-axis [degrees] |
| Image field | | |
| 0 | 0 | 0 |
| M4 | | |
| 499.479655 | −1.252109 | −14.266825 |
| M3 | | |
| 129.297951 | −202.71356 | 0.224322 |
| M2 | | |
| 1450.112914 | −934.129645 | 23.188425 |
| M1 | | |
| 74.84813 | −503.522568 | 7.398378 |
| Object field | | |
| 2080.169381 | −412.759825 | −8.55828 |

Table 2 for FIG. 7

| M4 | | |
|---|---|---|
| RD | −674.141685 | |
| CC | −7.057546 | |
| NH | 178 | |
| m (azimuthal) | n (radial) | Coefficient |
| 0 | 1 | 2.158826E+00 |
| 0 | 2 | 9.053848E−02 |
| 0 | 3 | 8.326399E−03 |
| 0 | 4 | 7.630368E−04 |
| 0 | 5 | 7.504028E−05 |
| 0 | 6 | 7.611690E−06 |
| 0 | 7 | 7.393046E−07 |
| 0 | 8 | 5.906798E−08 |
| 0 | 9 | 3.553988E−08 |
| 0 | 10 | 1.328395E−08 |
| 1 | 0 | −2.461487E−01 |
| 2 | 0 | 8.280850E−01 |
| 1 | 1 | 4.060911E−01 |
| 3 | 0 | 8.152266E−02 |
| 2 | 1 | −2.177222E−02 |
| 1 | 2 | −8.231040E−03 |
| 4 | 0 | 7.398675E−04 |
| 3 | 1 | −2.394160E−03 |
| 2 | 2 | 1.474217E−03 |
| 1 | 3 | 6.070534E−04 |
| 5 | 0 | −2.350329E−04 |
| 4 | 1 | −4.210644E−05 |
| 3 | 2 | 9.123412E−05 |
| 2 | 3 | 8.582007E−05 |
| 1 | 4 | 3.820082E−05 |
| 6 | 0 | −8.369689E−05 |
| 5 | 1 | −2.685826E−05 |
| 4 | 2 | −1.834685E−06 |
| 3 | 3 | 2.745246E−06 |
| 2 | 4 | 1.087568E−05 |
| 1 | 5 | 6.213705E−06 |
| 7 | 0 | −1.841681E−05 |
| 6 | 1 | 1.368494E−06 |
| 5 | 2 | −1.020304E−06 |
| 4 | 3 | −4.929447E−08 |
| 3 | 4 | −1.063891E−07 |
| 2 | 5 | 1.454338E−06 |
| 1 | 6 | 9.664322E−07 |
| M3 | | |
| RD | −703.081741 | |
| CC | −3.803876 | |
| NH | 122.2 | |
| m (azimuthal) | n (radial) | Coefficient |
| 0 | 1 | 4.007976E−01 |
| 0 | 2 | 1.117137E−03 |
| 0 | 3 | 1.362501E−04 |
| 0 | 4 | 3.380156E−06 |
| 0 | 5 | −6.932871E−08 |
| 0 | 6 | −2.330231E−09 |
| 0 | 7 | −1.499203E−08 |
| 0 | 8 | 1.708493E−08 |
| 0 | 9 | 1.663774E−08 |
| 0 | 10 | 8.506459E−10 |
| 1 | 0 | 8.127828E−03 |
| 2 | 0 | 7.774468E−01 |
| 1 | 1 | −4.475010E−02 |
| 3 | 0 | 1.146000E−01 |
| 2 | 1 | −1.712697E−02 |
| 1 | 2 | 1.640428E−03 |
| 4 | 0 | 6.971913E−03 |
| 3 | 1 | −2.987492E−03 |
| 2 | 2 | 4.508978E−04 |
| 1 | 3 | −3.487619E−06 |
| 5 | 0 | −1.168978E−03 |
| 4 | 1 | −3.768545E−04 |
| 3 | 2 | 6.215257E−05 |
| 2 | 3 | 2.173801E−06 |
| 1 | 4 | 1.034637E−05 |
| 6 | 0 | −2.019444E−04 |
| 5 | 1 | −2.215596E−05 |
| 4 | 2 | 6.847336E−06 |
| 3 | 3 | −1.864898E−06 |
| 2 | 4 | −1.067963E−06 |
| 1 | 5 | 3.143095E−06 |
| 7 | 0 | −3.869970E−05 |
| 6 | 1 | 1.402010E−06 |
| 5 | 2 | −1.124569E−06 |
| 4 | 3 | −4.110751E−07 |
| 3 | 4 | 9.245766E−08 |
| 2 | 5 | 1.239770E−07 |
| 1 | 6 | 3.386706E−07 |
| M2 | | |
| RD | −2266.478893 | |
| CC | 3.87813 | |
| NH | 469 | |
| m (azimuthal) | n (radial) | Coefficient |
| 0 | 1 | −2.429214E+00 |
| 0 | 2 | 7.665298E−02 |
| 0 | 3 | −2.801257E−03 |
| 0 | 4 | 8.885453E−05 |
| 0 | 5 | −2.126937E−06 |
| 0 | 6 | −9.077928E−08 |
| 0 | 7 | −8.362647E−08 |
| 0 | 8 | 7.011289E−08 |
| 0 | 9 | −3.590886E−10 |
| 0 | 10 | −1.816603E−09 |
| 1 | 0 | 9.023216E−02 |
| 2 | 0 | 5.484354E−01 |
| 1 | 1 | −1.384427E−01 |
| 3 | 0 | 1.114467E−01 |
| 2 | 1 | −3.595621E−03 |
| 1 | 2 | −1.164327E−03 |
| 4 | 0 | 2.391659E−02 |
| 3 | 1 | −3.141348E−03 |
| 2 | 2 | −8.894507E−04 |
| 1 | 3 | 2.080530E−04 |
| 5 | 0 | −3.882160E−03 |
| 4 | 1 | −9.728454E−04 |
| 3 | 2 | −1.977228E−05 |
| 2 | 3 | 6.740178E−05 |
| 1 | 4 | −1.918278E−06 |
| 6 | 0 | −7.882665E−04 |
| 5 | 1 | 3.950587E−05 |
| 4 | 2 | 1.751378E−06 |
| 3 | 3 | 5.893226E−07 |
| 2 | 4 | −5.921587E−06 |
| 1 | 5 | 6.220505E−06 |
| 7 | 0 | 5.094393E−05 |
| 6 | 1 | −6.775249E−07 |
| 5 | 2 | −1.116946E−06 |
| 4 | 3 | 4.148667E−07 |
| 3 | 4 | −3.048308E−07 |
| 2 | 5 | 1.082262E−06 |
| 1 | 6 | 1.077016E−06 |
| M1 | | |
| RD | −2941.822992 | |
| CC | 0 | |
| NH | 188 | |
| m (azimuthal) | n (radial) | Coefficient |
| 0 | 1 | 1.210828E−03 |
| 0 | 2 | 1.771270E−04 |
| 0 | 3 | −1.197954E−05 |
| 0 | 4 | 3.273471E−06 |
| 0 | 5 | −2.734902E−07 |
| 0 | 6 | 1.048878E−07 |
| 0 | 7 | −2.920113E−08 |
| 0 | 8 | 3.789820E−08 |
| 0 | 9 | 6.366711E−09 |
| 0 | 10 | 1.721357E−08 |
| 1 | 0 | −7.944568E−02 |
| 2 | 0 | −3.952909E−01 |
| 1 | 1 | 7.254268E−02 |
| 3 | 0 | 6.855305E−02 |
| 2 | 1 | 5.289044E−03 |
| 1 | 2 | −1.884276E−03 |
| 4 | 0 | 8.098740E−03 |
| 3 | 1 | −9.639560E−04 |
| 2 | 2 | −1.139779E−04 |
| 1 | 3 | −2.811414E−06 |
| 5 | 0 | −9.615278E−04 |
| 4 | 1 | −3.034513E−04 |
| 3 | 2 | −3.827645E−05 |
| 2 | 3 | 9.396414E−06 |
| 1 | 4 | 7.821304E−06 |
| 6 | 0 | −2.274966E−04 |
| 5 | 1 | −7.093649E−05 |
| 4 | 2 | −3.361308E−06 |
| 3 | 3 | 2.146141E−07 |
| 2 | 4 | −2.333223E−06 |
| 1 | 5 | 2.051580E−06 |
| 7 | 0 | −4.841925E−05 |
| 6 | 1 | −4.207961E−06 |
| 5 | 2 | −3.969009E−07 |
| 4 | 3 | 6.252160E−08 |
| 3 | 4 | −1.101290E−06 |
| 2 | 5 | 4.803750E−07 |
| 1 | 6 | 1.537131E−06 |

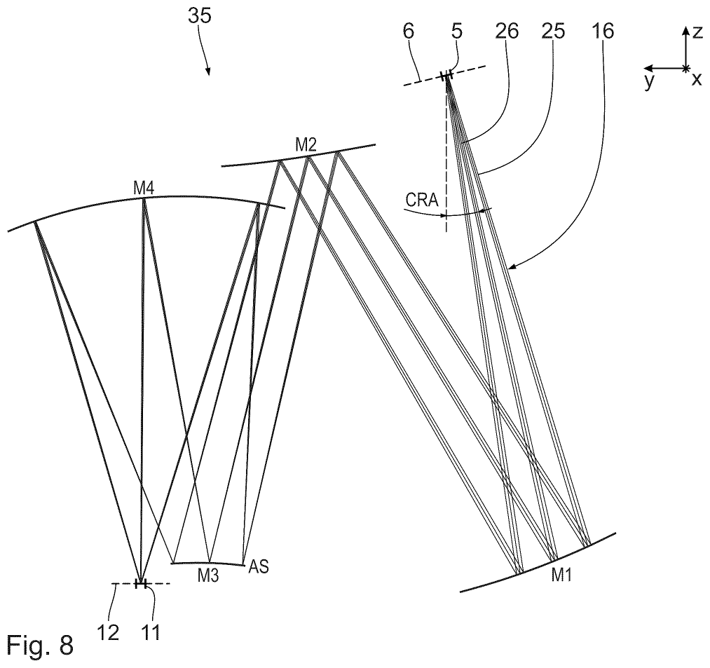

FIG. 8 shows a further embodiment of a projection optical unit or imaging optical unit 35, which can be used in the projection exposure apparatus 1 instead of the projection optical unit 10 of the embodiment according to FIG. 1. Components and functions corresponding to those which have already been explained above in conjunction with FIGS. 1 to 7, and in particular in conjunction with FIGS. 2 to 7, are denoted by the same reference signs and are not discussed in detail again.

An image-side numerical aperture of the projection optical unit 35 is 0.26.

A mean wavefront aberration RMS is 71.8 m, in the projection optical unit 35.

An x-position of the entrance pupil of the projection optical unit 35 is in the imaging beam path more than 1100 mm downstream of the object field 5. A y-position of the entrance pupil of the projection optical unit 35 is in the imaging beam path more than approximately 1100 mm downstream of the object field 5. Thus, there is object-side telecentricity to a good approximation in the projection optical unit 35 as well.

The overall transmission is 17.5% in the projection optical unit 35.

The polarization rotation of linearly polarized imaging light 16 in the imaging beam path of the projection optical unit 35 between the object field 5 and the image field 11 is approximately 1°.

The projection optical unit 35 has a chief ray angle CRA 5.9°.

There is a tilt angle of 18.4° between the object plane 6 and the image plane 12 in the projection optical unit 35.

An object-image offset is approximately 1100 mm in the projection optical unit 35.

A light path of the imaging beam path of the projection optical unit 35 between the object field 5 and the image field 11 is approximately 1850 mm.

An installation space requirement in the x/y-direction is approximately 830 mm in the projection optical unit 35.

A working distance between the mirror closest to the wafer and the image field 11 is 75 mm in the projection optical unit 35.

The optical design data of the projection optical unit 35 can be gathered from the following Tables 1 and 2, which in terms of their basic design correspond to the tables relating to the embodiment according to FIG. 7, that is to say they describe a Forbes free-form surface.

Table 1 for FIG. 8

| z-distance | y-distance | Tilt about the |
|---|---|---|
| [mm] | [mm] | x-axis [degrees] |
| Image field | | |
| 0 | 0 | 0 |
| M4 | | |
| 1383.433074 | −13.578952 | −4.823026 |
| M3 | | |
| 75 | −241.226417 | 2.208116 |
| M2 | | |
| 1528.071357 | −566.768637 | −8.212052 |
| M1 | | |
| 60.587987 | −1430.118911 | −20.666167 |
| Object field | | |
| 1822.997128 | −1096.312645 | −18.409534 |

Table 2 for FIG. 8

| M4 | | |
|---|---|---|
| RD | −1612.45275 | |
| CC | 0 | |
| NH | 269.320278 | |
| m (azimuthal) | n (radial) | Coefficient |
| 0 | 1 | 1.760977E−02 |
| 0 | 2 | −8.628785E−05 |
| 0 | 3 | 6.234087E−07 |
| 0 | 4 | 5.174072E−09 |
| 0 | 5 | −2.576197E−09 |
| 0 | 6 | −2.407451E−09 |
| 0 | 7 | −5.967537E−10 |
| 0 | 8 | −6.061126E−11 |
| 0 | 9 | −2.150472E−12 |
| 1 | 0 | 1.704289E−01 |
| 2 | 0 | 3.486352E−02 |
| 1 | 1 | −5.265955E−03 |
| 3 | 0 | 2.008072E−03 |
| 2 | 1 | 2.174086E−04 |
| 1 | 2 | 1.378131E−05 |
| 4 | 0 | −7.813876E−05 |
| 3 | 1 | 8.054593E−05 |
| 2 | 2 | −5.160556E−06 |
| 1 | 3 | −1.458274E−07 |
| 5 | 0 | 5.800466E−05 |
| 4 | 1 | −5.289889E−06 |
| 3 | 2 | −5.066663E−07 |
| 2 | 3 | 1.363909E−08 |
| 1 | 4 | −1.645447E−08 |
| 6 | 0 | −3.990225E−06 |
| 5 | 1 | −2.912809E−07 |
| 4 | 2 | 2.983336E−08 |
| 3 | 3 | 5.370310E−09 |
| 2 | 4 | −8.373416E−09 |
| 1 | 5 | −5.068696E−09 |
| 7 | 0 | −2.243625E−09 |
| 6 | 1 | 3.226100E−08 |
| 5 | 2 | 8.411002E−09 |
| 4 | 3 | −1.396113E−09 |
| 3 | 4 | −1.286162E−10 |
| 2 | 5 | −3.510828E−10 |
| 1 | 6 | −3.592554E−10 |
| M3 | | |
| RD | −1320.369333 | |
| CC | 0 | |
| NH | 151.916317 | |
| m (azimuthal) | n (radial) | Coefficient |
| 0 | 1 | 2.234853E−01 |
| 0 | 2 | −3.494072E−03 |
| 0 | 3 | 2.464736E−04 |
| 0 | 4 | −8.997152E−05 |
| 0 | 5 | 3.994293E−05 |
| 0 | 6 | −1.373121E−05 |
| 0 | 7 | 3.237536E−06 |
| 0 | 8 | −3.184110E−07 |
| 0 | 9 | −3.922443E−08 |
| 1 | 0 | −1.210345E+00 |
| 2 | 0 | 4.878177E−01 |
| 1 | 1 | −7.295334E−01 |
| 3 | 0 | −8.265461E−03 |
| 2 | 1 | −2.177110E−02 |
| 1 | 2 | 1.713353E−02 |
| 4 | 0 | −7.985117E−04 |
| 3 | 1 | 3.437028E−03 |
| 2 | 2 | 9.446428E−04 |
| 1 | 3 | −5.173699E−04 |
| 5 | 0 | 1.810260E−03 |
| 4 | 1 | 1.398708E−04 |
| 3 | 2 | −1.027657E−04 |
| 2 | 3 | −3.317884E−05 |
| 1 | 4 | 1.261704E−05 |
| 6 | 0 | 1.546091E−05 |
| 5 | 1 | −4.460386E−05 |
| 4 | 2 | −5.227008E−06 |
| 3 | 3 | 1.502412E−06 |
| 2 | 4 | 6.675811E−07 |
| 1 | 5 | 1.100138E−06 |
| 7 | 0 | 4.534528E−06 |
| 6 | 1 | −1.352029E−06 |
| 5 | 2 | 2.166020E−06 |
| 4 | 3 | −1.556496E−07 |
| 3 | 4 | 5.456739E−07 |
| 2 | 5 | −2.680866E−07 |
| 1 | 6 | −2.451496E−07 |
| M2 | | |
| RD | 4793.987896 | |
| CC | 0 | |
| NH | 332.761979 | |
| m (azimuthal) | n (radial) | Coefficient |
| 0 | 1 | 3.461835E+00 |
| 0 | 2 | −6.321338E−01 |
| 0 | 3 | −4.551329E−01 |
| 0 | 4 | 2.865871E−01 |
| 0 | 5 | 1.570447E−01 |
| 0 | 6 | −2.681335E−01 |
| 0 | 7 | 1.489997E−01 |
| 0 | 8 | −4.130630E−02 |
| 0 | 9 | 4.878372E−03 |
| 1 | 0 | 1.101951E+00 |
| 2 | 0 | 1.490353E+00 |
| 1 | 1 | −1.512959E+00 |
| 3 | 0 | 3.468813E+00 |
| 2 | 1 | 1.181578E+00 |
| 1 | 2 | −1.713662E+00 |
| 4 | 0 | −1.765590E+00 |
| 3 | 1 | −2.796762E+00 |
| 2 | 2 | −4.031345E−01 |
| 1 | 3 | 1.089376E+00 |
| 5 | 0 | −1.489463E−01 |
| 4 | 1 | 1.151131E+00 |
| 3 | 2 | 1.017497E+00 |
| 2 | 3 | 1.477901E−01 |
| 1 | 4 | −4.248762E−01 |
| 6 | 0 | −2.770800E−02 |
| 5 | 1 | 1.103040E−01 |
| 4 | 2 | −2.780892E−01 |
| 3 | 3 | −2.272929E−01 |
| 2 | 4 | −4.227557E−02 |
| 1 | 5 | 9.912375E−02 |
| 7 | 0 | −7.393471E−03 |
| 6 | 1 | −1.723151E−04 |
| 5 | 2 | −1.452361E−02 |
| 4 | 3 | 3.241639E−02 |
| 3 | 4 | 2.269809E−02 |
| 2 | 5 | 5.839684E−03 |
| 1 | 6 | −1.060217E−02 |
| M1 | | |
| RD | 2770.180378 | |
| CC | 0 | |
| NH | 294.960088 | |
| m (azimuthal) | n (radial) | Coefficient |
| 0 | 1 | −4.458839E−02 |
| 0 | 2 | 1.060174E−02 |
| 0 | 3 | −3.335210E−03 |
| 0 | 4 | 5.393741E−04 |
| 0 | 5 | 4.439556E−05 |
| 0 | 6 | −5.511384E−05 |
| 0 | 7 | 2.233819E−05 |
| 0 | 8 | −6.650336E−06 |
| 0 | 9 | 1.001173E−06 |
| 1 | 0 | −4.098512E−01 |
| 2 | 0 | 4.037363E−01 |
| 1 | 1 | −2.244212E−01 |
| 3 | 0 | −2.921199E−02 |
| 2 | 1 | 2.755862E−02 |
| 1 | 2 | 2.682705E−02 |
| 4 | 0 | 1.221419E−02 |
| 3 | 1 | 1.523907E−02 |
| 2 | 2 | −1.041059E−02 |
| 1 | 3 | −8.615941E−03 |
| 5 | 0 | 5.609151E−03 |
| 4 | 1 | −3.601026E−03 |
| 3 | 2 | −3.429086E−03 |
| 2 | 3 | 3.158207E−03 |
| 1 | 4 | 2.286182E−03 |
| 6 | 0 | −6.881652E−04 |
| 5 | 1 | −7.501832E−04 |
| 4 | 2 | 7.091527E−04 |
| 3 | 3 | 7.364596E−04 |
| 2 | 4 | −5.928267E−04 |
| 1 | 5 | −3.476039E−04 |
| 7 | 0 | −9.095077E−05 |
| 6 | 1 | 7.308780E−05 |
| 5 | 2 | 7.928103E−05 |
| 4 | 3 | −7.798261E−05 |
| 3 | 4 | −7.472596E−05 |
| 2 | 5 | 4.811982E−05 |
| 1 | 6 | 2.080239E−05 |

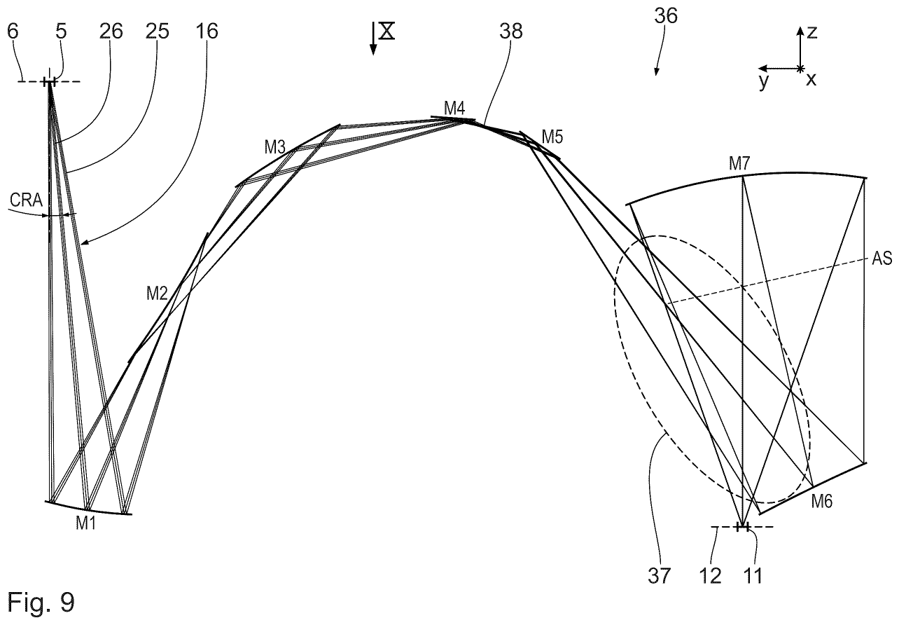

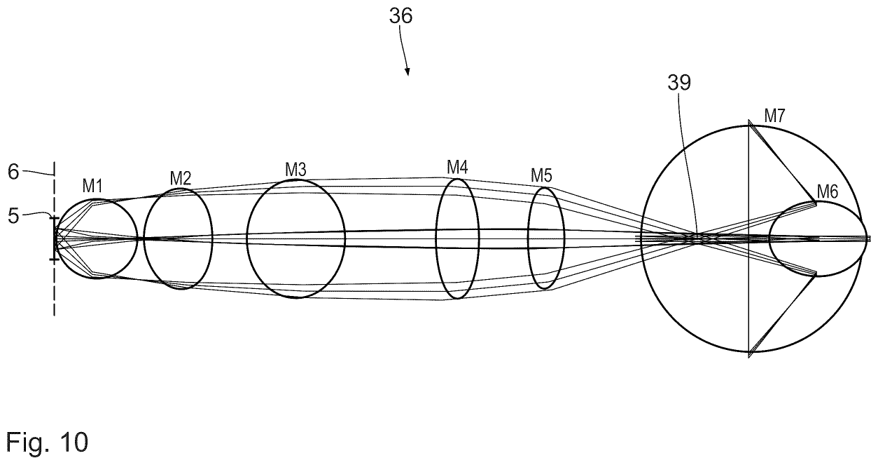

FIGS. 9 and 10 show a further embodiment of a projection optical unit or imaging optical unit 36, which can be used in the projection exposure apparatus 1 instead of the projection optical unit 10 of the embodiment according to FIG. 1. Components and functions corresponding to those which have already been explained above in conjunction with FIGS. 1 to 8, and in particular in conjunction with FIGS. 2 to 8, are denoted by the same reference signs and are not discussed in detail again.

The projection optical unit 36 has a total of seven mirrors M1 to M7 in the beam path between the object field 5 and the image field 11. The mirrors M1, M6 and M7 are embodied as NI mirrors. The mirrors M2, M3, M4 and M5 are embodied as mirrors for grazing incidence, that is to say as mirrors on which the imaging light 16 is incident with an angle of incidence that is greater than 45°. These mirrors for grazing incidence are also referred to as GI (grazing incidence) mirrors.

Deflecting effects of the four GI mirrors M2, M3, M4 and M5 add for the imaging light 16.

Imaging beam path portions between, firstly, the mirrors M5 and M6 and between, secondly, the mirror M7 and the image field 11 cross in a crossing region 37.

In the meridional yz-beam path of the imaging light 16, a y-intermediate image 38 is located between the GI mirrors M4 and M5. In the plane perpendicular thereto (cf. FIG. 10), a x-intermediate field 39 is located in the xz-beam path of the imaging light 16 between the GI mirror M5 and the NI mirror M6.

An image-side numerical aperture of the projection optical unit 36 is 0.33.

A mean wavefront aberration RMS is 8.57 m, in the projection optical unit 36.

An x-position of the entrance pupil of the projection optical unit 36 is in the imaging beam path more than 2700 mm downstream of the object field 5. A y-position of the entrance pupil of the projection optical unit 36 is in the imaging beam path more than approximately 1600 mm upstream of the object field 5. There is object-side telecentricity to a good approximation in the projection optical unit 36 as well. The overall transmission is 11.1% in the projection optical unit 36.

A polarization rotation of linearly polarized imaging light 16 in the imaging beam path of the projection optical unit 36 between the object field 5 and the image field 11 is no more than approximately 1.8°.

The projection optical unit 36 has a chief ray angle CRA of 5.05°.

The object plane 6 lies parallel to the image plane 12. A z-distance between the object plane and the image plane is of the order of 2.1 m.

An object-image offset is approximately 3.4 m in the projection optical unit 36.

An installation space requirement in the x-, y- and z-direction is approximately 1140 mm×3950 mm×1920 mm in the projection optical unit 36.

A working distance between the mirror closest to the wafer and the image field 11 is approximately 65 mm in the projection optical unit 36.

The projection optical unit 36 has no pupil obscuration. The reflection surfaces of all mirrors M1 to M6 are used contiguously without interruptions or passage openings.

The imaging scales βₓ, β_{y} of the projection optical unit 36 respectively are +0.25, or a reduction of 4.00, in the x-direction and −0.25 in the y-direction, this is caused by the odd number of mirrors overall and a respective intermediate image in the x- and y-directions.

The image field 11 of the projection optical unit 36 is rectangular and has an extent of 26.0 mm in the x-direction and an extent of 2.5 mm in the y-direction.

The mirror M6 has a diameter of just under 1150 mm. A maximum y/x-aspect ratio of a reflection surface extent is at the mirror M6 in the projection optical unit 36 and is approximately 1.56 there. A maximum x/y-aspect ratio of the reflection surface extent is at the mirror M4 in the projection optical unit 36 and is approximately 2.76.

Surface extent parameters of the optical design are tabulated below in relation to the projection optical unit 36:

Table 1 for FIG. 9

| Used wavelength | 13.5 | nm |
|---|---|---|
| Image-side numerical aperture | 0.33 | |
| Imaging scale βₓ | 4.00 | |
| Imaging scale β_{y} | −4.00 | |
| Chief ray angle CRA | 5.05° | |
| Etendue | 7.08 | mm² |
| Mean wavefront aberration RMS | 8.57 | mλ |
| Overall transmission | 11.12% | |
| Position of the entrance pupil (x) | 2914.91 | mm |
| Position of the entrance pupil (y) | −1560.59 | mm |
| Object-image offset | 3359.91 | mm |
| Working distance (M3 to image field) | 65 | mm |
| z-distance between the object field | 2156.00 | mm |

| and image field | |
|---|---|
| Angle between object plane and | 0.0° |
| image plane | |
| Installation space requirement xyz | (1138 × 3950 × 1916) mm |

TABLE 2
TABLE 2 for FIG. 9

| | M1 | M2 | M3 | M4 | M5 | M6 | M7 |
|---|---|---|---|---|---|---|---|
| Mirror extent (x)/mm | 373.9 | 468.5 | 565.1 | 586.2 | 494.4 | 356.4 | 1137.7 |
| Mirror extent (y)/mm | 378.9 | 679.5 | 566.1 | 212.4 | 233.0 | 556.4 | 1144.1 |

The optical design data for the projection optical unit 36 according to FIGS. 9 and 10 are tabulated in turn below, in the same format that was already explained above in relation to the embodiment according to FIG. 2.

Table 3 for FIG. 9

| z-distance | y-distance | Tilt about the |
|---|---|---|
| [mm] | [mm] | x-axis [degrees] |
| Image field | | |
| 0 | 0 | 0 |
| M7 | | |
| 1701.872691 | 0 | −6.384275 |
| M6 | | |
| 194.410382 | −341.616989 | −25.88081 |
| M5 | | |
| 1855.02607 | 1002.790559 | 32.318876 |
| M4 | | |
| 1982.035966 | 1526.553549 | 2.609139 |
| M3 | | |
| 1909.396635 | 2017.721981 | −27.21016 |
| M2 | | |
| 1197.193943 | 2705.301372 | −58.990586 |
| M1 | | |
| 67.626497 | 3072.900031 | 185.646125 |
| Object field | | |
| 2156 | 3359.913113 | 0 |

Table 4 for FIG. 9

| M7 | | |
|---|---|---|
| RDX | −1896.361096 | |
| RDY | −2172.735368 | |
| CCX | 0 | |
| CCY | 0 | |
| x**i | y**j | Coefficient |
| 2 | 1 | 3.748844E−09 |
| 0 | 3 | 4.082096E−09 |
| 4 | 0 | 1.862746E−13 |
| 2 | 2 | −2.732195E−12 |
| 0 | 4 | −2.632870E−12 |
| 4 | 1 | 1.033608E−15 |
| 2 | 3 | 3.096581E−15 |
| 0 | 5 | 3.520198E−15 |
| 6 | 0 | 5.719348E−20 |
| 4 | 2 | −8.213125E−19 |
| 2 | 4 | −1.308788E−18 |
| 0 | 6 | −8.472091E−19 |
| 6 | 1 | 3.676281E−22 |
| 4 | 3 | 1.442725E−21 |
| 2 | 5 | 2.098759E−21 |
| 0 | 7 | 1.956110E−21 |
| 8 | 0 | −9.972197E−26 |
| 6 | 2 | −5.299823E−25 |
| 4 | 4 | −1.080368E−24 |
| 2 | 6 | −4.511630E−25 |
| 0 | 8 | 1.273511E−24 |
| 8 | 1 | 3.183031E−28 |
| 6 | 3 | 9.255918E−28 |
| 4 | 5 | 1.120184E−27 |
| 2 | 7 | 1.307992E−28 |
| 0 | 9 | −1.741799E−28 |
| 10 | 0 | 1.969533E−31 |
| 8 | 2 | 5.127748E−31 |
| 6 | 4 | −9.600424E−31 |
| 4 | 6 | 1.656009E−30 |
| 2 | 8 | 1.018525E−30 |
| 0 | 10 | −2.959197E−30 |
| 10 | 1 | 4.372614E−34 |
| 8 | 3 | 1.719123E−35 |
| 6 | 5 | −2.108602E−33 |
| 4 | 7 | −1.091440E−33 |
| 2 | 9 | 2.053459E−33 |
| 0 | 11 | −2.688917E−34 |
| 12 | 0 | −4.027581E−37 |
| 10 | 2 | −2.776349E−36 |
| 8 | 4 | 1.232076E−36 |
| 6 | 6 | 1.082332E−36 |
| 4 | 8 | −5.268002E−36 |
| 2 | 10 | −9.245996E−37 |
| 0 | 12 | 8.001718E−36 |
| 12 | 1 | −2.436417E−39 |
| 10 | 3 | −1.522524E−39 |
| 8 | 5 | 1.700099E−39 |
| 6 | 7 | 3.507475E−39 |
| 4 | 9 | 1.089576E−39 |
| 2 | 11 | 3.717227E−41 |
| 0 | 13 | 5.267335E−39 |
| 14 | 0 | 9.757780E−44 |
| 12 | 2 | 3.145867E−42 |
| 10 | 4 | −1.385886E−43 |
| 8 | 6 | −1.150477E−42 |
| 6 | 8 | 3.060764E−42 |
| 4 | 10 | 7.692377E−42 |
| 2 | 12 | 2.116562E−42 |
| 0 | 14 | −6.199603E−42 |
| 14 | 1 | 3.488520E−45 |
| 12 | 3 | 4.245401E−45 |
| 10 | 5 | −2.569037E−45 |
| 8 | 7 | 2.555412E−45 |
| 6 | 9 | −5.758646E−46 |
| 4 | 11 | 4.514985E−45 |
| 2 | 13 | 1.213940E−45 |
| 0 | 15 | −4.943294E−45 |
| M6 | | |
| RDX | 3728.135312 | |
| RDY | 7192.393986 | |
| CCX | 0 | |
| CCY | 0 | |
| x**i | y**j | Coefficient |
| 2 | 1 | −5.393279E−08 |
| 0 | 3 | −5.205158E−08 |
| 4 | 0 | −4.089258E−11 |
| 2 | 2 | 1.624848E−10 |
| 0 | 4 | 6.050377E−11 |
| 4 | 1 | −4.619295E−14 |
| 2 | 3 | −7.979284E−14 |
| 0 | 5 | −1.140717E−13 |
| 6 | 0 | 3.279642E−16 |
| 4 | 2 | 1.116363E−16 |
| 2 | 4 | 1.375112E−16 |
| 0 | 6 | 9.134526E−17 |
| 6 | 1 | 1.451666E−19 |
| 4 | 3 | −1.747643E−19 |
| 2 | 5 | −3.176467E−19 |
| 0 | 7 | −3.025259E−19 |
| 8 | 0 | −2.941911E−22 |
| 6 | 2 | 1.667975E−22 |
| 4 | 4 | 4.611044E−22 |
| 2 | 6 | 4.351916E−22 |
| 0 | 8 | −2.937721E−23 |
| 8 | 1 | −7.048831E−24 |
| 6 | 3 | −2.273726E−24 |
| 4 | 5 | 4.048946E−25 |
| 2 | 7 | 1.712014E−25 |
| 0 | 9 | 3.678786E−25 |
| 10 | 0 | −2.729863E−26 |
| 8 | 2 | −1.355962E−26 |
| 6 | 4 | 6.322920E−27 |
| 4 | 6 | −1.524334E−28 |
| 2 | 8 | 5.527098E−28 |
| 0 | 10 | 4.030633E−27 |
| 10 | 1 | 1.485617E−28 |
| 8 | 3 | 4.872947E−29 |
| 6 | 5 | −8.988320E−30 |
| 4 | 7 | −2.831372E−29 |
| 2 | 9 | −1.347069E−29 |
| 0 | 11 | −6.417311E−30 |
| 12 | 0 | 7.289430E−31 |
| 10 | 2 | 7.728636E−31 |
| 8 | 4 | −9.289212E−32 |
| 6 | 6 | −4.714241E−32 |
| 4 | 8 | 6.145293E−33 |
| 2 | 10 | −8.664941E−33 |
| 0 | 12 | −3.801942E−32 |
| 12 | 1 | −1.717065E−33 |
| 10 | 3 | −2.483910E−34 |
| 8 | 5 | 2.537493E−34 |
| 6 | 7 | 8.942128E−34 |
| 4 | 9 | 4.358207E−34 |
| 2 | 11 | 1.043728E−34 |
| 0 | 13 | 3.153255E−35 |
| 14 | 0 | −4.896352E−36 |
| 12 | 2 | −1.175634E−35 |
| 10 | 4 | −1.512621E−36 |
| 8 | 6 | 8.887877E−37 |
| 6 | 8 | −6.522441E−37 |
| 4 | 10 | 1.800487E−38 |
| 2 | 12 | 1.063532E−37 |
| 0 | 14 | 1.671668E−37 |
| 14 | 1 | 7.850924E−39 |
| 12 | 3 | −1.543486E−38 |
| 10 | 5 | −2.410394E−40 |
| 8 | 7 | −1.148893E−38 |
| 6 | 9 | −7.554073E−39 |
| 4 | 11 | −2.435783E−39 |
| 2 | 13 | −5.685012E−40 |
| 0 | 15 | −1.341775E−40 |
| M5 | | |
| RDX | −1506.373665 | |
| RDY | 9682.42776 | |
| CCX | 0 | |
| CCY | 0 | |
| x**i | y**j | Coefficient |
| 0 | 1 | 3.695139E−02 |
| 2 | 1 | 2.174022E−07 |
| 0 | 3 | 1.198814E−07 |
| 4 | 0 | 5.228456E−11 |
| 2 | 2 | 6.082154E−11 |
| 0 | 4 | 1.079968E−10 |
| 4 | 1 | 1.079134E−13 |
| 2 | 3 | −5.953051E−13 |
| 0 | 5 | 9.794550E−14 |
| 6 | 0 | 5.711273E−17 |
| 4 | 2 | −1.729307E−15 |
| 2 | 4 | −1.353663E−15 |
| 0 | 6 | 2.947486E−16 |
| 6 | 1 | −1.617052E−18 |
| 4 | 3 | 2.211238E−19 |
| 2 | 5 | −5.221851E−18 |
| 0 | 7 | −1.684650E−17 |
| 8 | 0 | −3.980622E−22 |
| 6 | 2 | 6.198850E−21 |
| 4 | 4 | −8.426873E−21 |
| 2 | 6 | −1.666015E−19 |
| 0 | 8 | −1.813809E−19 |
| 8 | 1 | 6.533429E−24 |
| 6 | 3 | −1.864443E−23 |
| 4 | 5 | −5.558139E−22 |
| 2 | 7 | −9.943919E−22 |
| 0 | 9 | 2.952293E−22 |
| 10 | 0 | −1.099102E−27 |
| 8 | 2 | −5.519478E−26 |
| 6 | 4 | −1.347142E−24 |
| 4 | 6 | −3.289187E−24 |
| 2 | 8 | 6.324697E−24 |
| 0 | 10 | 1.737896E−23 |
| 10 | 1 | −5.363127E−29 |
| 8 | 3 | −1.976566E−27 |
| 6 | 5 | −6.243899E−27 |
| 4 | 7 | 1.676398E−26 |
| 2 | 9 | 8.940936E−26 |
| 0 | 11 | 1.118919E−25 |
| 12 | 0 | 1.205791E−32 |
| 10 | 2 | −1.502974E−30 |
| 8 | 4 | 4.049948E−31 |
| 6 | 6 | 7.098927E−29 |
| 4 | 8 | 2.680790E−28 |
| 2 | 10 | 1.782132E−28 |
| 0 | 12 | −9.493938E−29 |
| 12 | 1 | −5.045951E−34 |
| 10 | 3 | 1.316709E−32 |
| 8 | 5 | 1.828502E−31 |
| 6 | 7 | 8.846240E−31 |
| 4 | 9 | 1.128468E−30 |
| 2 | 11 | −1.706570E−30 |
| 0 | 13 | −4.727743E−30 |
| 14 | 0 | −4.213386E−38 |
| 12 | 2 | 1.595653E−35 |
| 10 | 4 | 1.884417E−34 |
| 8 | 6 | 1.174042E−33 |
| 6 | 8 | 3.721732E−33 |
| 4 | 10 | 1.459186E−33 |
| 2 | 12 | −9.424750E−33 |
| 0 | 14 | −2.374136E−32 |
| 14 | 1 | 6.492504E−39 |
| 12 | 3 | 7.275952E−38 |
| 10 | 5 | 5.123507E−37 |
| 8 | 7 | 2.326211E−36 |
| 6 | 9 | 5.834886E−36 |
| 4 | 11 | −1.104588E−36 |
| 2 | 13 | −1.328283E−35 |
| 0 | 15 | −4.087884E−35 |
| M4 | | |
| RDX | −1210.804598 | |
| RDY | 12074.63832 | |
| CCX | 0 | |
| CCY | 0 | |
| x**i | y**j | Coefficient |
| 0 | 1 | −2.698176E−02 |
| 2 | 1 | 1.178448E−07 |
| 0 | 3 | −3.129178E−07 |
| 4 | 0 | 4.657755E−11 |
| 2 | 2 | −1.372316E−09 |
| 0 | 4 | 1.796566E−09 |
| 4 | 1 | −2.185153E−12 |
| 2 | 3 | 1.307724E−11 |
| 0 | 5 | −3.077661E−12 |
| 6 | 0 | −1.111985E−15 |
| 4 | 2 | 3.684560E−14 |
| 2 | 4 | −3.595395E−14 |
| 0 | 6 | −2.860790E−14 |
| 6 | 1 | 3.737178E−17 |
| 4 | 3 | −2.793525E−16 |
| 2 | 5 | −4.710552E−16 |
| 0 | 7 | 9.377458E−17 |
| 8 | 0 | 1.175436E−20 |
| 6 | 2 | −5.367565E−19 |
| 4 | 4 | 1.428120E−19 |
| 2 | 6 | 5.266838E−18 |
| 0 | 8 | 8.388553E−19 |
| 8 | 1 | −3.534523E−22 |
| 6 | 3 | 3.580506E−21 |
| 4 | 5 | 1.530824E−20 |
| 2 | 7 | −1.958050E−20 |
| 0 | 9 | −5.038368E−21 |
| 10 | 0 | −7.184751E−26 |
| 8 | 2 | 4.380259E−24 |
| 6 | 4 | −2.318354E−24 |
| 4 | 6 | −1.271641E−22 |
| 2 | 8 | 6.673241E−24 |
| 0 | 10 | 3.050330E−24 |
| 10 | 1 | 1.840476E−27 |
| 8 | 3 | −2.568708E−26 |
| 6 | 5 | −1.277058E−25 |
| 4 | 7 | 4.551157E−25 |
| 2 | 9 | 1.077744E−25 |
| 0 | 11 | −1.819502E−26 |
| 12 | 0 | 2.158967E−31 |
| 10 | 2 | −1.794638E−29 |
| 8 | 4 | 3.962308E−29 |
| 6 | 6 | 8.361486E−28 |
| 4 | 8 | −7.058497E−28 |
| 2 | 10 | 1.445944E−28 |
| 0 | 12 | 5.444797E−28 |
| 12 | 1 | −4.446554E−33 |
| 10 | 3 | 8.403974E−32 |
| 8 | 5 | 3.393547E−31 |
| 6 | 7 | −1.942772E−30 |
| 4 | 9 | 7.642385E−31 |
| 2 | 11 | −1.855720E−30 |
| 0 | 13 | −2.745713E−30 |
| 14 | 0 | −2.171509E−37 |
| 12 | 2 | 2.690822E−35 |
| 10 | 4 | −1.679465E−34 |
| 8 | 6 | −1.870776E−33 |
| 6 | 8 | 1.051877E−34 |
| 4 | 10 | −3.982437E−33 |
| 2 | 12 | 2.705501E−33 |
| 0 | 14 | 5.454767E−33 |
| 14 | 1 | 3.141298E−39 |
| 12 | 3 | −6.000786E−38 |
| 10 | 5 | 6.918862E−38 |
| 8 | 7 | 2.938557E−36 |
| 6 | 9 | 4.343960E−36 |
| 4 | 11 | 8.531465E−36 |
| 2 | 13 | 6.164676E−37 |
| 0 | 15 | −3.804903E−36 |
| M3 | | |
| RDX | −5104.296222 | |
| RDY | −3534.780862 | |
| CCX | 0 | |
| CCY | 0 | |
| x**i | y**j | Coefficient |
| 2 | 1 | 6.531888E−08 |
| 0 | 3 | 3.167985E−08 |
| 4 | 0 | −4.423171E−11 |
| 2 | 2 | −1.013646E−10 |
| 0 | 4 | −1.340077E−10 |
| 4 | 1 | 9.837574E−14 |
| 2 | 3 | 2.414040E−13 |
| 0 | 5 | 2.506732E−13 |
| 6 | 0 | −3.082922E−17 |
| 4 | 2 | −3.088992E−16 |
| 2 | 4 | −7.293534E−16 |
| 0 | 6 | −8.437465E−16 |
| 6 | 1 | 1.918791E−19 |
| 4 | 3 | 1.130788E−18 |
| 2 | 5 | 2.455702E−18 |
| 0 | 7 | 2.901385E−18 |
| 8 | 0 | 8.357363E−23 |
| 6 | 2 | −7.973007E−22 |
| 4 | 4 | −4.150210E−21 |
| 2 | 6 | −9.802640E−21 |
| 0 | 8 | −1.096302E−20 |
| 8 | 1 | 1.035430E−25 |
| 6 | 3 | 5.288504E−24 |
| 4 | 5 | 1.583854E−23 |
| 2 | 7 | 3.796260E−23 |
| 0 | 9 | 3.380245E−23 |
| 10 | 0 | −6.868755E−28 |
| 8 | 2 | −4.750674E−27 |
| 6 | 4 | −3.284931E−26 |
| 4 | 6 | −6.137077E−26 |
| 2 | 8 | −1.191020E−25 |
| 0 | 10 | −7.006751E−26 |
| 10 | 1 | 2.793833E−30 |
| 8 | 3 | 3.109342E−29 |
| 6 | 5 | 1.536285E−28 |
| 4 | 7 | 2.033108E−28 |
| 2 | 9 | 2.707037E−28 |
| 0 | 11 | 6.574669E−29 |
| 12 | 0 | −3.651869E−33 |
| 10 | 2 | 8.435172E−33 |
| 8 | 4 | −1.105801E−31 |
| 6 | 6 | −4.536009E−31 |
| 4 | 8 | −4.758056E−31 |
| 2 | 10 | −4.173359E−31 |
| 0 | 12 | 6.917769E−32 |
| 12 | 1 | 4.110075E−35 |
| 10 | 3 | −6.825978E−35 |
| 8 | 5 | 2.546793E−34 |
| 6 | 7 | 7.220391E−34 |
| 4 | 9 | 6.765513E−34 |
| 2 | 11 | 3.997285E−34 |
| 0 | 13 | −2.883785E−34 |
| 14 | 0 | 5.921250E−38 |
| 12 | 2 | −2.582457E−38 |
| 10 | 4 | 1.624420E−37 |
| 8 | 6 | −2.096781E−37 |
| 6 | 8 | −4.739309E−37 |
| 4 | 10 | −4.932859E−37 |
| 2 | 12 | −1.998481E−37 |
| 0 | 14 | 3.401283E−37 |
| 14 | 1 | −3.946315E−40 |
| 12 | 3 | 1.665930E−40 |
| 10 | 5 | −3.647359E−40 |
| 8 | 7 | −5.456105E−42 |
| 6 | 9 | 2.134393E−41 |
| 4 | 11 | 1.279886E−40 |
| 2 | 13 | 3.027152E−41 |
| 0 | 15 | −1.505878E−40 |
| M2 | | |
| RDX | −7297.668572 | |
| RDY | 3197.447216 | |
| CCX | 0 | |
| CCY | 0 | |
| x**i | y**j | Coefficient |
| 2 | 1 | −5.122909E−08 |
| 0 | 3 | 1.894170E−07 |
| 4 | 0 | 8.648669E−12 |
| 2 | 2 | −1.039141E−10 |
| 0 | 4 | 2.583551E−10 |
| 4 | 1 | 3.454564E−14 |
| 2 | 3 | −1.609929E−13 |
| 0 | 5 | 3.504233E−13 |
| 6 | 0 | 1.448146E−16 |
| 4 | 2 | 6.887309E−17 |
| 2 | 4 | −1.523273E−16 |
| 0 | 6 | 4.504717E−16 |
| 6 | 1 | −8.019700E−20 |
| 4 | 3 | 8.908636E−19 |
| 2 | 5 | 4.364543E−19 |
| 0 | 7 | 5.328307E−19 |
| 8 | 0 | 7.537477E−22 |
| 6 | 2 | 2.489353E−21 |
| 4 | 4 | 3.999364E−21 |
| 2 | 6 | 1.813683E−21 |
| 0 | 8 | 2.781947E−22 |
| 8 | 1 | 1.183138E−24 |
| 6 | 3 | 7.647074E−24 |
| 4 | 5 | 5.984084E−24 |
| 2 | 7 | −4.469528E−24 |
| 0 | 9 | −1.279703E−24 |
| 10 | 0 | −1.385165E−26 |
| 8 | 2 | −5.258781E−26 |
| 6 | 4 | −3.476266E−27 |
| 4 | 6 | −4.157106E−26 |
| 2 | 8 | −3.764762E−26 |
| 0 | 10 | −4.303524E−27 |
| 10 | 1 | 9.379214E−29 |
| 8 | 3 | −7.409396E−29 |
| 6 | 5 | −2.285401E−28 |
| 4 | 7 | −1.951522E−28 |
| 2 | 9 | −5.324588E−29 |
| 0 | 11 | −8.489304E−30 |
| 12 | 0 | 1.382581E−31 |
| 10 | 2 | 9.276146E−31 |
| 8 | 4 | −2.820662E−31 |
| 6 | 6 | −5.621783E−31 |
| 4 | 8 | −5.830185E−32 |
| 2 | 10 | 1.641277E−31 |
| 0 | 12 | −2.289666E−32 |
| 12 | 1 | −2.487975E−33 |
| 10 | 3 | −1.101905E−33 |
| 8 | 5 | 9.657612E−34 |
| 6 | 7 | 4.854499E−34 |
| 4 | 9 | 1.187933E−33 |
| 2 | 11 | 7.038510E−34 |
| 0 | 13 | −5.722195E−35 |
| 14 | 0 | −2.713939E−37 |
| 12 | 2 | −6.052809E−36 |
| 10 | 4 | 6.399608E−37 |
| 8 | 6 | 4.484671E−36 |
| 6 | 8 | 3.162514E−36 |
| 4 | 10 | 2.601808E−36 |
| 2 | 12 | 9.818499E−37 |
| 0 | 14 | −7.675191E−38 |
| 14 | 1 | 1.840219E−38 |
| 12 | 3 | 1.870627E−38 |
| 10 | 5 | −9.453009E−40 |
| 8 | 7 | 5.173327E−39 |
| 6 | 9 | 2.967839E−39 |
| 4 | 11 | 1.736632E−39 |
| 2 | 13 | 5.001498E−40 |
| 0 | 15 | −4.024847E−41 |
| M1 | | |
| RDX | −8297.712811 | |
| RDY | −1899.720256 | |
| CCX | 0 | |
| CCY | 0 | |
| x**i | y**j | Coefficient |
| 2 | 1 | 4.110040E−08 |
| 0 | 3 | 1.498006E−08 |
| 4 | 0 | 1.000736E−10 |
| 2 | 2 | 1.683917E−11 |
| 0 | 4 | −1.850263E−11 |
| 4 | 1 | 5.430346E−14 |
| 2 | 3 | 4.291417E−14 |
| 0 | 5 | 1.608453E−14 |
| 6 | 0 | −1.063478E−16 |
| 4 | 2 | 1.196291E−17 |
| 2 | 4 | 7.109851E−17 |
| 0 | 6 | −5.467158E−17 |
| 6 | 1 | −1.407651E−19 |
| 4 | 3 | −2.070012E−19 |
| 2 | 5 | −7.562967E−20 |
| 0 | 7 | 1.591316E−19 |
| 8 | 0 | −3.205437E−22 |
| 6 | 2 | −3.080155E−22 |
| 4 | 4 | −7.305611E−23 |
| 2 | 6 | 8.803919E−22 |
| 0 | 8 | 6.031381E−22 |
| 8 | 1 | −5.084704E−25 |
| 6 | 3 | 5.341415E−24 |
| 4 | 5 | 1.998606E−23 |
| 2 | 7 | 2.419009E−23 |
| 0 | 9 | −1.669778E−24 |
| 10 | 0 | 2.036647E−26 |
| 8 | 2 | 3.818484E−27 |
| 6 | 4 | 2.062521E−26 |
| 4 | 6 | 1.148952E−25 |
| 2 | 8 | 5.836606E−26 |
| 0 | 10 | −8.015138E−26 |
| 10 | 1 | 1.261190E−29 |
| 8 | 3 | −3.142738E−28 |
| 6 | 5 | −6.349733E−28 |
| 4 | 7 | −1.105741E−27 |
| 2 | 9 | −9.774871E−28 |
| 0 | 11 | −6.495095E−28 |
| 12 | 0 | −4.915872E−31 |
| 10 | 2 | −6.859774E−31 |
| 8 | 4 | −2.708558E−30 |
| 6 | 6 | −8.764355E−30 |
| 4 | 8 | −1.645344E−29 |
| 2 | 10 | −8.426611E−30 |
| 0 | 12 | −2.684331E−30 |
| 12 | 1 | −1.278878E−33 |
| 10 | 3 | 2.905399E−33 |
| 8 | 5 | −1.151829E−32 |
| 6 | 7 | −5.073007E−32 |
| 4 | 9 | −8.237880E−32 |
| 2 | 11 | −2.939263E−32 |
| 0 | 13 | −6.309762E−33 |
| 14 | 0 | 4.347084E−36 |
| 12 | 2 | 1.653236E−35 |
| 10 | 4 | 2.405335E−35 |
| 8 | 6 | −3.165639E−35 |
| 6 | 8 | −1.423336E−34 |
| 4 | 10 | −1.902241E−34 |
| 2 | 12 | −4.996666E−35 |
| 0 | 14 | −8.294123E−36 |
| 14 | 1 | 3.113712E−38 |
| 12 | 3 | 3.321563E−38 |
| 10 | 5 | 3.877339E−38 |
| 8 | 7 | −4.393832E−38 |
| 6 | 9 | −1.559501E−37 |
| 4 | 11 | −1.701134E−37 |
| 2 | 13 | −3.396555E−38 |
| 0 | 15 | −4.672410E−39 |

As is evident from the signs of the radii of curvature in the tables above, the mirrors M2, M4 and M5 have saddle surfaces.

In principle, other combinations of NI and GI mirror sequences are also conceivable. In particular, the number of mirrors of successive GI mirrors may vary between three and five without resulting in a transmission that changes too significantly since the GI mirrors, if there is an increased number, are impinged on at grazing incidence, and hence each individual mirror has a high transmission.

None of the above-described projection optical units have a polarization rotation of linearly polarized imaging light 16 of greater than 10° in the imaging beam path between the object field 5 and the image field 11. In fact, in the above-described projection optical unit embodiments, this polarization rotation is less than 10°, is less than 7°, less than 6°, less than 5° and is also less than 4.5°.

In order to produce a microstructured or nanostructured component, the projection exposure apparatus 1 is used as follows: First, the reflection mask 10 or the reticle and the substrate or the wafer 11 are provided. Subsequently, a structure on the reticle 10 is projected onto a light-sensitive layer of the wafer 11 with the aid of the projection exposure apparatus 1. Then, a microstructure or nanostructure on the wafer 11, and hence the microstructured component, is produced by developing the light-sensitive layer.

What is claimed is:

1. An imaging EUV optical unit configured to image an object field into an image field, the imaging EUV optical unit comprising:
a plurality of mirrors configured to guide EUV imaging light at a wavelength of less than 30 nanometers along an imaging beam path from the object field towards the image field,
wherein:
the EUV optical unit comprises at least three normal incidence (NI) mirrors;
an overall transmission of the NI mirrors is greater than 10%; and
when EUV imaging light is linearly polarized, an overall number of the mirrors leads to an overall polarization rotation of no more than 10° along the imaging beam path.

2. The imaging EUV optical unit of claim 1, wherein the imaging EUV optical unit has precisely four NI mirrors.

3. The imaging EUV optical unit of claim 2, wherein a first imaging of the object field in the imaging beam path occurs in the image field.

4. The imaging EUV optical unit of claim 1, wherein the plurality of mirrors consists of NI mirrors.

5. The imaging EUV optical unit of claim 4, wherein a first imaging of the object field in the imaging beam path occurs in the image field.

6. The imaging EUV optical unit of claim 1, wherein at least one of the mirrors has a saddle-shaped reflection surface.

7. The imaging EUV optical unit of claim 1, wherein at least one of the mirrors has a reflection surface with an aspect ratio of greater than 1.5 between a greater surface extent along a first reflection surface dimension and a smaller surface extent along a second reflection dimension perpendicular thereto.

8. The imaging EUV optical unit of claim 1, wherein the imaging EUV optical unit has a ring-field-shaped image field.

9. The imaging EUV optical unit of claim 1, wherein:
two imaging beam path portions cross in a crossing region;
each imaging beam path portion is in the imaging beam path between the object field and the first mirror; and
each imaging beam path portion is between two successive mirrors, or each imaging beam path portion is between a last mirror in the imaging beam path and the image field.

10. The imaging EUV optical unit of claim 9, wherein the two crossing imaging beam path sections are:
between the object field and a first mirror in the imaging beam path; and
between a second mirror in the imaging beam path and the third mirror in the imaging beam path.

11. The imaging EUV optical unit of claim 1, wherein an entrance pupil of the imaging EUV optical unit is in the imaging beam path upstream of the object field.

12. The imaging EUV optical unit of claim 1, wherein at least one of the mirrors comprises an opening, and the imaging beam path passes through the opening.

13. The imaging EUV optical unit of claim 1, wherein the imaging EUV optical unit has precisely four NI mirrors, and at least one of the mirrors has a saddle-shaped reflection surface.

14. The imaging EUV optical unit of claim 1, wherein the plurality of mirrors consists of NI mirrors, and at least one of the mirrors has a saddle-shaped reflection surface.

15. The imaging EUV optical unit of claim 1, wherein the imaging EUV optical unit has precisely four NI mirrors, and at least one of the mirrors has a reflection surface with an aspect ratio of greater than 1.5 between a greater surface extent along a first reflection surface dimension and a smaller surface extent along a second reflection dimension perpendicular thereto.

16. The imaging EUV optical unit of claim 1, wherein the plurality of mirrors consists of NI mirrors, and at least one of the mirrors has a reflection surface with an aspect ratio of greater than 1.5 between a greater surface extent along a first reflection surface dimension and a smaller surface extent along a second reflection dimension perpendicular thereto.

17. The imaging EUV optical unit of claim 1, wherein the plurality of mirrors consists of four NI mirrors.

18. An optical system, comprising:
an EUV imaging optical unit according to claim 1; and
an illumination optical unit configured to illuminate the object field with the imaging light.

19. An apparatus, comprising:
an EUV light source configured to provide EUV light;
an EUV imaging optical unit according to claim 1; and
an illumination optical unit configured to illuminate the object field with the EUV light.

20. A method of using a projection exposure apparatus comprising an illumination optical unit and an imaging optical unit, the method comprising:
using the illumination optical unit to illuminate a portion of a reticle in an object field of the imaging optical unit; and
projecting the illuminated portion of the reticle into an image field of the imaging optical unit,
wherein the imaging optical unit is an imaging optical unit according to claim 1.
